(19) United States
(12) Patent Application Publication
(10) Pub. No.: US 2025/0033988 A1
(43) Pub. Date: Jan. 30, 2025

(54) SYNTHESIS, CAPPING AND DISPERSION OF HIGH REFRACTIVE INDEX NANOCRYSTALS AND NANOCOMPOSITES

(71) Applicant: PT SPE SUBCO LLC, Baltimore, MD (US)

(72) Inventors: Robert J. WIACEK, Baltimore, MD (US); Selina Thomas MONICKAM, Takoma Park, MD (US); Mohammad Sadegh YAZDANPARAST, Beaverton, OR (US); Brian SZYCHOWSKI, Abingdon, MD (US); Guoyi FU, Glenwood, MD (US); Peter Christopher GUSCHL, Abingdon, MD (US); Grace E.M. MCCLINTOCK, Baltimore, MD (US); Lei ZHENG, Greenbelt, MD (US); Zehra Serpil Gonen WILLIAMS, Odenton, MD (US); Mohammadreza AMIRMOSHIRI, Baltimore, MD (US); Nicole Joud TADROS, Baltimore, MD (US)

(21) Appl. No.: 18/721,555

(22) PCT Filed: Dec. 20, 2022
(86) PCT No.: PCT/US2022/053543

§ 371 Date: Jun. 20, 2024

Related U.S. Application Data
(60) Provisional application No. 63/292,197, filed on Dec. 21, 2021.

(51) Int. Cl. C01G 23/047; C01G 25/02; C30B 7/14; C30B 29/16

(52) U.S. Cl. CPC C01G 23/047; C01G 25/02; C30B 7/14; C30B 29/16; C01P 2002/85; C01P 2004/03; C01P 2004/04; C01P 2004/51; C01P 2004/64

(57) ABSTRACT

Preparation of capped metal oxide nanocrystals comprising a metal oxide shell that are photocatalytically and thermally stable and their dispersions in monomers, oligomers, and polymers, as well as the resulting formulations and nanocomposite films. These nanocrystals are highly monodisperse with nanocrystal size between 3-100 n. Resultant formulations incorporating these nanocrystals and a matrix material are highly stable and result in nanocomposites that have high refractive index, are highly transparent, have minimal to no change in absorption upon thermal or UV processing and are optically transparent in the visible wavelengths with very little or no scattering.

The present application claims the benefit of U.S. Provisional Application No. 63/292,197, filed Dec. 21, 2021, the entire contents of which are herein incorporated by reference.

In various embodiments, the present application describes preparation of photocatalytically and thermally stable capped metal oxide nanocrystals of ZrO₂ and TiO₂ comprising a metal oxide shell that are and their dispersions in monomers, oligomers, and/or polymers, as well as the resulting nanocomposite films. These nanocrystals are highly monodisperse with nanocrystal size between 3-100 nm. Dispersions of these nanocrystals are formed in various solvents, monomer, oligomers and/or polymers. These dispersions typically have high loading, high transmittance, and low viscosity. Resultant formulations incorporating these nanocrystals and a matrix material are typically highly stable and result in nanocomposites that have high refractive index, are low absorbing, with minimal to no change in absorption upon thermal or UV processing and are optically transparent in the visible wavelengths with very little or no scattering.

### BACKGROUND

Titanium dioxide (TiO₂), or titania, is one of the most widely used multifunctional ceramic materials due to its unique physical and chemical characteristics combined with its abundance and nontoxicity. Due to its bulk properties, including high refractive index and (UV) light absorption, TiO₂ has been commercially manufactured in the millions of tons and can commonly be found in pigments, paints, sunscreens, and coatings. In addition to the traditional applications, titania is also being studied for use in many applications including optoelectronics, photovoltaics, catalysis, fuel cells, batteries, smart windows, sensors, and self-cleaning surfaces.

Titanium dioxide, especially in sub-nm sized particles, has generated a great interest for optical applications because of its high refractive index. The two crystalline phases of titanium oxide, anatase and rutile, possess a refractive index of 2.55 and 2.76, respectively. And when combined with monomers, oligomers or polymers, these metal oxides demonstrate high transparency and high refractive index. However, TiO₂ particles are excellent UV absorbers. The energy band gap for anatase and rutile are 3.23 eV or 3.06 eV, respectively. As a result of this large energy band gap, TiO₂ is photochemically active. When exposed to high energy wavelengths, electrons are excited from the valence band to the conduction band, generating electron-hole pairs. These electron-hole pair diffuse to the surface of the TiO₂ to create radical species which then can be detrimental to surface organics leading to their breakdown. This degradation of the surface organics leads to disintegration of the polymers leading to defects, such as chalking and yellowing.

As the demand for higher refractive index material increases, the need for photochemically and thermally stable TiO₂ is becoming essential. With limited organic material options available, inorganic-organic nanocomposite materials remain the only option to attaining such higher refractive index demands.

### BRIEF SUMMARY

The present disclosure provides a method of making TiO₂ nanocrystals that have reduced photocatalytic activity and are thermally stable at higher temperatures.

The present disclosure provides methods for making TiO₂ and ZrO₂ nanocrystals comprising a crystalline core and a thin shell of a metal oxide forming a nanocrystal with core-shell structure. The shell materials include, but are not limited to, silicon dioxide, zirconium dioxide, hafnium dioxide, niobium oxide, aluminum oxide, tantalum oxide, barium titanium oxide, cerium oxide, or any combination thereof.

The present disclosure includes the method of capping the core-shell nanocrystals that have a crystalline core and a metal oxide outer shell/coating. The core-shell nanocrystals are separated, and/or purified, and capped with at least one capping agent to produce at least partially capped nanocrystals. The at least partially capped nanocrystals can be further purified and/or separated according to methods of the present disclosure. Nanocrystals and capped nanocrystals can be dispersed in a material, including solvent, monomer, polymer, or some combination thereof in methods of the present disclosure.

The present disclosure further includes a method of surface passivation of TiO₂ and ZrO₂ nanocrystals coated with a metal oxide outer shell/coating and further treatment with at least one inorganic passivation agent. The core-shell nanocrystals of the present disclosure are treated with at least one inorganic passivation agent prior to or after capping with at least one capping agent. The resulting at least partially capped nanocrystals with the inorganic treatment are further purified and/or separated according to methods of the present disclosure. Nanocrystals and capped nanocrystals are dispersed in a material, including solvent, polymer, or some combination thereof in methods of the present disclosure.

The present disclosure includes the method of passivation of TiO₂ and ZrO₂ nanocrystals without the outer shell with at least one inorganic passivation agent. The TiO₂ and ZrO₂ nanocrystals of the present disclosure are optionally treated with at least one inorganic passivation agent prior to or after capping. The at least partially capped nanocrystals with inorganic treatment are further purified and/or separated according to methods of the present disclosure. Nanocrystals and capped nanocrystals are dispersed in a material, including solvent, polymer, or some combination thereof in methods of the present disclosure.

The present disclosure further includes dispersions and formulations of core-shell nanocrystals with a core metal oxide and at least one shell metal oxide outer shell. These dispersions may be in solvents and formulations comprising monomers, oligomers and/or polymers in addition to other additives.

The present disclosure further includes a nanocomposite material containing a matrix and nanocrystals, which have been, for example, mixed, stirred, or dispersed therein. Nanocomposites according to the present disclosure are fabricated by, for example, UV curing, heat curing, melt blending, in situ polymerization, and/or solvent mixing of the nanocrystals and the matrix materials or precursors of the matrix. Nanocrystals comprise one or more of ZrO₂ nanocrystals, TiO₂ nanocrystals, and core-shell nanocrystals.

The present disclosure includes methods for evaluating the photocatalytic activity and the thermal stability of the TiO₂ nanocrystals embedded in a polymeric matrix.

The present disclosure also provides exemplary embodiments such as those shown in the examples section, enumerated embodiments 1-42, and those shown in claims 1-62 herein.

It is to be understood that both the foregoing summary and the following detailed description are exemplary and explanatory only and are not restrictive of the invention herein.

### BRIEF DESCRIPTION OF FIGURES

FIG. 1: An exemplary intensity versus particle size DLS plot of capped titanium oxide nanocrystals with ZrO₂ shell with inorganic passivation treatment described in example 6 at 5% by weight in PGMEA showing an average particle size of 37.15 nanometer.

FIG. 2: An exemplary volume versus particle size DLS plot of capped titanium oxide nanocrystals comprising ZrO₂ shell with inorganic passivation treatment described in example 6 at 5% by weight in PGMEA showing an average particle size of 25.46 nanometer.

FIG. 3: An exemplary TEM image of titanium oxide nanocrystals with an outer ZrO₂ shell described in example 6 showing average particle sizes less than 20 nanometers and Zr and Ti atoms present in the same particles.

FIGS. 4a, 4b, and 4c: An exemplary optical transmittance of a 1-micron thick spin coated nanocomposite comprising at least partially capped TiO₂ nanocrystals with ZrO₂ shell and a combination of acrylic monomer stated in example 19 when exposed to 450 nm wavelength for 1000 hours continuously: with (a) nanocrystals from example 5, (b) nanocrystals from example 6, and (c) nanocrystals from example 7.

### BRIEF DESCRIPTION OF TABLES

Table 1: The discoloration ranking of the TiO₂ nanocrystals with and without ZrO₂ shell before capping and do not contain inorganic treatment when exposed to UV irradiation and post baking step.

Table 2: The discoloration ranking of the at least partially capped TiO₂ nanocrystals without any metal oxide shell and with different inorganic treatments when exposed to UV irradiation and post baking step.

Table 3: The discoloration ranking of the at least partially capped TiO₂ with and without ZrO₂ shell and/or inorganic treatment when heated at different temperatures.

Table 4: Optical properties of the nanocomposites made using formulation described in example 19

Table 5: Optical properties of the nanocomposites prepared as described in example 19 and exposed to 320-390 nm wavelength for 158 hours (average intensity 4 mW/cm²) continuously.

Table 6: Optical properties of the nanocomposites prepared as described in example 19 and exposed to 405 nm wavelength for 148 hours (average intensity 25 mW/cm²) continuously.

Table 7: Optical properties of the nanocomposites prepared as described in example 19 and exposed to 450 nm wavelength for 1000 hours (average intensity 16 mW/cm²) continuously.

Table 8a: Summary of formulation composition and properties. Included samples with titania nanocrystals and titania-zirconia nanocrystals.

Table 8c: Optical properties of the nanocomposites described in example 21 when exposed to UVA light for 72 hours.

Table 8d: Optical properties of the nanocomposites described in example 21 when exposed to QUV accelerated weathering test for 72 hours

Table 9a: Summary of formulation composition and viscosities described in example 22

Table 9b: Optical properties of the nanocomposites on glass substrates described in example 22 when exposed to 405 nm light for 150 hrs.

Table 10a: Viscosities and optical properties of the nanocomposites made using formulation described in example 23

Table 10b: Optical properties of the nanocomposites described in example 23 when exposed to QUV accelerated weathering test for 72 hours

Table 10c: Optical properties of the nanocomposites described in example 23 when exposed to 405 nm wavelength for 148 hours continuously

### DETAILED DESCRIPTION

The zirconium oxide and titanium oxide nanocrystals used for various treatments in the present disclosure can typically be prepared by a solvothermal methods wherein a precursor of the titanium oxide or zirconium oxide is mixed or dissolved in at least one solvent and allowed to react for a certain period of time. Pressure and/or heating is used in some cases. The resultant TiO₂ or ZrO₂ nanocrystals are optionally separated and purified by settling, centrifugation, filtration and other separation methods known in the art. In a solvothermal process the solvent is not water. When water is used as most of the solvent, the synthetic method is referred to as a hydrothermal synthesis. Addition of small amount of water as a reactant rather than as a solvent into the reaction mixture in solvothermal synthesis of TiO₂ and ZrO₂ nanocrystals results in better control of the particle size and size distribution than reactions carried out without addition of water. Exemplary useful methods for the synthesis, capping and dispersion of TiO₂ and ZrO₂ nanocrystals herein include those described in International Application Nos: PCT/US2011/057822 (published as WO 2012/058271), and PCT/US2019/062439 (published as WO 2020/106860), the content of each of which is incorporated herein by reference in its entirety.

The precursor of the titanium oxide nanocrystals are typically selected from one or more of alkoxides, such as: titanium methoxide (Ti(OCH₃)₄), titanium ethoxide (Ti(OCH₂CH₃)₄), titanium n-propoxide (Ti(OCH₂CH₂CH₃)₄), titanium isopropoxide (Ti(OCH(CH₃)₂)₄), titanium n-butoxide (Ti(OCH₂CH₂CH₂CH₃)₄); acetylacetonates, such as titanium oxyacetylacetonate (TiO(CH₃COCH_{C}OCH₃)₂); halides, such as titanium chloride (TiCl₄); and mixed halides and alkoxide, such as titanium chlorotriisopropoxytitanium (TiCl(OCH(CH₃)₂)₃), chlorotributoxytitanium (TiCl(OCH₂CH₂CH₂CH₃)₃), or titanium dichloride diethoxide (TiCl₂(OCH₂CH₃)₂) or other organometallic compounds.

The precursor of the zirconium oxide nanocrystals are typically selected from one or more of alkoxides, such as: zirconium methoxide (Zr(OCH₃)₄), zirconium ethoxide (Zr(OCH₂CH₃)₄), zirconium n-propoxide (Zr(OCH₂CH₂CH₃)₄), zirconium isopropoxide (Zr(OCH(CH₃)₂)₄), zirconium n-butoxide (Zr(OCH₂CH₂CH₂CH₃)₄); acetylacetonates, such as zirconium oxyacetylacetonate (ZrO(CH₃COCH_{C}OCH₃)₂); halides, such as zirconium chloride (ZrCl₄); and mixed halides and alkoxide, such as zirconium chlorotriisopropoxytitanium (ZrCl(OCH(CH₃)₂)₃), chlorotributoxyzirconium (ZrCl(OCH₂CH₂CH₂CH₃)₃), or zirconium dichloride diethoxide (ZrCl₂(OCH₂CH₃)₂) or other organometallic compounds.

Examples for solvents for synthesis of nanocrystals of the present disclosure typically include one or more of alcohols such as: benzyl alcohol, phenol, oleyl alcohol, butanol, propanol, isopropanol, ethanol, butoxy ethanol, butoxy propanol, methanol, 2-(isopentyloxy)ethanol, 2-propoxy-propanol (PnP), 2-(hexyloxy)ethanol; ethers and cyclic ethers, such as: tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether; glycols such as: diethylene glycol, dipropylene glycol; ketones and cyclic ketones, such as: acetone; esters, such as: propylene glycol methyl ether acetate (PGMEA), ethyl lactate (EL), methyl acetates, ethyl acetates, butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate; aromatics such as: benzene, toluene; and water and any combination or mixture thereof.

The titanium oxide or zirconium oxide of the present disclosure is typically coated with an outer shell comprising at least one metal oxide. The method of coating the outer oxide shell generally includes converting a precursor of the oxide shell around the zirconium or titanium oxide nanocrystals. Examples of oxides used as shell material include, but are not limited to, silicon dioxide, zirconium dioxide, hafnium dioxide, niobium oxide, aluminum oxide, tantalum oxide, barium titanium oxide, cerium oxide or any combination thereof. The process includes mixing or suspending the TiO₂ or ZrO₂ nanocrystals that are optionally separated and purified in a solvent and adding at least one precursor of the shell metal oxides to the solution. The solution is then reacted for a period of time to facilitate the reaction between the core metal oxide and the shell oxide precursor. Heat and/or pressure is optionally applied during the reaction. This produces core-shelled nanocrystals. The core-shelled nanocrystals are optionally separated and purified.

Examples of the precursors of the oxide shell on TiO₂ or ZrO₂ nanocrystals include but are not limited to a metal alkoxide, such as a metal alkoxide having a formula of M(OR)4, a compound having a formula of M(OR)xGy, or a combination thereof, wherein M can be Ce, Zr, Si, Hf, NB, Al, Ta, Ti, Ba, each R group can be independently an alkyl group (e.g., a C1-C6 alkyl group) or a substituted alkyl group, G group at each occurrence is independently a halogen (e.g., Cl), wherein x is an integer of 0-4, y is an integer of 0-4, provided that x+y is 4, a metal oxyhalide, a metal halide, a metal, or any combination thereof. Examples of the precursor of the shell metal oxide include, but are not limited to zirconium oxychloride, titanium oxychloride, hafnium oxychloride, sodium aluminate, aluminum isopropoxide, tetraethyl orthosilicate, tetramethyl orthosilicate, cerium chloride, cerium carbonate or any combination thereof.

Optionally, a base or acid is present to facilitate the conversion of the shell metal oxide precursor into the oxide shell on TiO₂ or ZrO₂ nanocrystals. Examples of the base or acid of the present disclosure include, but are not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid.

Examples of the solvent that is used to facilitate the conversion of the shell metal oxide precursor into the oxide shell on TiO₂ or ZrO₂ nanocrystals include but are not limited to water, PGMEA, PGME, ethanol, methanol, isopropanol, benzyl alcohol or any combination thereof.

Examples of the solvent that is used for purification include but are not limited to water, THF, acetone, heptane, toluene, PGMEA, PGME, ethanol, methanol, isopropanol, or any combination thereof.

Optionally, a base or acid is present to facilitate the neutralization of excess acid or base present during purification. Examples of the base or acid of the present disclosure include, but are not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid.

Manufacturing sub-nanometer sized nanocrystals often results in agglomeration which leads to scattering and loss of transparency in resulting nanocomposites. The key to producing well-dispersed nanocomposites is to use nanocrystals which are not aggregated before the start of mixing with the matrix or media. One method to achieving nanocrystals that are not aggregated is to control the surface chemistry of the nanocrystals by introduction of ligand ions or molecules called capping agents. These capping agents are added to the surface of the nanocrystals to create a new effective surface of the nanocrystals. This effective surface is the surface of the shell created by the complete or partial surface coverage with capping agents. The chemistry of this effective surface can be tailored in order to create a chemical environment, distinct from the actual or initial surface of the nanocrystal, which facilitates dispersion while preventing or reducing aggregation.

In some embodiments, the surface of the core-shelled titanium oxide or zirconium oxide nanocrystals of the present disclosure are capped with at least one capping agent. The process of capping includes suspending the optionally separated and purified core-shelled nanocrystals in a capping solvent and adding a capping agent to this solution which is called a reaction mixture. The reaction mixture is reacted for a period. Heat and/or pressure is optionally applied during the reaction. Optionally, a base or acid is added to the solution to facilitate the reaction. Optionally, a second capping agent is added to the reaction mixture and reacted for a period of time. Heat and/or pressure is optionally applied during the reaction. The resultant capped product is optionally separated and purified to produce at least partially capped core-shelled nanocrystals. Optionally, the separated and purified at least partially capped core-shelled nanocrystals are dried and then dispersed in a solvent.

In one embodiment, at least partially capped core-shelled nanocrystals of the present disclosure can be further treated with an inorganic passivation reagent. The process of treatment includes suspending the separated and purified as synthesized core-shelled nanocrystals in a capping solvent and adding a capping agent to this solution. Heat and/or pressure is optionally applied during the reaction and the solution is reacted for a period of time. A base or acid is optionally added to the solution to facilitate the reaction. After the set period of reaction time, at least one inorganic passivation agent is added to the solution. Heat and/or pressure is optionally applied during the reaction. The resultant product is optionally separated and purified to produce at least partially capped as synthesized core-shelled nanocrystals with an inorganic treatment. Optionally, the capped inorganic treated material is separated, purified, dried and then dispersed in a solvent.

In another embodiment, the surface of the core-shelled titanium oxide or zirconium oxide nanocrystals of the present disclosure are treated with an inorganic passivation agent before capping with at least one capping agent. The process of treatment typically includes suspending the optionally separated and purified core-shelled nanocrystals in a solvent and adding at least one inorganic passivation agent to the suspension. The suspension is mixed for a period of time. After which, nanocrystals are separated, purified and re-suspended in a capping solvent. At least one capping agent is added to the suspension and reacted for a period of time. Heat and/or pressure is optionally applied during the reaction. Optionally, a base or acid is added to the solution to facilitate the reaction. Optionally, a second capping agent is added to the reaction mixture and reacted for a period of time. Heat and/or pressure is optionally applied during the reaction. The resultant capped product is optionally separated and purified to produce at least partially capped core-shelled nanocrystals with an inorganic treatment. Optionally, the separated and purified at least partially capped core-shelled nanocrystals with an inorganic treatment is dried and then dispersed in a solvent.

Examples of suitable capping agents include, but are not limited to, silanes, alcohols, phosphates or carboxylic acids. Examples of silanes of the present disclosure include, but not limited to, methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl] trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate or any combination thereof.

Examples of alcohols include, but are not limited to, heptanol, hexanol, octanol, benzyl alcohol, phenol, ethanol, propanol, butanol, oleylalcohol, dodecylalcohol, octadecanol and triethylene glycol monomethyl ether or any combination thereof.

Examples of phosphate containing capping agents include, but are not limited to, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, or any combination thereof.

Examples of carboxylic acids include, but are not limited to, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

Optionally, the silane capping agents can form a second outer metal oxide layer comprising silicon dioxide encapsulating titanium oxide or zirconium oxide nanocrystals comprising the first metal oxide shell. Examples of the first metal oxide shell material include, but are not limited to, silicon dioxide, zirconium dioxide, hafnium dioxide, niobium oxide, aluminum oxide, tantalum oxide, barium titanium oxide, cerium oxide or any combination thereof.

Optionally, the silane capping agents can mix with the outer metal oxide shell material to form a shell comprising mixtures of silicon dioxide and other metal oxides encapsulating titanium oxide or zirconium oxide nanocrystals. Examples of the other metal oxide shell material include, but are not limited to, silicon dioxide, zirconium dioxide, hafnium dioxide, niobium oxide, tantalum oxide, aluminum oxide, barium titanium oxide, cerium oxide or any combination thereof.

Examples of the capping solvent includes but are not limited to alcohols such as: benzyl alcohol, phenol, oleyl alcohol, butanol, propanol, isopropanol, ethanol, butoxy ethanol, butoxy propanol, methanol; ethers and cyclic ethers, such as: tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether; glycols such as: diethylene glycol, dipropylene glycol; ketones and cyclic ketones, such as: acetone; esters, such as: propylene glycol methyl ether acetate (PGMEA), ethyl lactate (EL), methyl acetates, ethyl acetates, butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate; aromatics such as: benzene, toluene; and water and any combination or mixture thereof.

Examples of the base or acid of the present disclosure include, but are not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid.

Examples of the solvent that is used for purification include but are not limited to water, THF, acetone, heptane, toluene, isopropanol, propylene glycol methyl ether acetate (PGMEA), propylene glycol monomethyl ether (PGME), ethanol, methanol, toluene, benzyl alcohol or any combination thereof.

Examples of the solvent that is used for dispersion include but are not limited to THF, acetone, heptane, benzyl alcohol, phenol, oleyl alcohol, butanol, propanol, isopropanol, ethanol, butoxy ethanol, butoxy propanol, methanol, tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether, diethylene glycol, dipropylene glycol, acetone; esters, such as: propylene glycol methyl ether acetate (PGMEA), ethyl lactate (EL), methyl acetates, ethyl acetates, butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate, benzene, toluene, and water and any combination or mixture thereof.

Examples of the inorganic passivation reagent include but are not limited to sodium polyphosphate, lithium nitrate, sodium hypochlorite, sodium hypophosphite, sodium phosphite, lithium chloride, sodium nitrate, sodium chloride, sodium aluminum phosphate, sodium hexametaphosphate or any combination thereof.

Optionally, the inorganic passivation reagents can be incorporated on to the outer metal oxide layer of the titanium oxide or zirconium oxide nanocrystals.

In another embodiment, the titanium oxide or zirconium oxide of the present disclosure is treated with an inorganic passivation agent before coating with an outer metal oxide shell. The process of treatment typically includes suspending the optionally separated and purified titanium oxide or zirconium oxide in a solvent and adding at least one inorganic passivation agent to the suspension. The suspension is mixed for a period of time. After which, the inorganic passivation agent treated nanocrystals are separated, purified and re-suspended in a solvent for coating. The method of coating the outer oxide shell typically includes converting a precursor of the oxide shell around the zirconium or titanium oxide nanocrystals. The process of coating includes mixing or suspending the TiO₂ or ZrO₂ nanocrystals that are optionally separated and purified in a solvent and adding at least one precursor of the shell metal oxides to the solution. The solution is then reacted for a period of time to facilitate the reaction between the TiO₂ or ZrO₂ nanocrystals and the shell oxide precursor. Heat and/or pressure is optionally applied during the reaction. This produces synthesized inorganic treated core-shelled nanocrystals. The synthesized inorganic treated core-shelled nanocrystals are optionally separated and purified.

In some embodiments, the surface of the inorganic treated core-shelled titanium oxide or zirconium oxide nanocrystals of the present disclosure is capped with at least one capping agent. The process of capping includes suspending the optionally separated and purified core-shelled nanocrystals in a capping solvent and adding a capping agent to this solution which is called a reaction mixture. The reaction mixture is reacted for a period of time. Heat and/or pressure is optionally applied during the reaction. Optionally, a base or acid is added to the solution to facilitate the reaction. Optionally, a second capping agent is added to the reaction mixture and reacted for a period of time. Heat and/or pressure is optionally applied during the reaction. The resultant capped product is optionally separated and purified to produce at least partially capped core-shelled nanocrystals. Optionally, the separated and purified at least partially capped core-shelled nanocrystals with inorganic treatment are dried and then dispersed in a solvent.

Examples of the inorganic passivation agent include but not limited to sodium polyphosphate, lithium nitrate, sodium hypochlorite, sodium hypophosphite, sodium phosphite, lithium chloride, sodium nitrate, sodium chloride, sodium aluminum phosphate, aluminum hypophosphite sodium hexametaphosphate, calcium hypophosphiteor any combination thereof.

Examples of the solvent for inorganic treatment includes but are not limited to benzyl alcohol, phenol, oleyl alcohol, butanol, propanol, isopropanol, ethanol, butoxy ethanol, butoxy propanol, methanol and water and any combination or mixture thereof.

Examples of oxides used as shell material include, but are not limited to, silicon dioxide, zirconium dioxide, hafnium dioxide, niobium oxide, aluminum oxide, tantalum oxide, barium titanium oxide, cerium oxide or any combination thereof.

Examples of the precursor of the shell metal oxide include, but are not limited to zirconium oxychloride, titanium oxychloride, and hafnium oxychloride, cerium chloride, cerium carbonate or any combination thereof.

Examples of a base or acid that is present to facilitate the conversion of the shell metal oxide precursor into the oxide shell on TiO₂ or ZrO2 nanocrystals includes, but not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid. Examples of the solvent that is used to facilitate the conversion of the shell metal oxide precursor into the oxide shell on TiO₂ or ZrO₂ nanocrystals include but not limited to water, PGMEA, PGME, ethanol, methanol, benzyl alcohol or any combination thereof.

Examples of the solvent that is used for purification include but are not limited to water, THF, acetone, heptane, toluene, PGMEA, PGME, ethanol, methanol, toluene or any combination thereof.

Optionally, a base or acid is present to facilitate the neutralization of excess acid or base present during purification. Examples of the base or acid of the present disclosure include, but are not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid.

Examples of the capping solvent includes but are not limited to alcohols such as: benzyl alcohol, phenol, oleyl alcohol, butanol, propanol, isopropanol, ethanol, butoxy ethanol, butoxy propanol, methanol; ethers and cyclic ethers, such as: tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether; glycols such as: diethylene glycol, dipropylene glycol; ketones and cyclic ketones, such as: acetone; esters, such as: propylene glycol methyl ether acetate (PGMEA), ethyl lactate (EL), methyl acetates, ethyl acetates, butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate; aromatics such as: benzene, toluene; and water and any combination or mixture thereof.

Examples of capping agents include, but are not limited to, silanes, alcohols, phosphates or carboxylic acids. Examples of silanes of the present disclosure include, but not limited to, methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate or any combination thereof.

Examples of alcohols include, but are not limited to, heptanol, hexanol, octanol, benzyl alcohol, phenol, ethanol, propanol, butanol, oleylalcohol, dodecylalcohol, octadecanol and triethylene glycol monomethyl ether or any combination thereof.

Examples of phosphate containing capping agents include, but are not limited to, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, or any combination thereof.

Examples of carboxylic acids include, but are not limited to, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

Examples of the base or acid include, but not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid.

Examples of the solvent that is used for purification include but are not limited to water, THF, acetone, heptane, toluene, propylene glycol methyl ether acetate (PGMEA/PGA), propylene glycol monomethyl ether (PGME), ethanol, methanol, toluene, benzyl alcohol or any combination thereof.

Examples of the solvent that is used for dispersion include but are not limited to THF, acetone, heptane, benzyl alcohol, phenol, oleyl alcohol, butanol, propanol, isopropanol, ethanol, butoxy ethanol, butoxy propanol, methanol, tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether, diethylene glycol, dipropylene glycol, acetone; esters, such as: propylene glycol methyl ether acetate (PGMEA), ethyl lactate (EL), methyl acetates, ethyl acetates (ETA), butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate, benzene, toluene, and water and any combination or mixture thereof.

Optionally, the silane capping agents can form a second outer metal oxide layer comprising silicon dioxide encapsulating titanium oxide or zirconium oxide nanocrystals comprising of the first metal oxide shell. Examples of the first metal oxide shell material include, but are not limited to, silicon dioxide, zirconium dioxide, hafnium dioxide, niobium oxide, aluminum oxide, tantalum oxide, barium titanium oxide, cerium oxide or any combination thereof.

Optionally, the silane capping agents can mix with the outer metal oxide layer material to form a shell comprising of mixtures of silicon dioxide and other metal oxides encapsulating titanium oxide or zirconium oxide nanocrystals. Examples of the other metal oxide shell material include, but are not limited to, silicon dioxide, zirconium dioxide, hafnium dioxide, niobium oxide, tantalum oxide, aluminum oxide, barium titanium oxide or any combination thereof.

Optionally, the inorganic passivation reagents can be incorporated on to the outer metal oxide layer of the titanium oxide or zirconium oxide nanocrystals.

In another embodiment, the titanium oxide or zirconium oxide without any outer shell of the present disclosure is treated with an inorganic passivation agent followed by capping. The process of treatment typically includes suspending the optionally separated and purified titanium oxide or zirconium oxide in a solvent and adding at least one inorganic passivation agent to the suspension. The suspension is mixed for a period of time. After which, the inorganic treated nanocrystals are separated, purified and re-suspended in a capping solvent. At least one capping agent is added to the suspension and reacted for a period of time. Heat and/or pressure is optionally applied during the reaction. Optionally, a base or acid is added to the solution to facilitate the reaction. Optionally, a second capping agent is added to the reaction mixture and reacted for a period of time. Heat and/or pressure is optionally applied during the reaction. The resultant capped product is optionally separated and purified to produce at least partially capped nanocrystals with an inorganic treatment. Optionally, the separated and purified at least partially capped nanocrystals with an inorganic treatment is dried and then dispersed in a solvent.

Examples of the inorganic passivation agent include but not limited to sodium polyphosphate, lithium nitrate, sodium hypochlorite, sodium hypophosphite, sodium phosphite, lithium chloride, sodium nitrate, sodium chloride, sodium aluminum phosphate, aluminum hypophosphite sodium hexametaphosphate, calcium hypophosphite or any combination thereof.

Examples of the solvent for inorganic treatment includes but are not limited to benzyl alcohol, phenol, oleyl alcohol, butanol, propanol, isopropanol, ethanol, butoxy ethanol, butoxy propanol, methanol and water and any combination or mixture thereof.

Examples of the solvent that is used for purification include but are not limited to water, THF, acetone, heptane, toluene, PGMEA, PGME, ethanol, methanol, toluene or any combination thereof.

Optionally, a base or acid is present to facilitate the neutralization of excess acid or base present during purification. Examples of the base or acid of the present disclosure include, but not limited to, trimethylammonium hydroxide, triethylammonium hydroxide, nitric acid, ammonium hydroxide, hydrochloric acid, benzoic acid, acetic acid or trifluoroacetic acid.

Examples of the capping solvent includes but are not limited to alcohols such as: benzyl alcohol, phenol, oleyl alcohol, butanol, propanol, isopropanol, ethanol, butoxy ethanol, butoxy propanol, methanol; ethers and cyclic ethers, such as: tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether; glycols such as: diethylene glycol, dipropylene glycol; ketones and cyclic ketones, such as: acetone; esters, such as: propylene glycol methyl ether acetate (PGMEA), ethyl lactate (EL), methyl acetates, ethyl acetates, butyl acetate, ethylene glycol monobutyl ether acetate (ETA), diethylene glycol monobutyl ether acetate, diethylene glycol monoethyl ether acetate, butoxy ethyl acetate, ethyl acetate, 2-(2-butoxyethoxy)ethyl acetate; aromatics such as: benzene, toluene; and water and any combination or mixture thereof.

Examples of suitable capping agents include, but are not limited to, silanes, alcohols, phosphates or carboxylic acids. Examples of silanes of the present disclosure include, but not limited to, methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate or any combination thereof.

Examples of alcohols include, but are not limited to, heptanol, hexanol, octanol, benzyl alcohol, phenol, ethanol, propanol, butanol, oleylalcohol, dodecylalcohol, octadecanol and triethylene glycol monomethyl ether or any combination thereof.

Examples of phosphate containing capping agents include, but are not limited to, (2-{2-[2-Methoxy-ethoxy]-ethoxy}-ethyl) phosphonic acid, (6-{2-[2-(2-Methoxy-ethoxy)-ethoxy]-ethoxy}-hexyl) phosphonic acid, 11-Acryloyloxyundecylphosphonic acid, or any combination thereof.

Examples of carboxylic acids include, but are not limited to, octanoic acid, acetic acid, propionic acid, 2-[2-(2-methoxyethoxy) ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

Examples of the base or acid include, but not limited to, trimethylammonium hydroxide, triethylammonium hydroxide, nitric acid, ammonium hydroxide, triethyl amine, polyethylenimine, citric acid, hydrochloric acid, benzoic acid, acetic acid or trifluoroacetic acid.

Examples of the solvent that is used for purification include but are not limited to water, THF, acetone, heptane, toluene, propylene glycol methyl ether acetate (PGMEA), propylene glycol monomethyl ether (PGME), ethanol, methanol, toluene, benzyl alcohol or any combination thereof.

Examples of the solvent that is used for dispersion include but are not limited to THF, acetone, heptane, benzyl alcohol, phenol, oleyl alcohol, butanol, propanol, isopropanol, ethanol, butoxy ethanol, butoxy propanol, methanol, tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether, diethylene glycol, dipropylene glycol, acetone; esters, such as: propylene glycol methyl ether acetate (PGMEA), ethyl lactate (EL), methyl acetates, ethyl acetates (ETA), butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate, benzene, toluene, and water and any combination or mixture thereof.

Optionally, the silane capping agents can form an outer metal oxide layer comprising silicon dioxide encapsulating titanium oxide or zirconium oxide nanocrystals.

Optionally, the inorganic passivation reagents can be incorporated on to the outer metal oxide layer of the titanium oxide or zirconium oxide nanocrystals.

TiO₂ and ZrO₂ Nanocrystal Synthesis Process

Exemplary methods for the synthesis, capping and dispersion of TiO₂ and ZrO₂ nanocrystals herein include those described in International Application Nos: PCT/US2011/057822 (published as WO 2012/058271), and PCT/US2019/062439 (published as WO 2020/106860), the content of each of which are incorporated herein by reference in their entirety.

In an exemplary method, titanium oxide nanocrystals are produced by a solvothermal process from a mixture of titanium (IV) butoxide, water, and benzyl alcohol in an inert atmosphere which is sealed within an autoclave. The ratio of titanium (IV) butoxide to water range from 1:0.1-1:10, such as 1:0.1-1:05, 1:0.5-1:1, 1:1-1:1.5, 1:1.5-1:2, 1:2-1:2.5, 1:2.5-1:3, 1:3-1:3.5, 1:3.5 to 1:4, 1:4-1:4.5, 1:4.5-1:5, 1:5-1:5.5, 1:5.5 to 1:6, 1:6-1:6.5, 1:6.5-1:7, 1:7-1:7.5, 1:7.5-1:8, 1:8-1:8.5, 1:8.5-1:9, 1:9-1:9.5, or 1:9.5-1:10. The ratio of titanium (IV) butoxide to benzyl alcohol range from 1:0.1-1:100, such as 1:0.1-1:5, 1:5-1:10, 1:10-1:15, 1:15-1:20, 1:20-1:25, 1:25-1:30, 1:30-1:35, 1:35-1:40, 1:40-1:45, 1:45-1:50, 1:50-1:55, 1:55-1:60, 1:60-1:65, 1:65-1:70, 1:70-1:75, 1:75-1:80, 1:80-1:85, 1:85-1:90, 1:90-1:95, or 1:95-1:100. The reaction mixture is heated to a temperature between 140-300° C., such as 140-150, 150-160, 160-170, 170-180, 180-190, 190-200, 200-210, 210-220, 220-230, 230-240, 240-250, 250-260, 260-270, 270-280, 280-290, or 290-300° C. at a heating rate is 0.1-5° C./min, such as 0.1-0.5, 0.5-1, 1-1.5, 1.5-2, 2-2.5, 2.5-3, 3-3.5, 2.5-4, 4-4.5, or 4.5-5° C./min. Once the reaction mixture reached the desired temperature, the temperature is maintained for 1-120 minutes, such as 1-10, 10-20, 20-30, 30-40, 40-50, 50-60, 60-70, 70-80, 80-90, 90-100, or 100-120 minutes. A white milky solution of synthesized TiO₂ nanocrystals is collected after the reactor is cooled down to the room temperature. The pressure of the reaction reaches 50 to 150 psi.

In an exemplary method, zirconium oxide nanocrystals are produced by a solvothermal process from a mixture of zirconium (IV) butoxide, water, and benzyl alcohol in an inert atmosphere which is sealed within an autoclave. The ratio of zirconium (IV) butoxide to water range from 1:0.1-1:10, such as 1:0.1-1:05, 1:0.5-1:1, 1:1-1:1.5, 1:1.5-1:2, 1:2-1:2.5, 1:2.5-1:3, 1:3-1:3.5, 1:3.5 to 1:4, 1:4-1:4.5, 1:4.5-1:5, 1:5-1:5.5, 1:5.5 to 1:6, 1:6-1:6.5, 1:6.5-1:7, 1:7-1:7.5, 1:7.5-1:8, 1:8-1:8.5, 1:8.5-1:9, 1:9-1:9.5, or 1:9.5-1:10. The ratio of zirconium (IV) butoxide to benzyl alcohol ranges from 1:0.1-1:100, such as 1:0.1-1:5, 1:5-1:10, 1:10-1:15, 1:15-1:20, 1:20-1:25, 1:25-1:30, 1:30-1:35, 1:35-1:40, 1:40-1:45, 1:45-1:50, 1:50-1:55, 1:55-1:60, 1:60-1:65, 1:65-1:70, 1:70-1:75, 1:75-1:80, 1:80-1:85, 1:85-1:90, 1:90-1:95, or 1:95-1:100. The reaction mixture is heated to a temperature between 140-350° C., such as 140-150, 150-160, 160-170, 170-180, 180-190, 190-200, 200-210, 210-220, 220-230, 230-240, 240-250, 250-260, 260-270, 270-280, 280-290, or 290-300° C., or 300-350° C. at a heating rate is 0.1-5° C./min, such as 0.1-0.5, 0.5-1, 1-1.5, 1.5-2, 2-2.5, 2.5-3, 3-3.5, 2.5-4, 4-4.5, or 4.5-5° C./min. Once the reaction mixture reaches the desired temperature, the temperature is maintained for 1-120 minutes, such as 1-10, 10-20, 20-30, 30-40, 40-50, 50-60, 60-70, 70-80, 80-90, 90-100, or 100-120 minutes. A white milky solution of synthesized ZrO₂ nanocrystals is collected after the reactor is cooled down to the room temperature. The pressure of the reaction reaches 100 to 500 psi.

### Core Shell Coating Process

In an exemplary method, the TiO₂ or ZrO₂ nanocrystals are obtained from the reaction mixture by centrifuged at 100-9000 rpm, such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes, such as 0-5, 5-10, 10-15, 15-20, 30-25, 25-30, 30-35, 35-40, 40-45, 45-50, 50-55 or 55-60 minutes. The supernatant is then decanted, and a purified TiO₂ or ZrO₂ nanocrystals is formed on the bottom of the centrifuge bottle as a wetcake. Solvent is added to wetcake and the centrifugation step is repeated 1-10 times, such as 1-2, 2-3, 3-4, 4-5, 5-6, 6-7, 7-8, 8-9, or 9-10 times. The wetcake is dispersed into the solvent at 5%-50% of the wetcake to the solvent by weight, such as 5%, 10%, 15%, 20%, 25%, 30%, 35%, 40%, 45% or 50% of the wetcake to the solvent by weight. At least one shell metal oxide precursor is added to the nanocrystal suspension at 0.1-500% of precursor to wet cake by weight, such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, 90%-100%, 100%-110%, 110%-120%, 120%-130%, 130%-140%, 140%-150%, 150%-200%, 200%-300%, or 300%-500% of precursor to wet cake by weight. This mixture is then heated to 50-130° C. such as 50-60, 60-70, 70-80, 80-90, 90-100, 100-110, 110-120, or 120-130° C. for 1-400 hours, such as 1-10, 10-20, 20-30, 30-40, 40-50, 50-60, 60-70, 70-80, 80-90, 90-100, 100-120, 120-150, 150-200, 200-250, 250-300, 300-350, or 340-400 hours. The reaction mixture is then cooled to room temperature upon completion. At least one other precursor for a second and consecutive shell metal oxides can be added at the same time as the first shell metal oxide precursor or after heating the first precursor for a period of time. Heating and/or application of pressure can be repeated after the addition of the second shell material.

The titanium oxide or zirconium oxide nanocrystals with at least one shell oxide coating are purified by precipitating the nanocrystal from the reaction mixture using a solvent or solvent mixture to form a milky suspension. The milky suspension obtained from the precipitation is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes such as 0-5, 5-10, 10-15, 15-20, 30-25, 25-30, 30-35, 35-40, 40-45, 45-50, 50-55, or 55-60 minutes. The supernatant is then decanted, and a wet cake of purified core shelled titanium oxide or zirconium oxide is formed at the bottom of the centrifuge bottle. Solvent is added to wetcake and the centrifugation step is repeated 1-10 times, such as 1-2, 2-3, 3-4, 4-5, 5-6, 6-7, 7-8, 8-9, or 9-10 times to yield purified core shelled titanium oxide or zirconium oxide nanocrystals. Optionally, a base or acid is present to facilitate the neutralization of excess acid or base present.

Capping of Core Shelled TiO₂ or ZrO₂

In an exemplary method, the purified core shelled TiO₂ or ZrO₂ nanocrystals is capped with at least one capping agent in a solvent. The purified core-shelled titanium oxide nanocrystal obtained as a wetcake is dispersed in a solvent of choice for capping in a round bottom flask. The wetcake is dispersed in the capping solvent at 5-80% of the wetcake to the solvent by weight such as 5%, 10%, 15%, 20%, 25%, 30%, 35%, 40%, 45%, 50%, 55%, 60%, 65%, 70%, 75%, or 80% of the wetcake to the solvent by weight. At least one capping agent is added to the nanocrystal suspension at 0.1-100% of capping agent to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, 90%-100% of capping agent to wet cake by weight. The suspension is mixed at 25-60° C. such as 25° C., or 30° C., or 35° C., or 40° C., or 45° C., or 50° C., or 55° C., or 60° C., for 5 minutes to 3 hours, such as 5 min, 10 min, 15 min, 20 min, 25 min or 30 min, 45 min, 1 h, 2, or 3 h. A base is added to the suspension at 5-30% of the wetcake to the solvent by weight, such as 5%, 10%, 15%, 20%, 25% or 30% of the wetcake to the solvent by weight. The suspension is heated at 50-130° C. such as 50-60, 60-70, 70-80, 80-90, 90-100, 100-110, 110-120, or 120-130° C. for 15-300 min such as 15-30 min, 30-60 min, 60-90 min, 90-120 min, 120-150 min, 150-180 min, 180-210 min, 210-240 min, 240-270 min, or 270-300 min.

In some embodiments, a second capping agent is added to the reaction mixture at 0.1-100% of capping agent to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, or 90%-100% of capping agent to wet cake by weight. The suspension is continued to heat at 50-130° C. such as 50-60, 60-70, 70-80, 80-90, 90-100, 100-110, 110-120, 120-130° C. for 15-300 min such as 15-30 min, 30-60 min, 60-90 min, 90-120 min, 120-150 min, 150-180 min, 180-210 min, 210-240 min, 240-270 min, or 270-300 min.

In some embodiments, an inorganic passivation agent is added to the reaction mixture after the addition steps of the first or second capping agents at 0.1-50%, of inorganic passivation agent to wet cake by weight such as 0.1-5%, 5-10%, 10-15%, 15-20%, 20-25%, 25%-30%, 30%-35%, 35%-40%, 40%-45%, or 45%-50%, of inorganic passivation agent to wet cake by weight. The suspension is continued to heat at 50-130° C. such as 50-60, 60-70, 70-80, 80-90, 90-100, 100-110, 110-120, or 120-130° C. for 15-300 min such as 15-30 min, 30-60 min, 60-90 min, 90-120 min, 120-150 min, 150-180 min, 180-210 min, 210-240 min, 240-270 min, or 270-300 min.

The reaction mixture is then cooled to room temperature to provide at least partially capped core-shelled nanocrystals. The capped core-shelled nanocrystals are purified by repeated precipitation in solvent or solvent combination to remove excess capping agent and other by-products. The capped core-shelled nanocrystals is precipitated from the reaction mixture by adding a solvent or solvent combination called an anti-solvent in a 0.1:1-3:1 solvent to reaction mixture weight-to-weight ratio, such as 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, or 2.75:1-3:1 solvent to reaction mixture weight-to-weight ratio. An anti-solvent is a solvent or solvent combination that is not compatible with the nanocrystals and causes the nanocrystals to precipitate out of a solution. This precipitate is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, 8500-9000 rpm for 0-60 minutes such as 0-5, 5-10, 10-15, 15-20, 30-25, 25-30, 30-35, 35-40, 40-45, 45-50, 50-55, 55-60 minutes. The resulting supernatant is decanted and discarded. The solids collected from the centrifuge step is then dispersed in a solvent that is compatible with the capped nanocrystals. The dispersed solids are then precipitated with an anti-solvent in a 0.1:1-3:1 anti-solvent to solvent weight-to-weight ratio such as 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, or 2.75:1-3:1 anti-solvent to solvent weight-to-weight ratio. This precipitate is collected by centrifuging at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes such as 0-5, 5-10, 10-15, 15-20, 30-25, 25-30, 30-35, 35-40, 40-45, 45-50, 50-55, 55-60 minutes. The resulting supernatant was decanted and discarded. This process is repeated if necessary. The solids are then placed in a vacuum oven to dry overnight.

The dried solids are redispersed in a 1:1 ratio of solids to solvent such as PGMEA, PGME, ETA or ethanol to create a 50% by weight loaded dispersion. The resulting dispersion is filtered through a 0.45 micron and then a 0.2-micron absolute or nominal filter.

Inorganic Treatment of the Core Shelled TiO₂ or ZrO₂ Followed by Capping

In this disclosure, terms such as inorganic treatment, inorganic passivation, alkali metal compound treatment, and inorganic salt are used interchangeably and refer to the process of treating either the core metal oxide or the core shell metal oxide nanocrystals before or after capping with a compound comprising at least one of sodium polyphosphate, lithium nitrate, sodium hypochlorite, sodium hypophosphite, sodium phosphite, lithium chloride, sodium nitrate, sodium chloride, sodium aluminum phosphate, aluminum hypophosphite sodium hexametaphosphate, calcium hypophosphite, or any hydrates thereof, or any combination thereof.

In an exemplary method, the purified core shelled TiO₂ or ZrO₂ nanocrystals is treated with an inorganic passivation agent prior to capping. The purified core-shelled nanocrystal obtained as a wetcake is dispersed in a solvent of choice for inorganic treatment in a round bottomed flask. The wetcake is dispersed in the solvent at 5-80% of the wetcake to the solvent by weight such as 5%, 10%, 15%, 20%, 25%, 30%, 35%, 40%, 45%, 50%, 60%, 70%, or 80% of the wetcake to the solvent by weight to give a white slurry. At least one inorganic passivation agent is added to the slurry at 0.1-100% of inorganic passivation agent to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, or 90%-100% of inorganic passivation agent to wet cake by weight. The slurry is mixed at 25-60° C. such as 25° C., or 30° C., or 35° C., or 40° C., or 45° C., or 50° C., or 55° C., or 60° C. for 0.1-12 hours such as 0.1-1 hour, 1-2 hours, 2-3 hours, 3-4 hours, 4-5 hours, 5-6 hours, 6-7 hours, 7-8 hours, 8-9 hours, 9-10 hours, 10-11 hours, or 11-12 hours. The treated nanocrystal is collected from the slurry by centrifugation. The slurry is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes such as 0-5, 5-10, 10-15, 15-20, 30-25, 25-30, 30-35, 35-40, 40-45, 45-50, 50-55, or 55-60 minutes. The resulting supernatant is decanted and discarded. The solids collected by centrifuge step is suspended in a solvent or solvent combination and centrifuged again. This process is repeated twice. The resulting solid is suspended in a solvent of choice for capping in a round bottomed flask. The wetcake is dispersed in the capping solvent at 5-80% of the wetcake to the solvent by weight such as 5%, 10%, 15%, 20%, 25%, 30%, 35%, 40%, 45%, 50%%, 60%, 70%, or 80% of the wetcake to the solvent by weight. The first capping agent is added to the nanocrystal suspension at 0.1-100% of capping agent to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, or 90%-100% of capping agent to wet cake by weight. The suspension is mixed at 25-60° C. such as 25° C., or 30° C., or 35° C., or 40° C., or 45° C., or 50° C., or 55° C., or 60° C. for 5 minutes to 3 hours, such as 5 min, 10 min, 15 min, 20 min, 25 min or 30 min, 45 min, 1 h, 2, or 3 h. A base is added to the suspension at 5-30% of the wetcake to the solvent by weight such as 5%, 10%, 15%, 20%, 25% or 30% of the wetcake to the solvent by weight. The suspension is heated at 50-300 min such as 50-60, 60-70, 70-80, 80-90, 90-100, 100-110, 110-120, 120-130° C. for 15-30 min, 30-60 min, 60-90 min, 90-120 min, 120-150 min, 150-180 min, 180-210 min, 210-240 min, 240-270 min, or 270-300 min.

In some embodiments, a second capping agent is added to the reaction mixture at 0.1-100% of capping agent to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, or 90%-100% of capping agent to wet cake by weight. The suspension is continued to heat at 50-130° C. such as 50-60, 60-70, 70-80, 80-90, 90-100, 100-110, 110-120, 120-130° C. for 15-300 min such as 15-30 min, 30-60 min, 60-90 min, 90-120 min, 120-150 min, 150-180 min, 180-210 min, 210-240 min, 240-270 min, or 270-300 min. [0109] in some embodiments, an inorganic passivation agent is added to the reaction mixture after the addition steps of the first or second capping agents at 0.1-50%, of inorganic passivation agent to wet cake by weight such as 0.1-5%, 5-10%, 10-15%, 15-20%, 20-25%, 25%-30%, 30%-35%, 35%-40%, 40%-45%, or 45%-50%, of inorganic passivation agent to wet cake by weight. The suspension is continued to heat at 50-130° C. such as 50-60, 60-70, 70-80, 80-90, 90-100, 100-110, 110-120, 120-130° C. for 15-300 min such as 15-30 min, 30-60 min, 60-90 min, 90-120 min, 120-150 min, 150-180 min, 180-210 min, 210-240 min, 240-270 min, or 270-300 min.

The reaction mixture is then cooled to room temperature to provide at least partially capped inorganic treated core-shelled nanocrystals. The capped inorganic treated core-shelled nanocrystal is purified by repeated precipitation in solvent or solvent combination to remove excess capping agent and other by-products. The capped inorganic treated core-shelled nanocrystals is precipitated from the reaction mixture by adding a solvent or solvent combination called an anti-solvent in a 0.1:1-3:1 solvent to reaction mixture weight-to-weight ratio such as 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, or 2.75:1-3:1 solvent to reaction mixture weight-to-weight ratio. An anti-solvent is a solvent or solvent combination that is not compatible with the nanocrystals and causes the nanocrystals to precipitate out of a solution. This precipitate is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, 8500-9000 rpm for 0-60 minutes such as 0-5, 5-10, 10-15, 15-20, 30-25, 25-30, 30-35, 35-40, 40-45, 45-50, 50-55, 55-60 minutes. The resulting supernatant is decanted and discarded. The solids collected from the centrifuge step is then dispersed in a solvent that is compatible with the capped nanocrystals. The dispersed solids are then precipitated with an anti-solvent in a 0.1:1-3:1 anti-solvent to solvent weight-to-weight ratio, such as 0.1:1-1:1, 1:1-1.25:1, 1.25:1-1.5:1, 1.5:1-1.75:1, 1.75:1-2:1, 2:1-2.25:1, 2.25:1-2.5:1, 2.5:1-2.75:1, 2.75:1-3:1 anti-solvent to solvent weight-to-weight ratio. This precipitate is collected by centrifuging at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, 8500-9000 rpm for 0-60 minutes such as 0-5, 5-10, 10-15, 15-20, 30-25, 25-30, 30-35, 35-40, 40-45, 45-50, 50-55, 55-60 minutes. The resulting supernatant is decanted and discarded. This process is repeated if necessary. The solids are then placed in a vacuum oven to dry overnight.

The dried solids are redispersed in a 1:1 ratio of solids to solvent such as PGMEA, PGME or ethanol to create a 50% by weight loaded dispersion. The resulting dispersion is filtered through a 0.45 micron and then a 0.2-micron absolute or nominal filter.

### Inorganic Treatment of the Non-Shelled Nanocrystals Followed by Core-Shell Process

In an exemplary method, the purified TiO₂ or ZrO₂ nanocrystals (no other metal oxide shell) is treated with an inorganic passivation agent prior to coating with metal oxides. The purified nanocrystals obtained as a wetcake is dispersed in a solvent of choice for inorganic treatment in a round bottomed flask. The wetcake is dispersed in the solvent at 5-80% of the wetcake to the solvent by weight such as 5%, 10%, 15%, 20%, 25%, 30%, 35%, 40%, 45%, 50%, 60%, 70%, or 80% of the wetcake to the solvent by weight to give a white slurry. At least one inorganic passivation agent is added to the slurry at 0.1-100% of inorganic passivation agent to wet cake by weight 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, or 90%-100% of inorganic passivation agent to wet cake by weight. The slurry is mixed at 25-60° C. such as 25° C., or 30° C., or 35° C., or 40° C., or 45° C., or 50° C., or 55° C., or 60° C. for 0.1-12 hours such as 0.1-1 hour, 1-2 hours, 2-3 hours, 3-4 hours, 4-5 hours, 5-6 hours, 6-7 hours, 7-8 hours, 8-9 hours, 9-10 hours, 10-11 hours, or 11-12 hours. The treated nanocrystal is collected from the slurry by centrifugation. The slurry is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes such as 0-5, 5-10, 10-15, 15-20, 30-25, 25-30, 30-35, 35-40, 40-45, 45-50, 50-55, 55-60 minutes. The resulting supernatant is decanted and discarded. The solids collected by centrifuge step is suspended in a solvent or solvent combination and centrifuged again. This process is repeated twice. The resulting solid or wetcake is suspended in a solvent of choice for oxide shell formation process.

The wetcake is dispersed into the solvent at 5-50% of the wetcake to the solvent by weight such as 5%, 10%, 15%, 20%, 25%, 30%, 35%, 40%, 45% or 50% of the wetcake to the solvent by weight for the coating process. The at least one shell metal oxide precursor is added to the nanocrystal suspension at 0.1-500% of precursor to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, 90%-100%, 100%-110%, 110%-120%, 120%-130%, 130%-140%, 140%-150%, 150%-200%, 200%-300%, or 300%-500% of precursor to wet cake by weight. This mixture is then heated to 50-130° C. such as 50-60, 60-70, 70-80, 80-90, 90-100, 100-110, 110-120, 120-130° C. for 1-400 hours such as 1-10, 10-20, 20-30, 30-40, 40-50, 50-60, 60-70, 70-80, 80-90, 90-100, 100-120, 120-150, 150-200, 200-250, 250-300, 300-350, or 340-400 hours. The reaction mixture is then cooled to room temperature upon completion.

The inorganic treated nanocrystals with at least one oxide shell are purified by precipitating the nanocrystal from the reaction mixture using a solvent or solvent mixture to form a milky suspension. The milky suspension obtained from the precipitation is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes such as 0-5, 5-10, 10-15, 15-20, 30-25, 25-30, 30-35, 35-40, 40-45, 45-50, 50-55, or 55-60 minutes. The supernatant is then decanted, and a wet cake of purified as inorganic treated nanocrystals with the oxide shell is formed at the bottom of the centrifuge bottle. Solvent is added to wetcake and the centrifugation step is repeated 1-10 times such as 1-2, 2-3, 3-4, 4-5, 5-6, 6-7, 7-8, 8-9, or 9-10 times to yield purified inorganic treated core shelled nanocrystals.

Optionally, a base or acid is present to facilitate the neutralization of excess acid or base present.

In some embodiments, the nanocrystal from this process is at least partially capped with a capping agent following the process described in ‘Capping of core shelled synthesized TiO₂ or ZrO₂’.

### Capping of the Inorganic Treated Nanocrystals (Non-Core Shell)

In an exemplary method, the purified TiO₂ or ZrO₂ nanocrystals (no metal oxide shell) are treated with an inorganic passivation agent prior to coating with metal oxides. The purified nanocrystals obtained as a wetcake is dispersed in a solvent of choice for inorganic treatment in a round bottomed flask. The wetcake is dispersed in the solvent at 5-80% of the wetcake to the solvent by weight such as 5%, 10%, 15%, 20%, 25%, 30%, 35%, 40%, 45%, 50%, 60%, 70%, or 80% of the wetcake to the solvent by weight to give a white slurry. At least one inorganic passivation agent is added to the slurry at 0.1-100% of inorganic passivation agent to wet cake by weight such as 0.1-5%, 5-10%, 10-15%, 15-20%, 20-25%, 25%-30%, 30%-35%, 35%-40%, 40%-45%, 45%-50%, 50%-55%, 55%-60%, 60%-70%, 70%-80%, 80%-90%, or 90%-100% of inorganic passivation agent to wet cake by weight. The slurry is mixed at 25-35° C. such as 25° C. or 30° C. or 35° C. for 0.1-12 hours such as 0.1-1 hour, 1-2 hours, 2-3 hours, 3-4 hours, 4-5 hours, 5-6 hours, 6-7 hours, 7-8 hours, 8-9 hours, 9-10 hours, 10-11 hours, or 11-12 hours. The treated nanocrystal is collected from the slurry by centrifugation. The slurry is centrifuged at 100-9000 rpm such as 100-500, 500-1000, 100-1500, 1500-2000, 2000-2500, 2500-3000 rpm, 3000-3500, 3500-4000, 4000-4500, 4500-5000, 5000-5500, 5500-6000, 6000-6500, 6500-7000, 7000-7500, 7500-8000, 8000-8500, or 8500-9000 rpm for 0-60 minutes such as 0-5, 5-10, 10-15, 15-20, 30-25, 25-30, 30-35, 35-40, 40-45, 45-50, 50-55, or 55-60 minutes. The resulting supernatant is decanted and discarded. The solids collected by centrifuge step is suspended in a solvent or solvent combination and centrifuged again. This process is repeated twice. The resulting solid or wetcake is suspended in a solvent of choice for capping in a round bottomed flask. The nanocrystal from this process is at least partially capped with a capping agent following the process described in ‘Capping of core shelled TiO₂ or ZrO₂’.

Core-Shelled TiO₂ and ZrO₂ Nanocrystal

The crystallinity of the nanocrystals described in the present disclosure is analyzed by X-ray Powder Diffraction. The XRD patterns of the titanium oxide and zirconium oxide nanocrystals comprising a metal oxide shell match the original anatase phase and tetragonal phase, respectively, indicating that the shell process and capping process has not altered the original phase.

The at least partially capped titanium dioxide nanocrystals comprising a layer of a metal oxide shell and/or treated with an inorganic passivation agent of the present disclosure has an average particle size less than 30 nm as measured by TEM. Preferably the particle size is between 1-4 nm, or 4-6 nm, or 6-8 nm, or 8-10 nm, or 10-12 nm, or 12-14 nm, or 14-16 nm, or 16-18 nm, or 18-20 nm, or 20-25 nm, or 25-30 nm as measured by TEM.

The at least partially capped zirconium oxide nanocrystals that comprising a metal oxide shell and/or treated with an inorganic passivation agent of the present disclosure has an average particle size less than 30 nm as measured by TEM. Preferably the particle size is between 1-4 nm, or 4-6 nm, or 6-8 nm, or 8-10 nm, or 10-12 nm, or 12-14 nm, or 14-16 nm, or 16-18 nm, or 18-20 nm, or 20-25 nm, or 25-30 nm as measured by TEM.

The at least partially capped titanium dioxide nanocrystals comprising a metal oxide shell and/or treated with an inorganic passivation agent of the present disclosure wherein the thickness of the metal oxide shell is less than 5 nm as measured by TEM. Preferably the thickness of the shell is between 0.05-0.1 nm, 0.1-0.2 nm, 0.2-0.3 nm, 0.3-0.4 nm, 0.4-0.5 nm, 0.5-0.6 nm, 0.6-0.7 nm, 0.7-0.8 nm, 0.8-0.9 nm, 0.9-1.0 nm, 1.0-1.2 nm, 1.2-1.4 nm, 1.4-1.6 nm, 1.6-1.8 nm, 1.8-2.0 nm, 2.0-2.2 nm, 2.2-2.4 nm, 2.4-2.6 nm, 2.6-2.8 nm, 2.8-3.0 nm, 3.0-3.2 nm, 3.0-3.2 nm, 3.2-3.4 nm, 3.4-3.6 nm, 3.6-3.8 nm, 3.8-4.0 nm, 4.0-4.2 nm, 4.2-4.4 nm, 4.4-4.6 nm, 4.6-4.8 nm, 4.8-5.0 nm as measured by TEM.

The at least partially capped zirconium oxide nanocrystals comprising a metal oxide shell and/or treated with an inorganic passivation agent of the present disclosure wherein the thickness of the metal oxide shell is less than 5 nm as measured by TEM. Preferably the thickness of the shell is between 0.05-0.1 nm, 0.1-0.2 nm, 0.2-0.3 nm, 0.3-0.4 nm, 0.4-0.5 nm, 0.5-0.6 nm, 0.6-0.7 nm, 0.7-0.8 nm, 0.8-0.9 nm, 0.9-1.0 nm, 1.0-1.2 nm, 1.2-1.4 nm, 1.4-1.6 nm, 1.6-1.8 nm, 1.8-2.0 nm, 2.0-2.2 nm, 2.2-2.4 nm, 2.4-2.6 nm, 2.6-2.8 nm, 2.8-3.0 nm, 3.0-3.2 nm, 3.0-3.2 nm, 3.2-3.4 nm, 3.4-3.6 nm, 3.6-3.8 nm, 3.8-4.0 nm, 4.0-4.2 nm, 4.2-4.4 nm, 4.4-4.6 nm, 4.6-4.8 nm, 4.8-5.0 nm as measured by TEM.

In some embodiments, the at least partially capped titanium oxide or zirconium oxide nanocrystals comprising a metal oxide shell and/or treated with an inorganic passivation agent of the present disclosure can be characterized in that the core metal oxide has a narrow particle size distribution, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

In some embodiments, the at least partially capped titanium oxide or zirconium oxide nanocrystals comprising a metal oxide shell and/or treated with an inorganic passivation agent of the present disclosure can be characterized in that the core-shell metal oxide has a narrow particle size distribution, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

In some embodiments, the at least partially capped core shell nanocrystals and/or nanocrystals treated with an inorganic passivation agent of the present disclosure can be characterized in that the atomic ratio of the shell metal oxide to the core metal oxide is less than 0.1, less than 0.2, less than 0.3, less than 0.4, less than 0.5, less than 0.6, less than 0.7, less than 0.8, less than 0.9, less than 1, less than 2, less than 3, as measured by SEM EDX.

In some embodiments, the at least partially capped titanium dioxide nanocrystals comprising a ZrO₂ shell and/or treated with an inorganic passivation agent of the present disclosure can be characterized in that the atomic ratio of Zr/Ti for the core TiO₂ nanocrystals with a shell of ZrO₂ material is less than 0.1, less than 0.2, less than 0.3, less than 0.4, less than 0.5, less than 0.6, less than 0.7, less than 0.8, less than 0.9, less than 1, less than 2, less than 3, as measured by SEM EDX.

In some embodiments, the at least partially capped titanium dioxide nanocrystals comprising a metal oxide shell and/or treated with an inorganic passivation agent of the present disclosure, can be characterized in that the metal oxide shell comprises of ZrO₂ and encapsulates the TiO₂ core completely or partially.

In some embodiments, the at least partially capped zirconium dioxide nanocrystals comprising a metal oxide shell and/or treated with an inorganic passivation agent of the present disclosure, can be characterized in that the metal oxide shell comprises of ZrO₂ and encapsulates the ZrO₂ core completely or partially.

In some embodiments, the at least partially capped titanium dioxide nanocrystals comprising a metal oxide shell and/or treated with an inorganic passivation agent of the present disclosure, can be characterized in that the shell metal oxide comprises of ZrO₂ and encapsulates 1 or more of the core TiO₂ nanocrystals to form a single particle.

In some embodiments, the at least partially capped zirconium dioxide nanocrystals comprising a metal oxide shell and/or treated with an inorganic passivation agent of the present disclosure, can be characterized in that the shell metal oxide comprises of ZrO₂ and encapsulates 1 or more of the core ZrO₂ nanocrystals to form a single particle.

In some embodiments, the at least partially capped titanium dioxide nanocrystals comprising a metal oxide shell and/or treated with an inorganic passivation agent of the present disclosure, can be characterized in that the metal oxide shell comprises ZrO₂ material which can be crystalline or amorphous.

In some embodiments, the at least partially capped zirconium dioxide nanocrystals comprising a metal oxide shell and/or treated with an inorganic passivation agent of the present disclosure, can be characterized in that the metal oxide shell comprises of ZrO₂ material and can be crystalline or amorphous.

In some embodiments, the presently disclosed nanocrystals have a core-shell structure, comprising a core and an outer shell, wherein the core is TiO₂ nanocrystals and is at least partially encapsulated by the outer shell comprising a metal oxide and/or treated with an inorganic passivation agent additionally demonstrates UV stability. When exposed to UV irradiation at and above 320 nm, or at and above 340 nm, or at and above 365 nm, or at and above 390 nm, or at and above 405 nm, or at and above 450 nm, or at and above 500 nm for 1-2 min, 2-5 min, 5-10 minutes, or 10-30 minutes, or 30-60 minutes, or 1-2 hours, 2-8 h, 8-48 h, 48-72 h, 72-100 h, 100-200 h, 200-300 h, 300-400 h, 400-500 h, 500-600 h, 600-700 h, 700-800 h, 800-900 h, 900-1000 h or >1000 h the TiO₂ nanocrystals comprising a metal oxide shell undergoes less change in optical properties and refractive index compared to the nanocrystal without the oxide shell. These nanocrystals show less than 5%, less than 10%, less than 15%, less than 20%, less than 30%, less than 40%, or less than 50% change in b* when the b* of a film comprising the core shell nanocrystals is measured using a hazemeter before and after the UV exposure. These nanocrystals show change in refractive index less than 0.001, or less than 0.002, or less than 0.004, or less than 0.006, or less than 0.008, or less than 0.01, or less than 0.012, or less than 0.015, or less than 0.018, or less than 0.02, or less than 0.022, or less than 0.025, or less than 0.028, or less than 0.03, or less than 0.035, or less than 0.04, or less than 0.045, or less than 0.05, or less than 0.055, or less than 0.06, or less than 0.065, or less than 0.07, or less than 0.075, or less than 0.08, or less than 0.085, or less than 0.09, or less than 0.095, or less than 0.1, at 520 nm for films that are, less than 1 microns thick, or 1-2 microns thick, or 2-4 microns thick, or 4-6 microns thick, or 6-8 microns thick, or 8-10 microns thick, or 10-20 microns thick, or 20-30 microns thick as measured by a prism coupler or an ellipsometer when measured before and after the UV exposure. These nanocrystals additionally show a percent change in film thickness less than 0.1, or less than 0.2, or less than 0.3, or less than 0.4, or less than 0.5, or less than 0.6, or less than 0.7, or less than 0.8, or less than 0.9, or less than 1.0, or less than 1.5, or less than 2.0, or less than 2.5, or less than 3.0 or less than 3.5 or less than 4.0 or less than 4.5, or less than 5, or less than 10, or less than 15, or less than 20, or less than 25, or less than 50 and a change in % haze less than 0.001, or less than 0.002, or less than 0.004, or less than 0.006, or less than 0.008, or less than 0.01, or less than 0.012, or less than 0.015, or less than 0.018, or less than 0.02, or less than 0.022, or less than 0.025, or less than 0.028, or less than 0.03, or less than 0.035, or less than 0.04, or less than 0.045, or less than 0.05, or less than 0.055, or less than 0.06, or less than 0.065, or less than 0.07, or less than 0.075, or less than 0.08, or less than 0.085, or less than 0.09, or less than 0.095, or less than 0.1, for films incorporating these nanocrystals that are less than 1 microns thick, or 1-2 microns thick, or 2-4 microns thick, or 4-6 microns thick, or 6-8 microns thick, or 8-10 microns thick, or 10-20 microns thick, or 20-30 microns thick as measured by hazemeter when measured before and after the UV exposure.

In some embodiments, the presently disclosed core-shell nanocrystals comprising TiO₂ nanocrystals comprising a metal oxide shell and/or treated with an inorganic passivation agent additionally demonstrates thermal stability. When exposed to temperatures below 120° C., or 120 C-175° C., or 175 C-200° C., or 200 C-250° C., or 250 C-300° C., or above 300° C. in air, nitrogen, or under vacuum for 5 minutes or longer, or 10 minute or longer, or 30 minutes or longer, or 60 minutes or longer, or 120 minutes or longer, the core shell nanocrystals undergo less discoloration compared to the nanocrystals without the oxide shell or inorganic treatment. In a scale of 0-6 in discoloration where ‘0’ indicates no discoloration and ‘6’ indicates the most discoloration such as brown color, the nanocrystals show a discoloration of 0-1, 1-2, 2-3 when compared to the nanocrystal with no shell/inorganic treatment which shows a discoloration of ‘6’.

### TiO₂ Nanocrystal Dispersions

The present disclosure provides a composition containing a dispersion of any of the capped titanium oxide or zirconium oxide nanocrystals and capped core shell TiO₂ and ZrO₂ nanocrystals comprising a metal oxide shell and the capped titanium oxide or zirconium oxide nanocrystals and core shell nanocrystals that are treated with an inorganic passivation reagent in a solvent or at least one monomer. The capped nanocrystals are present in the solvent in an amount of less than 10% by weight, or 10%-20% by weight, or 20%-30% by weight, or 30%-40% by weight, or 40%-50% by weight, or 50%-60% by weight, or 60%-70% by weight, or 70%-80% by weight, or 80%-90% by weight, or 90%-95% by weight of the total dispersion. The solvent includes alcohols, such as, benzyl alcohol, phenol, oleyl alcohol, butanol, propanol, isopropanol, ethanol, butoxy ethanol, butoxy propanol, methanol, 2-(isopentyloxy)ethanol, 2-propoxy-propanol (PnP), 2-(hexyloxy)ethanol; ethers and cyclic ethers, such as: tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether; glycols such as: diethylene glycol, dipropylene glycol; ketones and cyclic ketones, such as: acetone; esters, such as: propylene glycol methyl ether acetate (PGMEA), ethyl lactate (EL), methyl acetates, ethyl acetates (ETA), butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate; aromatics such as: benzene, toluene; and water and any combination or mixture thereof.

One common technique to characterize the size and size distribution of nanocrystals in dispersion is Dynamic Light Scattering (DLS). DLS usually measures nanocrystals dispersed in a liquid transparent to the measuring wavelength. In this technique, the liquid sample with proper concentration is kept in a plastic, glass, or fused silica cuvette, a laser beam is scattered off the liquid sample, and the time dependence of the scattered laser light, which is a result of the Brownian motion of the nanocrystals, is measured and the size and size distribution of the nanocrystal can be calculated. The result is usually the size distribution of the nanocrystals with equivalent diameter as the x-axis, the y-axis can represent scattering intensity, the volume of the scattering nanocrystals, or the number of scattering nanocrystals. The measured size often includes the size of the nanocrystals and the size of the capping agent and/or solvent group and/or precursor group along with a thin layer of solvent (solvent shell), therefore the actual nanocrystal size is often smaller than measured by DLS. In the present disclosure, except when noted as “as measured by DLS”, all references to nanocrystal size and size distributions refer to the nanocrystal size measured by TEM and not the nanocrystal size plus capping agent and/or solvent group and/or precursor group or nanocrystal plus capping agent and/or solvent group and/or precursor group plus solvent shell. D9999 is defined as the particle size of 99.99% of the particles in the measured dispersion are less than reported value (in nanometers), as measured by volume. There are a variety of DLS spectrometers available, each vendor often develops its own proprietary methodology and algorithm, the results may not be interchangeable, the models that are specifically used to acquire the data in this disclosure is a Malvern Zetasizer Nano S DLS.

A typical DLS measurement of particle size and size distribution by intensity or by volume of a nanocrystal dispersion is collected at 5 wt % nanocrystals in a solvent.

Average Particle size as measured by intensity of any of the capped titanium oxide or zirconium oxide nanocrystals and core shelled and/or inorganic treated TiO₂ and ZrO₂ nanocrystals described in this disclosure when dispersed at 5% by weight in a solvent is less than 100 nm as measured by Dynamic Light Scattering. Preferably the particle size is between 1-4 nm, or 4-6 nm, or 6-8 nm, or 8-10 nm, or 10-12 nm, or 12-14 nm, or 14-16 nm, or 16-18 nm, or 18-20 nm, or 20-25 nm, or 25-30 nm, or 30-35 nm, or 35-40 nm, or 40-45 nm, or 45-50 nm, or 50-55 nm, or 55-60 nm, or 60-65 nm, or 65-70 nm, or 75-80 nm, or 80-85 nm, or 85-90 nm, or 90-95 nm, or 95-100 nm, as measured by DLS.

Average Particle size as measured by volume of any of the capped titanium oxide or zirconium oxide nanocrystals and core shelled and/or inorganic treated TiO₂ and ZrO₂ nanocrystals described in this disclosure when dispersed at 5% by weight in a solvent is less than 100 nm as measured by Dynamic Light Scattering. Preferably the particle size is between 1-4 nm, or 4-6 nm, or 6-8 nm, or 8-10 nm, or 10-12 nm, or 12-14 nm, or 14-16 nm, or 16-18 nm, or 18-20 nm, or 20-25 nm, 25-30, or 30-35 nm, or 35-40 nm, or 40-45 nm, or 45-50 nm, or 50-55 nm, or 55-60 nm, or 60-65 nm, or 65-70 nm, or 75-80 nm, or 80-85 nm, or 85-90 nm, or 90-95 nm, or 95-100 nm as measured by DLS.

D9999 as measured by volume of any of the capped titanium oxide, zirconium oxide nanocrystals, core-shell nanocrystals, inorganic treated nanocrystals, core-shell and inorganic treated nanocrystals described in this disclosure when dispersed 5% by weight in a solvent is <500 nm as measured by Dynamic Light Scattering. Preferably D9999 is <20, <30, <40, <50, <60, <70, <80, <90, <100, <110, <120, <130, <140, <150, <160, <170, <180, <190, <200, <220, <150, <240, <260, <280, <300, <400 or <500 nm as measured by DLS.

In one embodiment the at least partially capped core shell nanocrystals comprising the core TiO₂ or ZrO₂ nanocrystals and a metal oxide shell comprising ZrO₂ and/or treated with an inorganic passivation agent of the present disclosure, have a narrow particle size distribution, which is characterized by D9999 is <20, <30, <40, <50, <60, <70, <80, <90, <100, <110, <120, <130, <140, <150, <160, <170, <180, <190, <200.

One common technique to characterize the % solids, % inorganics and the % organics in a nanocrystal dispersions or nanocrystal formulation is Thermogravimetric Analysis (TGA). Nanocrystal formulation in the present disclosure is any dispersion that contains any capped nanocrystals described in this disclosure, monomers, oligomers, polymer and other additives. Optionally, the formulation will contain a solvent or combination of solvents. In this technique, the nanocrystals dispersion or nanocrystal polymer nanocomposite is kept in a crucible and heated up from room temperature up to about 800° C., while the weight is monitored. The organic solvent, polymer, and capping agent will decompose at high, and usually different temperatures, leaving only the inorganic nanocrystals behind. The relative weight percentage of various ingredients in the original sample can be obtained. TGA results usually generate plots with temperature as the x-axis and the relative weight percentage as the y-axis. There are a variety of TGA instruments available, they are all based on similar principles and when operated properly, the results are interchangeable. The model that was specifically used to acquire the data in this disclosure is a TA Instrument TGA Q500.

The presently disclosed dispersion is analyzed using a TA instrument Q500 thermal gravimetric analyzer (TGA) to determine the organic, inorganic, and solid content of capped nanocrystal dispersion. The percent mass at 200° C. (M200C) relative to the initial mass is regarded as capped nanocrystals present in the dispersion and the percent mass at 700° C. (M700C) relative to the initial mass is regarded as inorganic portion of the capped nanocrystal, i.e. inorganic solid content. The organic content of the capped nanocrystals is defined as the difference between the percent mass at 200° C. and at 700° C. divided by percent mass at 200° C., i.e. % Organics=(M200C−M700C)/M200C.

The presently disclosed formulations are analyzed using a TA instrument Q500 thermal gravimetric analyzer (TGA). The TGA is run with nanocrystal dispersions in a solvent with boiling point <200C to determine the organic content of capped nanocrystals. The percent mass at 200° C. relative to the initial mass is regarded as capped nanocrystals and the percent mass at 700° C. relative to the initial mass is regarded as inorganic portion of the capped nanocrystal, i.e., inorganic solid content. The percent organics of capped nanocrystals (% Org) is defined as the difference between the percent mass at 200° C. (M200C) and at 700° C. (M700C) divided by the percent mass at 200° C.:

% Org=(M200C−M700C)/M200C×100%

For a nanocomposite or a formulation, the percent solids (% S) is calculated from the inorganic content of the nanocomposite and organic content of the capped nanocrystals measured in solvent:

% S=M700C/(100%−% Org)×100%

The solid content of the presently disclosed dispersions comprising the capped titanium oxide, zirconium oxide nanocrystals, core shell TiO₂ and ZrO₂ nanocrystals comprising a metal oxide shell, and nanocrystals with inorganic treatment is typically 0-93% such as 0-10%, or 10-20%, or 20-30%, or 30-40%, or 40-50%, or 50-60%, or 60-70%, or 70-80%, or 80-90%, or 90-93%, as measured by TGA.

The inorganic solid content of the presently disclosed dispersion comprising the capped titanium oxide, zirconium oxide nanocrystals, core shell TiO₂ and ZrO₂ nanocrystals comprising a metal oxide shell, and nanocrystals with inorganic treatment is typically 0-93% such as 0-10%, or 10-20%, or 20-30%, or 30-40%, or 40-50%, or 50-60%, or 60-70%, or 70-80%, or 80-90%, or 90-93% as measured by TGA.

The organic content of the presently disclosed dispersion comprising the capped titanium oxide, zirconium oxide nanocrystals, core shell TiO₂ and ZrO₂ nanocrystals comprising a metal oxide shell, and nanocrystals with inorganic treatment is typically 0-25% such as 0-5%, or 5-10%, or 10-15%, or 15-20%, or 20-25%, or less than 5%, or less than 8% or less than 10%, less than 12%, or less than 14% or less than 16%, less than 18%, or less than 20% or less than 20%, less than 25% of the capped nanocrystals, as measured by TGA.

The organic content of the capped titanium oxide, zirconium oxide nanocrystals, core shell TiO₂ and ZrO₂ nanocrystals comprising a metal oxide shell, and nanocrystals with inorganic treatment is typically 0-25% such as 0-5%, or 5-10%, or 10-15%, or 15-20%, or 20-25%, or less than 5%, or less than 8% or less than 10%, less than 12%, or less than 14% or less than 16%, less than 18%, or less than 20% or less than 20%, less than 25% of the capped nanocrystals, as measured by TGA.

The presently disclosed titanium oxide or zirconium oxide nanocrystals and core shell TiO₂ and ZrO₂ nanocrystals dispersed in a solvent, monomer, polymer or as a formulation are storage stable for at least 1 week, or 2 weeks, or 3 weeks, or 4 weeks, or 3 months, or at least 5 months, or at least 6 months, or at least 7 months, or at least 8 months, or at least 9 months, or at least 10 months, or at least 11 months, or at least 1 year, or at least 2 years or at least 3 years, when the dispersion is stored at a temperature in the range of 18-25° C. without deliberate shaking or mixing of the dispersion.

### Formulation Components and Properties

The present disclosure provides a solvent-containing and/or solvent-free, nanoimprintable, inkjettable and spin coatable, high-transparency, high-RI, formulations comprising at least partially capped titanium dioxide or zirconium oxide nanocrystals comprising a layer of a metal oxide shell and/or treated with an inorganic passivation agent, dispersed in a monomer, oligomer, polymer or mixtures thereof. Said formulations optionally include, a solvent, a curing agent, an adhesion promoter, a wetting agent, a leveling agent, a dispersing agent, a viscosity modifier, organic dopants and an antioxidant. These formulations make it possible to produce nanocomposites and thin film coatings with high refractive indices and high optical transparency.

The acrylic monomer, oligomer, and/or polymer of presently disclosed formulation can include benzyl (meth)acrylate (BA and BMA), trimethylolpropane tri(meth)acrylate (TMPTA and TMPTMA), trimethylolpropane ethoxylate tri(meth)acrylate (EOTMPTA and EOTMPTMA), 1,6-hexanediol di(meth)acrylate (HDDA and HDDMA), di(ethyleneglycol) di(meth)acrylate (DEGDA and DEGDMA), ethylene glycol diacrylate, glycerol 1,3-diglycerolate diacrylate, tri(propylene glycol) diacrylate, 1,6-hexanediol ethoxylate diacrylate, ethylene glycol phenyl ether (meth)acrylate (PEA and PEMA), 2-hydroxy-3-phenoxypropyl acrylate (HPPA), 2-hydroxy-3-phenoxypropyl methacrylate (HPPMA), 2-phenoxy benzyl acrylate (PBA), biphenyl methacrylate (BPMA), isobornyl acrylate (IBA), 2-phenylphenol methacrylate (PPMA), isobutyl acrylate (IBA), 2-phenylethyl acrylate (2-PEA), 2-(phenylthio)ethyl acrylate (PTEA), tris(2-hydroxy Ethyl)isocyanurate triacrylate (THEICTA or M370), Bisphenol A Glycerolate Dimethacrylate, esters with acrylic acid (OPPEOA), 9,9-Bis[4-(2-acryloyloxyethyloxy)phenyl]fluorene or bisfluorene diacrylate in OPPEOA (HR6042), Bisphenol A Ethoxylate diacrylates, Bisphenol A propoxylate diacrylate, Bisphenol F ethoxylate (2 EO/phenol) diacrylate, Bisphenol A glycerolate diacrylates, bisphenol A ethoxylate dimethacrylate, Ethoxylated (4) bisphenol A diacrylate (SR-601), Biphenol A ethoxylate diacrylate(SR-349), Tris(2-acryloyloxy)ethyl}isocyanurate, tricyclodecane dimethanol diacrylate, cresol novolac epoxy acrylate (CN112C60), tri(ethyleneglycol) diacrylate, ethylene glycol diacrylate, Poly(ethylene glycol) diacrylate, Glycerol 1,3-diglycerolate diacrylate, and combinations thereof.

In some preferred embodiments, the monomer, oligomer and/or polymer can be selected from, 2-phenylethyl acrylate (2-PEA), biphenyl methacrylate (BPMA), 2-phenoxy benzyl acrylate (PBA), trimethylolpropane tri(meth)acrylate (TMPTA and TMPTMA), tris(2-hydroxy ethyl)isocyanurate triacrylate (THEICTA), 9,9-Bis[4-(2-acryloyloxyethyloxy)phenyl]fluorene or bisfluorene diacrylate in OPPEOA (HR6042), and combinations thereof.

The vinyl monomer, oligomer, and/or polymer of presently disclosed formulation can include N-vinyl pyrrolidone (NVP), phenyl norborene, styrene (STY), 4-methylstyrene, 4-vinylanisole, divinylbenzene or combinations thereof.

The capped nanocrystals are present in the monomer in an amount of less than 10% by weight, or 10%-20% by weight, or 20%-30% by weight, or 30%-40% by weight, or 40%-50% by weight, or 50%-60% by weight, or 60%-70% by weight, or 70%-80% by weight, or 80%-90% by weight, or 90%-95% by total weight of the monomer, oligomer and polymer.

The presently disclosed formulation optionally includes an organic dopant to increase the refractive index of the film or coating. The organic dopant, if present, includes phenanthrene (PhA), 9-cyanophenanthrene, triphenyl methane, benzoquinoline, 9-vinylcarbazole and combinations thereof.

Curing agents of the presently disclosed formulation typically comprise a photopolymerization initiator. Any photopolymerization initiator, provided that it doesn't limit optical and physical performance of the nanocomposite, can be used as long as it is capable of producing an active species, such as a radical with light (UV) energy. Examples of photopolymerization initiator curing agents include amines such as Ebecryl© P115, or benzophenone and its derivatives such as Ebecryl® P39, benzophenone, SpeedCure BEM (Lambson USA Ltd, Rutherford, CT, USA) or organophosphines such as diphenyl(2,4,6-trimethylbenzoyl)-phosphine oxide (TPO), Irgacure® 819, or Irgacure© 184 (BASF USA, Florham Park, NJ, USA). The formulation comprises a single photopolymerization initiator or any combination thereof. Although the formulations described herein focus on the application of UV radiation for cure, thermal cure is entirely possible with appropriate thermo-initiators, such as 2,2-Azobis(2-methylpropionitrile) (AIBN).

A combination of more than one curing agent is advantageous in certain circumstances known to one of ordinary skill.

The amount of curing agent of presently disclosed formulation is typically in an amount of less than 0.5% by total weight of the monomer, oligomer, and/or polymer, or 0.5%-1% by total weight of the monomer, oligomer, and/or polymer, or 1%-2% by total weight of the monomer, oligomer, and/or polymer, or 2%-3% by total weight of the monomer, oligomer, and/or polymer, or 3%-4% by total weight of the monomer, oligomer, and/or polymer, or 4%-5% by total weight of the monomer, oligomer, and/or polymer, or 5%-6% by total weight of the monomer, oligomer, and/or polymer, or 6%-7% by total weight of the monomer, oligomer, and/or polymer, or 7%-8% by total weight of the monomer, oligomer, and/or polymer, or 8%-15% by total weight of the monomer, oligomer, and/or polymer.

The adhesion promoter, if present is selected from organo-metallic compounds, such as organo functional silanes, or from functionalized monomers and oligomers. Some organo functional silane adhesion promoters that are suitable contain amino or methacryloxy groups. Exemplary silane adhesion promoters include, but are not limited to 3-aminopropyltriethoxysilane, 3-[(methacryloyloxy)propyl]trimethoxysilane, ureidopropyltrimethoxysilane, and trimethoxy[3-(methylamino)propyl]silane, AP3000 (Dow Chemical). Functionalized monomer and oligomer adhesion promoters include, but are not limited to, CN820, CN146 (Sartomer Americas, Exton, PA, USA), SR9051, SR9053 (Sartomer Americas, Exton, PA, USA), and Ebecryl 171 (Allnex USA Inc., Wallingford, CT, USA).

Adhesion promoters of the presently disclosed formulation can be present in an amount of less than 0.5% by weight of the monomer, oligomer, and/or polymer, or 0.5-1% by weight of the monomer, oligomer, and/or polymer, or 1-5% by weight of the monomer, oligomer, and/or polymer, or 5-10% by weight of the monomer, oligomer, and/or polymer, or 10-15% by weight of the monomer, oligomer, and/or polymer, or 15-30% by weight of the monomer, oligomer, and/or polymer.

In some embodiments, a surfactant, which can act as a wetting agent, leveling agent, defoaming agent and dispersing agent is present to reduce the surface tension of the formulation and thereby improve the flow properties of the formulation to produce a more uniform dried coating surface. The surfactant is non-ionic, anionic, or a combination thereof. Representative examples of suitable wetting agents include but are not limited to siloxane surfactants such as BYK-331, BYK-333, BYK-377, BYK-378, (BYK Chemie, GMBH) and fluoro-surfactants such as Novec 4430, Novec 4432, and Novec 4434 (3M, St. Paul, MN, USA), and Capstone FS-3100 (The Chemours Company, Wilmington, DE, USA).

Examples of leveling agent, if present, are a polyacrylate compound such as BYK-352, BYK-353, BYK-356, and BYK-361N; an aralkyl modified polymethylalkylsiloxane, such as BYK-322, BYK-323, and BYK-350 (BYK Chemie, GMBH) and a polyether-modified, acryl functional siloxane, such as BYK-UV3530. Examples of the dispersing agent include, without limitation, polyalkylene glycols and esters thereof, polyoxyalkylenes, polyhydric alcohol ester alkylene oxide addition products, alcohol alkylene oxide addition products, sulfonate esters, sulfonate salts, carboxylate esters, carboxylate salts, alkylamide alkylene oxide addition products, alkyl amines, and the like, and are used singularly or as a mixture of two or more. Commercially available examples of the dispersing agent include without limitation DISPERBYK-101, DISPERBYK-130, DISPERBYK-140, DISPERBYK-160, DISPERBYK-161, DISPERBYK-162, DISPERBYK-163, DISPERBYK-164, DISPERBYK-165, DISPERBYK-166, DISPERBYK-170, DISPERBYK-171, DISPERBYK-182, DISPERBYK-2000, DISPERBYK-2001 (BYK Chemie, GMBH), Solsperse 32000, Solsperse 36000, Solsperse 28000, Solsperse 20000, Solsperse 41000, and Solsperse 45000 (Lubrizol, Wickliffe, OH, USA).

In some embodiments, the amount of surfactant of the presently disclosed formulation, for the purpose of improving wetting properties, is in amount of less than 0.05% by weight of the total formulation, or 0.05-0.1% by weight of the total formulation, or 0.1-0.5% by weight of the total formulation, or 0.5-1% by weight of the total formulation, or 1-2% by weight of the total formulation, or 2-5% by weight of the total formulation. For the purposes of aiding in dispersion the amount of surfactant of the presently disclosed formulation varies depending on the material being dispersed. The amount of dispersing agent is less than 3% by weight of the material being dispersed or 3-5% by weight of the material being dispersed, or 5-10% by weight of the material being dispersed, or 10-20% by weight of the material being dispersed, or 20-40% by weight of the material being dispersed, or 40-60% by weight of the material being dispersed, or 60-80% by weight of the material being dispersed, or 80-100% by weight of the material being dispersed, or 100-150% by weight of the material being dispersed.

Antioxidant agents of the presently disclosed formulation, if present, can include at least one primary antioxidant. This primary antioxidant is typically selected from sterically hindered phenols, such as Irganox 1010, Irganox 1076, SongNox® 1076, SongNox® 2450 or phenolic phosphites such as SongNox® 1680 or phosphines such as Irgaphos 168 (BASF USA, Florham Park, NJ, USA) or aromatic secondary amines or hindered amines such as SongLight® 6220 (Songwon Americas, Friendwood, TX, USA).

Formulations of present disclosure optionally include UV absorbers such as TINUVIN 405 (T405), a solid triazine-based UV absorber for coatings and Tinuvin 400. The amount of UV absorbers of presently disclosed formulation is generally less than 0.5% by weight of the total formulation, or 0.5%-1% by weight of the total formulation, or 1%-2% by weight of the total formulation, or 2%-3% by weight of the total formulation, or 3%-4% by weight of the total formulation, or 4%-5% by weight of the total formulation, or 5%-6% by weight of the total formulation, or 6%-7% by weight of the total formulation, or 7%-8% by weight of the total formulation or 8%-10% by weight of the total formulation.

Formulations of the present disclosure optionally contain at least one secondary antioxidant. This secondary antioxidant is preferably chosen from compounds comprising at least one unit formed from a sulfur atom linked to two carbon atoms. Representative examples of the secondary antioxidant are di(t-butyl) hydroxyphenylamino bisoctylthiotriazine and Irganox PS800 (BASF USA, Florham Park, NJ, USA).

The amount of anti-oxidant of presently disclosed formulation is generally less than 0.5% by weight of the total formulation, or 0.5%-1% by weight of the total formulation, or 1%-2% by weight of the total formulation, or 2%-3% by weight of the total formulation, or 3%-4% by weight of the total formulation, or 4%-5% by weight of the total formulation, or 5%-6% by weight of the total formulation, or 6%-7% by weight of the total formulation, or 7%-8% by weight of the total formulation or 8%-10% by weight of the total formulation.

The presently disclosed formulation further comprises, plasticizer, toughener, thickener, thinner, dispersant, or flexibilizer, or other functional additives.

Optionally, the presently disclosed formulation further comprises a solvent. The choice of solvent depends entirely on the at least partially capped titanium dioxide or zirconium oxide comprising a metal oxide shell and/or treated with an inorganic passivation agent, and selected monomers, oligomers and polymers of the formulation. Examples of solvents that range from low to high boiling point include alcohols, glycols, methyl acetates, ethyl acetates, esters, ketones, glycol ethers, glycol esters, such as propylene glycol monomethyl ether acetate (PGMEA), propylene glycol monomethyl ether (PGME), ethylene glycol monobutyl ether acetate, diethylene glycol monobutyl ether acetate, diethylene glycol butyl ether, diethylene glycol monoethyl ether acetate, dipropylene glycol methyl ether acetate, butoxy ethanol, butoxy propanol, ethoxy ethyl acetate, butoxy ethyl acetate, 2-(isopentyloxy)ethanol, 2-(hexyloxy)ethanol, diethylene glycol, diethylene glycol monomethyl ether, diethylene glycol monoethyl ether, triethylene glycol, triethylene glycol monomethyl ether, dipropylene glycol, dipropylene glycol monomethyl ether, and dipropylene glycol monoethyl ether, ethyl acetate, THF, acetone, any combination thereof.

The amount of solvent of presently disclosed formulation is less than 0.5% by weight of the total formulation, or 0.5%-1% by weight of the total formulation, or 1%-2% by weight of the total formulation, or 2%-3% by weight of the total formulation, or 3%-4% by weight of the total formulation, or 4%-5% by weight of the total formulation, or 5%-6% by weight of the total formulation, or 6%-7% by weight of the total formulation, or 7%-8% by weight of the total formulation or 8%-10% by weight of the total formulation, or 10%-20% by weight of the total formulation, or 20%-30% by weight of the total formulation or 30%-40% by weight of the total formulation or 40%-50% by weight of the total formulation or 50%-60% by weight of the total formulation or 60%-70% by weight of the total formulation or 70%-80% by weight of the total formulation or 80%-90% by weight of the total formulation or 90%-95% by weight of the total formulation.

### Formulation Properties

The solid content of the presently disclosed formulation is typically 0-93%, such as 0-10%, or 10-20%, or 20-30%, or 30-40%, or 40-50%, or 50-60%, or 60-70%, or 70-80%, or 80-90%, or 90-93% as measured by TGA.

The inorganic content of the presently disclosed formulation is typically 0-93%, such as 0-10%, or 10-20%, or 20-30%, or 30-40%, or 40-50%, or 50-60%, or 60-70%, or 70-80%, or 80-90%, or 90-93% as measured by TGA.

The capped nanocrystals of the presently disclosed formulation constitute less than 10% by weight of the total formulation, or 10%-20% by weight of the total formulation, or 20%-30% by weight of the total formulation, or 30%-40% by weight of the total formulation, or 40%-50% by weight of the total formulation, or 50%-60% by weight of the total formulation, or 60%-70% by weight of the total formulation, or 70%-80% by weight of the total formulation, or 80%-90% by weight of the total formulation, or 90%-93% by weight of the total formulation.

The capped nanocrystals of the presently disclosed nanocomposite constitute less than 10% by weight of the total nanocomposite, or 10%-20% by weight of the total nanocomposite, or 20%-30% by weight of the total nanocomposite, or 30%-40% by weight of the total nanocomposite, or 40%-50% by weight of the total nanocomposite, or 50%-60% by weight of the total nanocomposite, or 60%-70% by weight of the total nanocomposite, or 70%-80% by weight of the total nanocomposite, or 80%-90% by weight of the total nanocomposite, or 90%-93% by weight of the total nanocomposite.

One common technique to characterize optical transmittance and absorptance of nanocrystals formulation and/or nanocomposite is UV-Vis Spectrophotometer (UV-Vis). The UV-Vis technique measures the transmitted light vs. the incident light of a sample in the 200 nm-900 nm wavelength range.

The transmittance of a sample at a given wavelength is defined as:

$$T = \frac{I}{{I}_{0}}$$

where I is the transmitted light intensity and I₀ is the incident light intensity, both at the same wavelength. The absorptance of a sample at a given wavelength is defined as:

$$A = \frac{{I}_{0} - I}{{I}_{0}}$$

The absorbance of a sample, i.e., Optical Density (OD), at a given wavelength is defined as:

$$O D = - {log}_{10} \frac{I}{{I}_{0}}$$

Often a reference sample is used to remove the effects from other materials in the sample. For thin film samples, often there are multiple reflections involved, modeling and algorithm may be applied to extract the actual transmittance, absorptance, and absorbance.

To measure a nanocrystal formulation, the sample is usually kept in a plastic, glass, or fused-silica cuvette with 10 mm optical path. The sample is measured against a reference, which comprises the same solvent, monomer, polymer used in the dispersion kept in the same or same type of cuvette to remove the effects from the cuvette and solvent, monomer, polymer. To measure nanocrystal polymer nanocomposite, the nanocomposite is spin-cast on a glass or a fused-silica wafer to form a uniform thin film, the sample may be measured against a reference, which comprises the same wafer and/or the same polymer spin-cast on a wafer with same thickness to remove the effects from the wafer and polymer. Modeling and algorithms may be applied to extract the exact transmittance, absorptance, and absorbance of the nanocomposite.

There are a variety of UV-Vis spectrometers available, they are all based on the same principle and when operated properly, the results are interchangeable. The model that was specifically used to acquire the data in this disclosure is a Perkin Elmer Lambda 850.

Optical transmittance of a formulation of the present disclosure comprising any of the at least partially capped titanium oxide nanocrystals comprising a metal oxide shell and/or nanocrystals with inorganic treatment described in the present disclosure at 450 nm is in the range of 99%-95%, or 95%-90%, or 90%-85%, or 85%-80%, or 80%-75%, or 75%-70%, 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%, 10%-5%, or, 5%-3% or 3%-2%, or 2%-1% when measured in a cuvette with 1 cm path length.

Optical transmittance of a dispersion or a formulation of the present disclosure comprising any of the at least partially capped titanium oxide nanocrystals comprising a metal oxide shell and/or nanocrystals with inorganic treatment described in the present disclosure at 500 nm is in the range of 99%-95%, or 95%-90%, or 90%-85%, or 85%-80%, or 80%-75%, or 75%-70%, 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%, 10%-5%, or, 5%-3% or 3%-2%, or 2%-1% when measured in a cuvette with 1 cm path length.

Optical transmittance of a dispersion or a formulation of the present disclosure comprising any of the at least partially capped zirconium oxide nanocrystals comprising a metal oxide shell and/or nanocrystals with inorganic treatment described in the present disclosure at 450 nm is in the range of 99%-95%, or 95%-90%, or 90%-85%, or 85%-80%, or 80%-75%, or 75%-70%, 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%, 10%-5%, or, 5%-3% or 3%-2%, or 2%-1% when measured in a cuvette with 1 cm path length.

Optical transmittance of a dispersion or a formulation of the present disclosure comprising any of the at least partially capped zirconium oxide nanocrystals comprising a metal oxide shell and/or nanocrystals with inorganic treatment described in the present disclosure at 500 nm is in the range of 99%-95%, or 95%-90%, or 90%-85%, or 85%-80%, or 80%-75%, or 75%-70%, 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10%, 10%-5%, or, 5%-3% or 3%-2%, or 2%-1% when measured in a cuvette with 1 cm path length.

Formulations of present disclosure have a tunable viscosity, and/or a viscosity that can be controlled by one or more of components of the formulation. Parameters that can control viscosity of the formulation include, but are not limited to, the average length, and molecular weight, of a monomer, oligomer, and/or polymer; as well as the presence of a solvent and the concentration of a solvent, the presence of a thickener (i.e., a viscosity-modifying component) and the concentration of a thickener, the particle size of a component present in the formulation, temperature, and combinations thereof.

The formulation described herein can also have a tunable viscosity in the range of about 1 cp to about 1000 cp, such as about 1 cP-2 cP, about 2 cP-5 cP, about 5 cP-10 cP, about 10 cP-15 cP, about 15 cP-20 cP, about 20 cP-25 cP, about 25 cP-30 cP, about 30 cP-40 cP, about 40 c-50 cP, about 50 cP-60 cP, about 60 cP-75 cP, about 75 cP-100 cP, about 100 cP-200 cP, about 200 cP-500 cP, or about 500 cP-1,000 cP, or about 1,000 cP-2,000 cP, or about 2,000 cP-3,000 cP, or about 3,000 cP-4,000 cP, or about 4,000 cP-5,000 cP, or about 5,000 cP-6,000 cP, or about 6,000 cP-7,000 cP, or about 7,000 cP-8,000 cP, or about 8,000 cP-9,000 cP, or about 9,000 cP-10,000 cP, or >10,000 cP when measured with a Brookfield RVDV II+cone and plate viscometer.

The presently disclosed formulations are stable for more than 1 week, or more than 2 weeks, or more than 3 weeks, or more than 6 weeks, or more than 8 weeks, or more than 3 months, or more than 6 months, or more than 12 months, or more than 36 months, with no significant increase in viscosity. There is no visible precipitation of capped nanocrystals, and the change in formulation viscosity is less than 1%, or less than 2%, or less than 3%, or less than 4%, or less than 5%, or less than 10%, or less than 20%, or less than 30%, or less than 40%. Furthermore, the change in the optical transmittance of the formulations is less than 0.5%, less than 1%, or less than 2%, or less than 3%, or less than 4%, or less than 5%, or less than 10%, or less than 20%, or less than 30%, or less than 40% 450 nm.

The formulations, for inkjet printing applications, have a strong resistance to inkjet nozzle faceplate wetting and appropriate wettability to desired substrates. A liquid wet to a specific solid surface and a contact angle forms once the liquid has reached equilibrium. Very low values of contact angle are typically less than 10°, and the liquid has high wettability with said surface. With high wettability uniform coatings can be achieved. Contact angles greater than 450 are suggestive of partially wetted or non-wetted cases. For such cases irregular surfaces and possible lens printing are possible outcomes and are often indicative of high surface tension liquids on low surface energy surfaces.

For inkjet printing applications, the jetting of the presently disclosed formulations are stable for more than 1 hour, for more than 8 hours, for more than 1 day, or more than 1 week with no significant increase in viscosity. The formulation does not solidify by way of drying or curing leading to clogging of printhead nozzles.

### Methods of Making a Solvent-Free or Solvent-Containing Formulation

1. A method of making a solvent-free formulation comprising a direct dispersion (directly dispersing nanocrystals in a media), method wherein the at least partially capped nanocrystals of the present disclosure are separated from a solvent and dried under vacuum until the solvent content is less than 5% to form dry nanocrystals; mixing dry nanocrystals of at least partially capped oxide nanocrystals in at least one monomer, oligomer, polymer or mixtures thereof by soaking, stirring, speed mixing, microfluidizing or other mixing methods.

Method 1 can further comprise filtering said formulation to remove aggregates or other contaminants.

2. Another method of making a solvent free formulation comprising mixing dry powder of at least partially capped oxide nanocrystals of the present disclosure in at least one solvent by soaking, stirring, speed mixing, microfluidizing or other mixing methods to provide a nanocrystal solvent dispersion; mixing said dispersion with at least one monomer, oligomer, and/or polymer or mixtures or monomers, oligomers and/or polymers to provide a solvent containing formulation; removing said solvent by evaporation or other solvent removal methods such as roto-evaporation.

Method 2 can further comprise filtering said solvent containing or solvent free formulation to remove aggregates or other contaminants.

The amount of solvent remaining in the final solvent free formulation may be referred to as the residual solvent. The residual solvent is typically less than 10%, preferably less than 5% of the total formulation in a solvent free formulation.

The solvents of Method 2 include, ethyl acetate (ETA), methyl ethyl ketone, or other low boiling point solvents.

3. A method of making a solvent containing formulation comprising mixing dry powder of at least partially capped oxide nanocrystals of the present disclosure in at least one solvent by soaking, stirring, speed mixing, microfluidizing or other mixing methods to provide a nanocrystal solvent dispersion; mixing said dispersion with at least one monomer, oligomer, and/or polymer or mixtures or monomers, oligomers and/or polymers to provide a solvent containing formulation.

### Nanocomposite

A nanocomposite is a film, coating, layer, lens on a substrate or free-standing structure. The present disclosure provides a nanocomposite comprising a mixture of at least partially capped titanium dioxide or zirconium oxide nanocrystals comprising a metal oxide shell and/or nanocrystals treated with an inorganic passivation agent and a polymerizable matrix, wherein capped nanocrystals are present in the nanocomposite in the amount of 20-95% by weight of the nanocomposite.

The inorganic solid content of the presently disclosed nanocomposite coating or film is analyzed using a TA instrument Q500 thermal gravimetric analyzer (TGA). The procedure is the same as described previously. The percent at 700° C. relative to the initial mass is regarded as inorganic portion of the formulation, i.e. solid content.

The inorganic solid content of the presently disclosed nanocomposite coating is 0.1-10% as measured by TGA, or 10-20% as measured by TGA, or 20-30% as measured by TGA, or 30-40% as measured by TGA, or 40-50% as measured by TGA, or 50-60% as measured by TGA, or 60-70% as measured by TGA, or 70-80% as measured by TGA, or 80-90% as measured by TGA, or 90-93% as measured by TGA.

The nanocomposite films have moderate to high degrees of cure, good adhesion to the intended substrates and good film uniformity. The capped nanocrystals of present disclosure maintain dispersibility or remain agglomeration-free in a polymer or monomer matrix. Such physical characteristics of the presently disclosed materials not only reduce light scattering but also make for improved processability.

The transmittance of a film according to the present disclosure may be normal transmittance measured with a Perkin-Elmer UV-Vis Lambda 850 spectrophotometer, wherein the film is coated on an optically transparent substrate, such as fused silica or glass substrates, and a blank substrate of the same type and thickness is used as a reference. The ripples in the spectrum are the result of interference of incoming light and reflected light, it usually is an indication of high film quality, i.e. high smoothness, high uniformity, and high transparency.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 20 microns thick at 400 nm as measured by a Perkin-Elmer UV-Vis Lambda 850 spectrophotometer. The transmittance of a film according to the present disclosure is normal transmittance measured with a Perkin-Elmer UV-Vis Lambda 850 spectrophotometer, wherein the nanocomposite is coated on an optically transparent substrate, such as fused silica or glass substrates, and a blank substrate of the same type and thickness is used as a reference.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 20 microns thick at 450 nm as measured by a Perkin-Elmer UV-Vis Lambda 850 spectrophotometer.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 20 microns thick at 650 nm as measured by a Perkin-Elmer UV-Vis Lambda 850 spectrophotometer.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 1 microns thick at 400 nm as measured by a Perkin-Elmer UV-Vis Lambda 850 spectrophotometer.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 1 microns thick at 450 nm as measured by a Perkin-Elmer UV-Vis Lambda 850 spectrophotometer.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 1 microns thick at 650 nm as measured by a Perkin-Elmer UV-Vis Lambda 850 spectrophotometer.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 20 microns thick at 450 nm as measured by a Perkin-Elmer UV-Vis Lambda 850 spectrophotometer; when the nanocrystal loading is 0.1-10%, or 10-20%, or 20-30%, or 30-40%, or 40-50%, or 50-60%, or 60-70%, or 70-80%, or 80-90%, or 90-93%.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 1 microns thick at 450 nm as measured by a Perkin-Elmer UV-Vis Lambda 850 spectrophotometer; when the nanocrystal loading is 0.1-10%, or 10-20%, or 20-30%, or 30-40%, or 40-50%, or 50-60%, or 60-70%, or 70-80%, or 80-90%, or 90-93%.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 20 microns thick at 520 nm as measured by a Perkin-Elmer UV-Vis Lambda 850 spectrophotometer; when the nanocrystal loading is 0.1-10%, or 10-20%, or 20-30%, or 30-40%, or 40-50%, or 50-60%, or 60-70%, or 70-80%, or 80-90%, or 90-93%.

The presently disclosed nanocomposite possesses high optical transmittance of 99.9%-99%, or 99%-98%, or 98%-97%, or 97%-96%, or 96%-95%, or 95%-90%, or 90%-85%, or 85%-80%, 80%-75%, or 75%-70%, or 70%-65%, or 65%-60%, or 60%-55%, or 55%-50%, or 50%-45%, or 45%-40%, or 40%-35%, or 35%-30%, or 30%-25%, or 25%-20%, or 20%-15%, or 15%-10% for films that are less than 1 microns thick at 520 nm as measured by a Perkin-Elmer UV-Vis Lambda 850 spectrophotometer; when the nanocrystal loading is 0.1-10%, or 10-20%, or 20-30%, or 30-40%, or 40-50%, or 50-60%, or 60-70%, or 70-80%, or 80-90%, or 90-93%.

One common technique to characterize the color of a nanocomposite is quantify the intensity of red, green and blue wavelength transmitted through a nanocomposite using a colorimetric spectrophotometer where the intensity of the light at each wavelength is multiplied with the illuminant to give X,Y, Z color values which are referred to as CIE color co-ordinates. The color co-ordinates reported in this disclosure is measured using Hunterlab's Vista hazemeter which converts the CIE X, Y, Z color co-ordinates to a 3-dimensional rectangular color space through series of equations to give L*, a*, b* color space values. In a color space, ‘L*’ is in the ‘y-axis’ and denotes the lightness of the specimen, ‘a*’ is the ‘x-axis’ and denotes the red-green shift and ‘b*’ denotes the blue-yellow color shift and in the ‘z-axis’. Typically, when a nanocomposite undergoes degradation, the color changes from clear or white to yellow and this change is measured in terms of change in ‘b*’. Additionally, the degradation of the film in all aspects of the color space can be monitored by calculating the Delta E* from delta L*, a* and b*.

$$Delta {E}^{*} = {[ {( {L}_{final}^{*} - {L}_{initial}^{*} )}^{2} + {( {a}_{final}^{*} - {a}_{initial}^{*} )}^{2} + {( {b}_{final}^{*} - {b}_{initial}^{*} )}^{2} ]}^{1 / 2}$$

In addition to color, the Hunterlab's Vista hazemeter is used to quantify the haze or clarity of the optical clear nanocomposite.

The presently disclosed nanocomposite typically possesses very low b* indicating minimal coloration of the film and the b* is in the range of 0.01-0.05, or 0.05-0.1, or 0.1-0.5, or 0.5-1.0, or 1.0-1.5, or 1.5-2.0 for films that are less than 1 microns thick as measured by a Hunterlab Vista hazemeter. Haze and b* values of the nanocomposites maybe affected by the type of the substrate, haze of the substrate, RI mismatch between the substrate and the film, and film thickness. For example, nanocomposites made from the same formulations when coated on a PET substrate show higher b* and haze than when coated on a glass substrate. Unless otherwise stated the b* values reported are for films on glass substrates.

The presently disclosed nanocomposite typically possesses very low % haze indicating high clarity of the film and the % haze is in the range of 0.0-0.02, or 0.02-0.04, or 0.04-0.06, or 0.06-0.08, or 0.08-0.1, or 0.1-0.14, or 0.14-0.18, or 0.18-0.20, or 0.20-0.25, or 0.25-0.30, or 0.30-0.35, or 0.35-0.40, or 0.40-0.45, or 0.45-0.50 for films that are less than 1 microns thick as measured by a Hunterlab Vista hazemeter.

The presently disclosed nanocomposite typically possesses very low b* indicating minimal coloration of the film and the b* is in the range of 0.01-0.05, or 0.05-0.1, or 0.1-0.5, or 0.5-1.0, or 1.0-1.5, or 1.5-2.0, 2.0-2.5, or 2.5-3.0 for films that are less than 20 microns thick as measured by a Hunterlab Vista hazemeter.

The presently disclosed nanocomposite typically possesses very low b* indicating minimal coloration of the film and the b* is in the range of 0.01-0.05, or 0.05-0.1, or 0.1-0.5, or 0.5-1.0, or 1.0-1.5, or 1.5-2.0, 2.0-2.5, or 2.5-3.0, or 3.0-3.5, or 3.5-4.0, or 4.0-4.5, or 4.5-5.0 for films that are less than 20 microns thick coated on a PET substrate as measured by a Hunterlab Vista hazemeter.

The presently disclosed nanocomposite typically possesses very low % haze indicating high clarity of the film and the % haze is in the range of 0.0-0.02, or 0.02-0.04, or 0.04-0.06, or 0.06-0.08, or 0.08-0.1, or 0.1-0.14, or 0.14-0.18, or 0.18-0.20, or 0.20-0.25, or 0.25-0.30, or 0.30-0.35, or 0.35-0.40, or 0.40-0.45, or 0.45-0.50 for films that are less than 20 microns thick as measured by a Hunterlab Vista hazemeter.

One common technique to characterize measure the refractive index is to use Metricon's 2010/M model Prism Coupler. Using the Metricon's 2010/M model Prism Coupler which is equipped with 448 nm and 635 nm laser beam, one can calculate the estimated refractive index of the same material at a third wavelength. The calculation of the refractive index at 550 nm is based on a 2-term version of Cauchy's equation:

$$R I ( w ) = A + \frac{B}{{w}^{2}}$$

The A and B parameters depend on the measured RI values at specific wavelengths, which were chosen to be 448 and 635 nm. By representing parameters A and B in terms of RI(448 nm) and RI(635 nm), the following equation allows for the calculation of the RI(550 nm):

$$R I ( 550 nm ) = \frac{1}{3} R I ( 448 nm ) + \frac{2}{3} R I ( 635 nm )$$

RI values for other wavelengths can be calculated using the same equation.

Another method to measure refractive index is by an ellipsometer. With an ellipsometer refractive index as a function of wavelengths can be measured. Some refractive index measurements are made using a JA Woollam M2000 Ellipsometer.

The presently disclosed nanocomposite typically possesses a refractive index of 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.00-2.02, or 2.02-2.04, or 2.04-2.06, or 2.06-2.08, or 2.08-2.10, or 2.10-2.12, or 2.12-2.14, or 2.14-2.16, or 2.16-2.18, or 2.18-2.20, or 2.20-2.22, or 2.22-2.24, or 2.24-2.26, or 2.26-2.28, or 2.28-2.30, or 2.30-2.32, or 2.32-2.34, or 2.34-2.36, or 2.36-2.38, or 2.38-2.40, or 2.40-2.42, or 2.42-2.44, or 2.44-2.46, or 2.46-2.48, or 2.48-2.50, or 2.50-2.52, or 2.52-2.54, or 2.54-2.56, or 2.56-2.58, or 2.58-2.60, at 448 nm.

The presently disclosed nanocomposite typically possesses a refractive index of 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.00-2.02, or 2.02-2.04, or 2.04-2.06, or 2.06-2.08, or 2.08-2.10, or 2.10-2.12, or 2.12-2.14, or 2.14-2.16, or 2.16-2.18, or 2.18-2.20, or 2.20-2.22, or 2.22-2.24, or 2.24-2.26, or 2.26-2.28, or 2.28-2.30, or 2.30-2.32, or 2.32-2.34, or 2.34-2.36, or 2.36-2.38, or 2.38-2.40, or 2.40-2.42, or 2.42-2.44, or 2.44-2.46, or 2.46-2.48, or 2.48-2.50, or 2.50-2.52, or 2.52-2.54, or 2.54-2.56, or 2.56-2.58, or 2.58-2.60, at 520 nm.

The presently disclosed nanocomposite typically possesses a refractive index of 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.00-2.02, or 2.02-2.04, or 2.04-2.06, or 2.06-2.08, or 2.08-2.10, or 2.10-2.12, or 2.12-2.14, or 2.14-2.16, or 2.16-2.18, or 2.18-2.20, or 2.20-2.22, or 2.22-2.24, or 2.24-2.26, or 2.26-2.28, or 2.28-2.30, or 2.30-2.32, or 2.32-2.34, or 2.34-2.36, or 2.36-2.38, or 2.38-2.40, or 2.40-2.42, or 2.42-2.44, or 2.44-2.46, or 2.46-2.48, or 2.48-2.50, or 2.50-2.52, or 2.52-2.54, or 2.54-2.56, or 2.56-2.58, or 2.58-2.60, at 589 nm.

The presently disclosed nanocomposite typically possesses a refractive index of 1.54-1.56, 1.56-1.58, 1.58-1.60, 1.60-1.62, or 1.62-1.64, 1.64-1.66, or 1.66-1.68, or 1.68-1.70, or 1.70-1.72, or 1.72-1.74, or 1.74-1.76 or 1.76-1.78, or 1.78-1.80, or 1.80-1.82, or 1.82-1.84, or 1.84-1.86, or 1.86-1.88, or 1.88-1.90, 1.90-1.92, or 1.92-1.94, or 1.94-1.96, or 1.96-1.98, or 1.98-2.00, or 2.00-2.02, or 2.02-2.04, or 2.04-2.06, or 2.06-2.08, or 2.08-2.10, or 2.10-2.12, or 2.12-2.14, or 2.14-2.16, or 2.16-2.18, or 2.18-2.20, or 2.20-2.22, or 2.22-2.24, or 2.24-2.26, or 2.26-2.28, or 2.28-2.30, or 2.30-2.32, or 2.32-2.34, or 2.34-2.36, or 2.36-2.38, or 2.38-2.40, or 2.40-2.42, or 2.42-2.44, or 2.44-2.46, or 2.46-2.48, or 2.48-2.50, or 2.50-2.52, or 2.52-2.54, or 2.54-2.56, or 2.56-2.58, or 2.58-2.60, at 635 nm.

The presently disclosed nanocomposite typically possesses hardness values of 100-150 MPa, or 150-200 MPa, or 200-250 MPa, 250-300 MPa, or 300-350 MPa, or 350-400 MPa as measured with nanoindentation.

The presently disclosed nanocomposite typically possesses modulus values of 3.0-3.5 GPa, or 3.5-4.0 GPa, or 4.0-4.5 GPa, 4.5-5.0 GPa, or 5.0-5.5 GPa, or 5.5-6.0 GPa, or 6.0-6.5 GPa, or 6.5-7.0 GPa, or 7.0-7.5 GPa, or 7.5-8.0 GPa, or 8.0-8.5 GPa, or 8.5-9.0 GPa, or 9.0-9.5 GPa, or 9.5-10.0 GPa, or 10.0-15.0 GPa as measured with nanoindentation.

The presently disclosed nanocomposite additionally demonstrates thermal stability at temperatures below 120° C., or 120-175° C., or 175-200° C., or 200-250° C., or 250-300° C., or 300-400° C. The thermal stability is measured by subjecting the nanocomposite at designated temperature in air, nitrogen, or under vacuum for 10 sec-5 minutes, or 5-10 minute, or 10-30 minutes, or 30-60 minutes, or 60-120 minutes, or longer than 120 min, without visually observable coloration, cracking, or delamination and change in b* less than 1%, or less than 5%, or less than 10%, or less than 15%, or less than 20%, or less than 25%, or less than 50% of the initial b* for films that are less than 1 microns thick, or less than 2 microns thick, or less than 3 microns thick, or less than 4 microns thick, or less than 5 microns thick, or less than 10 μm, or 5-10 um thick, or 1-2 um thick or less than 1 um thick or >10 μm thick as measured by a Hunterlab Vista hazemeter.

The presently disclosed nanocomposite additionally demonstrates thermal stability at temperatures below 120° C., or 120-175° C., or 175-200° C., or 200-250° C., or 250-300° C., or 300-400° C. The thermal stability is measured by subjecting the nanocomposite at designated temperature in air, nitrogen, or under vacuum for 10 sec-5 minutes, or 5-10 minute, or 10-30 minutes, or 30-60 minutes, or 60-120 minutes, or longer than 120 min, without visually observable coloration, cracking, or delamination and change in % haze less than 1%, or less than 5%, or less than 10%, or less than 15%, or less than 20%, or less than 25%, or less than 50% of the initial haze for films that are 1 microns thick, or less than 2 microns thick, or less than 3 microns thick, or less than 4 microns thick, or less than 5 microns thick, or less than 10 μm, or 5-10 um thick, or 1-2 um thick or less than 1 um thick or >10 μm thick as measured by a Hunterlab Vista hazemeter.

The presently disclosed nanocomposite additionally demonstrates thermal stability at temperatures below 120° C., or 120-175° C., or 175-200° C., or 200-250° C., or 250-300° C., or 300-400° C. The thermal stability is measured by subjecting the nanocomposite at designated temperature in air, nitrogen, or under vacuum for 10 sec-5 minutes, or 5-10 minute, or 10-30 minutes, or 30-60 minutes, or 60-120 minutes, or longer than 120 min, without visually observable coloration, cracking, or delamination and with less than 10% decrease in transmittance, or less than 20% decrease in transmittance, or less than 30% decrease in transmittance, or less than 40% decrease in transmittance, or less than 50% decrease in transmittance at 400 nm for films that are 1 microns thick, or less than 2 microns thick, or less than 3 microns thick, or less than 4 microns thick, or less than 5 microns, or less than 10 μm, or 5-10 um thick, or 1-2 um thick or less than 1 um thick or >10 μm thick as measured by a a Perkin-Elmer UV-Vis Lambda 850 spectrophotometer.

In various embodiments, the present disclosure refers to various properties of the nanocrystals, dispersions, formulations, and/or nanocomposites herein. Unless otherwise specified or contrary from context, these properties are measured according to industry standards known to a person of ordinary skill in the art, in view of the present disclosure. Further, unless otherwise specified or contrary from context, when two or more testing methods of a given nanocrystal, dispersion, formulation, or nanocomposite provide different results for a recited property, it should be understood that such given nanocrystal, dispersion, formulation, or nanocomposite is considered within the defined scope herein (e.g., the claims, enumerated embodiments, etc.) as long as (1) under one testing method in accordance with the relevant method(s) shown in the Examples section herein, the result(s) is within the range or definition described for the property of the nanocrystal, dispersion, formulation, or nanocomposite; such one testing method can be validated for example by using the exemplary composition(s) in the Examples section herein, which should provide the same result as that reported herein, within experimental error generally accepted by a person of ordinary skill in the art; or (2) if no relevant method(s) is shown in the Examples section, the result(s) is within the range or definition described for the property of the nanocrystal, dispersion, formulation, or nanocomposite under any testing method acceptable by a person of ordinary skill in the art in view of the present disclosure.

### QUV Accelerated Weather Testing:

In some embodiments, the presently disclosed core-shell nanocrystals with and without an inorganic treatment, dispersions, formulations and nanocomposites made from these nanocrystals demonstrate low photocatalytic activity upon exposure to UV irradiation. The Q Lab QUV Accelerated Weather tester uses a commercial unit with controlled irradiance. The QUV weathering testing has two components, UV and humidity steps. For Step 1, the UV is a 340 nm UV set with 0.89 mW/cm² intensity, temperature is set to 60° C. for 4 hrs. Step 2 is condensation without UV exposure at 50 C for 4 hrs. This cycle is repeated nine times for a total duration of 72 hrs. Films used in QUV testing are deposited on a glass substrate or a PET substrate supported by a glass substrate. Samples are inserted film side down into the sample holders and loaded into the QUV accelerated weathering tester. Refractive index and film thickness of the sampler were measured using Metricon Model 2010/M prism coupler and the color and haze parameters were measured using the HunterLab Hazemeter. Measurements were performed before and after exposure to calculate the change in optical performance due to the weathering test.

### UVA:

For the UVA set up, two 250-watt UV-A Flood lamps (320-390 nm range) were set up with a height difference of 15 cm from a round rotating sample stage, keeping the bulbs and fixture as close to one another as possible. 2.5-inch glass substrates with thin films were then organized in a radial manner, starting the circle at a point under a bulb and avoiding the center of the rotating plate to ensure equal exposure of all films to UV-A bulbs while the stage is rotating. Bulb intensity was checked before each 72 hr run.

The films are placed on the tray side is facing down, allowing UV-A wavelengths to go through the glass substrate before reaching the film. To start the test, the films are organized in the orientation specified above on the rotating plate, lamps are switched on and the test is run for 72-158 hours. Since bulbs can get hot, it's possible to switch off bulbs for an hour every 12-24 hours if needed, but the total exposure time should be 72 hours. Average intensity is kept at 4 mW/cm².

After the test is complete, Refractive index and film thickness of the sampler were measured using Metricon Model 2010/M prism coupler and the color and haze parameters were measured using the HunterLab Hazemeter. Measurements were performed before and after exposure to calculate the change in optical performance due to the weathering test.

In some embodiments, the presently disclosed nanocomposites are additionally tested for the photostability to 405 nm and 450 nm wavelength. The setup is similar to that described for UVA testing setup comprises of lamps of desired wavelengths and a flat aluminum tray placed on a turntable. The lamps are hung 6-12 inches above a flat surface facing the coated substrates. Films or nanocomposites coated on substrates such as glass, silicon wafer or plastic substrates such as PET are placed flat on the aluminum tray with the film surface facing upwards. The aluminum tray is then spun at a slow speed while the films are exposed to the light for the desired duration. The nanocomposites are exposed to 405 nm at an average intensity of (25 mW/cm²) and 450 nm at an average intensity of (16 mW/cm²) wavelength for 148 hours (total UV dosage of 13000 J/cm²) and 1000 hours (total UV dosage of 57600 J/cm²) respectively. The optical properties of the nanocomposites film properties such as b*, % haze, RI and film thickness before and after the total exposure is measured and recorded.

In some embodiments, the presently disclosed nanocomposites demonstrate low photocatalytic activity and therefore high light stability upon UV exposure at wavelengths 320-390 nm, or 390-420 nm, or 420-450 nm, or above 450 nm. The photocatalytic stability is measured by exposing the nanocomposite at designated exposure wavelength at an intensity in the range of 0.5-1.0 mJ/cm²·s, or 1.0-2.0 mJ/cm²·s, or 2.0-3.0 mJ/cm²·s, or 3.0-4.0 mJ/cm²·s, or 4.0-5.0 mJ/cm²·s, or 5.0-8.0 mJ/cm²·s, or 8.0-10.0 mJ/cm²·s, or 10.0-12.0 mJ/cm²·s, or 12.0-14.0 mJ/cm²·s, or 14.0-16.0 mJ/cm²·s, or 16.0-18.0 mJ/cm²·s, or 18.0-20.0 mJ/cm²·s, or 20.0-25.0 mJ/cm²·s, or 25.0-30.0 mJ/cm²·s, or 30.0-35.0 mJ/cm²·s, or 35.0-40.0 mJ/cm²·s, or 40.0-45.0 mJ/cm²·s, or 45.0-50.0 mJ/cm²·s, for 30 sec or longer, for 1 min or longer, for 2 min or longer, for 3 min or longer, for 4 min or longer, 5 minutes or longer, or 10 minute or longer, or 30 minutes or longer, or 60 minutes or longer, or 2 hours or longer, or 6 hours or longer, or 12 hours or longer, or 24 hours or longer, or 48 hours or longer, or 72 hours or longer, or 100 hours or longer, or 120 hours or longer, or 158 hours or longer, or 192 hours or longer, or 240 hours or longer, or 288 hours or longer, or 336 hours or longer, or 384 hours or longer, or 432 hours or longer, or 500 hours or longer, or 600 hours or longer, or 700 hours or longer, or 800 hours or longer, or 900 hours or longer, or 1000 hours or longer, without visually observable coloration, cracking, or delamination and change in b*less than 1%, or less than 5%, or less than 10%, or less than 15%, or less than 20%, or less than 25%, less than 30%, less than 40%, less than 50% of the initial b* for films that are less than 1 micron thick, or 1-5 um thick, or 5-10 um thick, or 10-20 μm thick, as measured by a Hunterlab Vista hazemeter.

In some embodiments, the presently disclosed nanocomposites demonstrate low photocatalytic activity and therefore high light stability upon UV exposure at wavelengths 320-390 nm, or 390-420 nm, or 420-450 nm, or above 450 nm. The photocatalytic stability is measured by exposing the nanocomposite at designated exposure wavelength at an intensity in the range of 0.5-1.0 mJ/cm²·s, or 1.0-2.0 mJ/cm²·s, or 2.0-3.0 mJ/cm²·s, or 3.0-4.0 mJ/cm²·s, or 4.0-5.0 mJ/cm²·s, or 5.0-8.0 mJ/cm²·s, or 8.0-10.0 mJ/cm²·s, or 10.0-12.0 mJ/cm²·s, or 12.0-14.0 mJ/cm²·s, or 14.0-16.0 mJ/cm²·s, or 16.0-18.0 mJ/cm²·s, or 18.0-20.0 mJ/cm²·s, or 20.0-25.0 mJ/cm²·s, or 25.0-30.0 mJ/cm²·s, or 30.0-35.0 mJ/cm²·s, or 35.0-40.0 mJ/cm²·s, or 40.0-45.0 mJ/cm²·s, or 45.0-50.0 mJ/cm²·s, for 30 sec or longer, for 1 min or longer, for 2 min or longer, for 3 min or longer, for 4 min or longer, for 5 minutes or longer, or 10 minute or longer, or 30 minutes or longer, or 60 minutes or longer, or 2 hours or longer, or 6 hours or longer, or 12 hours or longer, or 24 hours or longer, or 48 hours or longer, or 72 hours or longer, or 96 hours or longer, or 120 hours or longer, or 158 hours or longer, or 192 hours or longer, or 240 hours or longer, or 288 hours or longer, or 336 hours or longer, or 384 hours or longer, or 432 hours or longer, or 500 hours or longer, or 600 hours or longer, or 700 hours or longer, or 800 hours or longer, or 900 hours or longer, or 1000 hours or longer, without visually observable coloration, cracking, or delamination and change in % haze less than 1%, or less than 5%, or less than 10%, or less than 15%, or less than 20%, or less than 25%, less than 30%, less than 40%, less than 50% of the initial haze for films that are less than 1 microns thick as measured by a Hunterlab Vista hazemeter. These films also show less than 10% decrease in transmittance, or less than 20% decrease in transmittance, or less than 30% decrease in transmittance, or less than 40% decrease in transmittance, or less than 50% decrease in transmittance at 400 nm, or 450 nm, or 520 nm, or 550 nm for films that are less than 1 microns thick, or 1-5 um thick, or 5-10 um thick, or 10-20 um thick as measured by a Perkin-Elmer UV-Vis Lambda 850 spectrophotometer.

In some embodiments, the presently disclosed nanocomposites demonstrate low photocatalytic activity and therefore high light stability upon UV exposure at wavelengths 320-390 nm, or 390-420 nm, or 420-450 nm, or above 450 nm. The photocatalytic stability is measured by exposing the nanocomposite at designated exposure wavelength at an intensity in the range of 0.5-1.0 mJ/cm²·s, or 1.0-2.0 mJ/cm²·s, or 2.0-3.0 mJ/cm²·s, or 3.0-4.0 mJ/cm²·s, or 4.0-5.0 mJ/cm²·s, or 5.0-8.0 mJ/cm²·s, or 8.0-10.0 mJ/cm²·s, or 10.0-12.0 mJ/cm²·s, or 12.0-14.0 mJ/cm²·s, or 14.0-16.0 mJ/cm²·s, or 16.0-18.0 mJ/cm²·s, or 18.0-20.0 mJ/cm²·s, or 20.0-25.0 mJ/cm²·s, or 25.0-30.0 mJ/cm²·s, or 30.0-35.0 mJ/cm²·s, or 35.0-40.0 mJ/cm²·s, or 40.0-45.0 mJ/cm²·s, or 45.0-50.0 mJ/cm²·s, for 30 sec or longer, for 1 min or longer, for 2 min or longer, for 3 min or longer, for 4 min or longer, for 5 minutes or longer, or 10 minute or longer, or 30 minutes or longer, or 60 minutes or longer, or 2 hours or longer, or 6 hours or longer, or 12 hours or longer, or 24 hours or longer, or 48 hours or longer, or 72 hours or longer, or 96 hours or longer, or 120 hours or longer, or 158 hours or longer, or 192 hours or longer, or 240 hours or longer, or 288 hours or longer, or 336 hours or longer, or 384 hours or longer, or 432 hours or longer, or 500 hours or longer, or 600 hours or longer, or 700 hours or longer, or 800 hours or longer, or 900 hours or longer, or 1000 hours or longer, without significant change in refractive index with a change in refractive index less than 0.001, or less than 0.002, or less than 0.004, or less than 0.006, or less than 0.008, or less than 0.01, or less than 0.012, or less than 0.015, or less than 0.018, or less than 0.02, or less than 0.022, or less than 0.025, or less than 0.028, or less than 0.03, or less than 0.035, or less than 0.04, or less than 0.045, or less than 0.05, or less than 0.055, or less than 0.06, or less than 0.065, or less than 0.07, or less than 0.075, or less than 0.08, or less than 0.085, or less than 0.09, or less than 0.095, or less than 0.1, at 520 nm for films that are less than 1 microns thick, or 1-5 um thick, or 5-10 um thick, or 10-20 um thick as measured by a prism or an ellipsometer.

In some embodiments, the presently disclosed nanocomposites demonstrate low photocatalytic activity and therefore high light stability upon UV exposure at wavelengths 390-420 nm, or 420-450 nm, or above 450 nm. The photocatalytic stability is measured by exposing the nanocomposite at designated exposure wavelength at an intensity in the range of 0.5-1.0 mJ/cm²·s, or 1.0-2.0 mJ/cm²·s, or 2.0-3.0 mJ/cm²·s, or 3.0-4.0 mJ/cm²·s, or 4.0-5.0 mJ/cm²·s, or 5.0-8.0 mJ/cm²·s, or 8.0-10.0 mJ/cm²·s, or 10.0-12.0 mJ/cm²·s, or 12.0-14.0 mJ/cm²·s, or 14.0-16.0 mJ/cm²·s, or 16.0-18.0 mJ/cm²·s, or 18.0-20.0 mJ/cm²·s, or 20.0-25.0 mJ/cm²·s, or 25.0-30.0 mJ/cm²·s, or 30.0-35.0 mJ/cm²·s, or 35.0-40.0 mJ/cm²·s, or 40.0-45.0 mJ/cm²·s, or 45.0-50.0 mJ/cm²·s, for 30 sec or longer, for 1 min or longer, for 2 min or longer, for 3 min or longer, for 4 min or longer, for 5 minutes or longer, or 10 minute or longer, or 30 minutes or longer, or 60 minutes or longer, or 2 hours or longer, or 6 hours or longer, or 12 hours or longer, or 24 hours or longer, or 48 hours or longer, or 72 hours or longer, or 96 hours or longer, or 120 hours or longer, or 158 hours or longer, or 192 hours or longer, or 240 hours or longer, or 288 hours or longer, or 336 hours or longer, or 384 hours or longer, or 432 hours or longer, or 500 hours or longer, or 600 hours or longer, or 700 hours or longer, or 800 hours or longer, or 900 hours or longer, or 1000 hours or longer, without visually observable coloration, cracking, or delamination and change in % haze less than 1%, or less than 5%, or less than 10%, or less than 15%, or less than 20%, or less than 25%, less than 30%, less than 40%, less than 50% of the initial haze for films that are less than 1 microns thick as measured by a Hunterlab Vista hazemeter. These films also show less than 10% decrease in transmittance, or less than 20% decrease in transmittance, or less than 30% decrease in transmittance, or less than 40% decrease in transmittance, or less than 50% decrease in transmittance at 400 nm, or 450 nm, or 520 nm, or 550 nm for films that are less than 1 microns thick, or 1-5 um thick, or 5-10 um thick, or 10-20 um thick as measured by a Perkin-Elmer UV-Vis Lambda 850 spectrophotometer.

In some embodiments, the presently disclosed nanocomposites demonstrate low photocatalytic activity and therefore high light stability upon UV exposure at wavelengths 390-420 nm, or 420-450 nm, or above 450 nm. The photocatalytic stability is measured by exposing the nanocomposite at designated exposure wavelength at an intensity in the range of 0.5-1.0 mJ/cm²·s, or 1.0-2.0 mJ/cm²·s, or 2.0-3.0 mJ/cm²·s, or 3.0-4.0 mJ/cm²·s, or 4.0-5.0 mJ/cm²·s, or 5.0-8.0 mJ/cm²·s, or 8.0-10.0 mJ/cm²·s, or 10.0-12.0 mJ/cm²·s, or 12.0-14.0 mJ/cm²·s, or 14.0-16.0 mJ/cm²·s, or 16.0-18.0 mJ/cm²·s, or 18.0-20.0 mJ/cm²·s, or 20.0-25.0 mJ/cm²·s, or 25.0-30.0 mJ/cm²·s, or 30.0-35.0 mJ/cm²·s, or 35.0-40.0 mJ/cm²·s, or 40.0-45.0 mJ/cm²·s, or 45.0-50.0 mJ/cm²·s, for 30 sec or longer, for 1 min or longer, for 2 min or longer, for 3 min or longer, for 4 min or longer, for 5 minutes or longer, or 10 minute or longer, or 30 minutes or longer, or 60 minutes or longer, or 2 hours or longer, or 6 hours or longer, or 12 hours or longer, or 24 hours or longer, or 48 hours or longer, or 72 hours or longer, or 96 hours or longer, or 120 hours or longer, or 158 hours or longer, or 192 hours or longer, or 240 hours or longer, or 288 hours or longer, or 336 hours or longer, or 384 hours or longer, or 432 hours or longer, or 500 hours or longer, or 600 hours or longer, or 700 hours or longer, or 800 hours or longer, or 900 hours or longer, or 1000 hours or longer, without significant change in refractive index with a change in refractive index less than 0.001, or less than 0.002, or less than 0.004, or less than 0.006, or less than 0.008, or less than 0.01, or less than 0.012, or less than 0.015, or less than 0.018, or less than 0.02, or less than 0.022, or less than 0.025, or less than 0.028, or less than 0.03, or less than 0.035, or less than 0.04, or less than 0.045, or less than 0.05, or less than 0.055, or less than 0.06, or less than 0.065, or less than 0.07, or less than 0.075, or less than 0.08, or less than 0.085, or less than 0.09, or less than 0.095, or less than 0.1, at 520 nm for films that are less than 1 microns thick, or 1-5 um thick, or 5-10 um thick, or 10-20 um thick as measured by a prism or an ellipsometer.

### A Method of Making a Nanocomposite

The present disclosure provides a method of making a nanocomposite using the presently disclosed formulation. A nanocomposite film is described herein containing a cured or partially cured formulation of the present disclosure. Said nanocomposite is cured or partially cured by UV or thermal curing techniques known to one of ordinary skill in the art.

The present disclosure provides a nanocomposite film as described herein wherein the film is produced by spin coating, slot-die coating, screen-printing, ink-jet printing, dip coating, draw-bar coating, roll-to-roll printing, spray coating, imprinting, nanoimprinting, molding or any combination thereof.

### A Device

The present disclosure provides an LED, organic LED, micro LED, touch screen, display, sensor, Augmented Reality lens, Virtual Realty lens, optical lens, or a solar cell device comprising an active component, said active component comprising or containing a nanocomposite of the present disclosure.

### Preferred Embodiments Include the Following Enumerated Embodiments 1-42

1. Nanocrystals having a core-shell structure, comprising a core and an outer shell, wherein the core is at least partially encapsulated by the outer shell, wherein the core comprises a core metal oxide, and the outer shell comprises a shell metal oxide, wherein the core metal oxide is characterized as having an average particle size greater than 3 nm but less than 50 nm as measure by TEM; and the outer shell is characterized as having a thickness between 0.1 nm and 5 nm as measure by TEM, wherein the core metal oxide and the shell metal oxide are the same or different.

2. The nanocrystals of embodiment 1, wherein the atomic ratio of the shell metal oxide to the core metal oxide is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX. Preferably the atomic ratio of the shell metal oxide to the core metal oxide is less than 0.5.

3. The nanocrystals of any of embodiments 1 and 2, wherein the core metal oxide and core-shell metal oxide nanocrystals have narrow particle size distributions, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

4. The nanocrystals of any of embodiments 1-3, comprising an inorganic passivation agent treated core and/or core-shell, wherein the inorganic passivation agent comprises at least one of sodium polyphosphate, lithium nitrate, sodium hypochlorite, sodium hypophosphite, sodium phosphite, lithium chloride, sodium nitrate, sodium chloride, sodium aluminum phosphate, sodium hexametaphosphate or any combination thereof. Preferably inorganic passivation agent comprises NaH₂PO₂.

5. The nanocrystals of any of embodiments 1-4, comprising an at least partially capped nanocrystal capped with at least one capping agent selected from methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof. Preferably the capping agent are one or more of methyltrimethoxysilane, phenytrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, vinyltrimethoxysilane, allyltrimethoxysilane, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, 2-[2-(2-methoxyethoxy)ethoxy]acetic acid, or any combination thereof.

6. The nanocrystals of embodiment 5, wherein the organic content of the at least partially capped nanocrystals is less than 25%, such as less than 5%, or 5% to 8% or 8% to 10%, or 10% to 12%, or 12% to 14% or 14% to 16%, or 16% to 18%, or 18% to 20% of the at least partially capped nanocrystals.

7. The nanocrystals of any of embodiments 1-6, wherein the core metal oxide comprises titanium dioxide, zirconium dioxide, and/or barium titanate, and wherein the shell metal oxide comprises silicon dioxide, zirconium dioxide, hafnium dioxide, niobium oxide, aluminum oxide, tantalum oxide, barium titanium oxide, cerium oxide, or any combination thereof.

8. The nanocrystals of any of embodiments 1-6, wherein the core metal oxide comprises TiO₂, and the shell metal oxide comprises silicon dioxide, zirconium dioxide, hafnium dioxide, niobium oxide, aluminum oxide, tantalum oxide, cerium oxide, barium titanium oxide, or any combination thereof.

9. The nanocrystals of any of embodiments 1-6, wherein the core metal oxide comprises TiO₂, and the shell metal oxide comprises silicon dioxide, zirconium dioxide, cerium oxide or any combination thereof.

10. The nanocrystals of any of embodiments 1-9 exhibit low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure; and as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 320-390 nm for 66 h @ light intensity of 4 mW/cm².

11. The nanocrystals of any of embodiments 1-9 exhibit low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure; and as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 450 nm for 1000 h at light intensity of 16 mW/cm² or UV exposure at or above 405 nm for 148 h at light intensity of 25 mW/cm².

12. The nanocrystals of any of embodiments 10-11, wherein the core metal oxide is titanium oxide and the shell metal oxide comprises zirconium oxide, and the average particle size of the nanocrystals is less than 30 nm as measured by TEM; wherein the atomic ratio of the shell Zr to the core Ti is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX.

13. The capped nanocrystals of any of embodiments 5-12, wherein the particle size distribution of the nanocrystals is characterized by a D9999 as less than 500 nm as measured by volume of the nanocrystals dispersed 5% by weight in a solvent, by Dynamic Light Scattering (DLS).

14. A method of preparing core-shelled TiO₂ nanocrystals comprising a core comprising TiO₂ nanocrystals and a shell comprising a shell metal oxide, the method comprising converting a precursor of the shell metal oxide into the shell metal oxide at least partially encapsulating the core comprising TiO₂ nanocrystals in a solvent, wherein the converting comprises 1) mixing the precursor of the shell metal oxide in a reaction mixture of the solvent and the core comprising TiO2 nanocrystals, and 2) heating the reaction mixture at a reaction temperature, e.g., about 90° C., for a period of time to provide the shell metal oxide at least partially encapsulating the core comprising the TiO₂ nanocrystals.

15. The method of embodiment 14, wherein converting comprises 1) mixing the precursor of the shell metal oxide either directly, or in water, into the reaction mixture of the solvent and the core comprising TiO₂ nanocrystals, and 2) heating the reaction mixture at a reaction temperature of about 50° C. to about 90° C., for about 10 min to about 7 days, preferably for about 1 h to 24 h, to form the shell metal oxide at least partially encapsulating the core comprising the TiO₂ nanocrystals.

16. The method of any one of embodiments 14-15 wherein the shell metal oxide comprising zirconium oxide and wherein the precursor of zirconium dioxide is a zirconium alkoxide, such as a zirconium alkoxide having a formula of Zr(OR)₄, a compound having a formula of Zr(OR)ₓG_{y}, or a combination thereof, wherein each R group can be independently an alkyl group (e.g., a C1-C6 alkyl group) or a substituted alkyl group, G group at each occurrence is independently a halogen (e.g., Cl), wherein x is an integer of 0-4, y is an integer of 0-4, provided that x+y is 4, or a zirconium oxyhalide or a zirconium halide; zirconium oxyhalide is preferred. The atomic ratio of Zr/Ti of the core TiO₂ nanocrystals and the shell ZrO₂ is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX. Preferably the atomic ratio of Zr/Ti of the core TiO₂ nanocrystals and the shell ZrO₂ is less than 1.

17. The method of any one of embodiments 14-16, wherein the solvent comprises one or more solvents selected from benzyl alcohol, phenol, oleyl alcohol, butanol, propanol, isopropanol, ethanol, butoxy ethanol, butoxy propanol, methanol, 2-(isopentyloxy)ethanol, 2-propoxy-propanol (PnP), 2-(hexyloxy)ethanol, tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, diethylene glycol monoethyl ether, diethylene glycol, dipropylene glycol, acetone, propylene glycol methyl ether acetate (PGMEA), ethyl lactate (EL), methyl acetates, ethyl acetates, butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate, benzene, toluene, and water. Preferably the solvent comprises water.

18. The method of any one of embodiments 14-17, wherein the core-shelled TiO₂ nanocrystals have an average particle size of about 3 nm to about 50 nm as measured by TEM, or 4 nm to 30 nm as measured by TEM. Preferably, the core shell nanocrystals with the shell comprising the shell metal oxide have a shell thickness of 0.1 nm to 5 nm, as measured by TEM. Preferably, the shell of at least one metal oxide material on the TiO₂ nanocrystals encapsulates the TiO₂ nanocrystals completely or partially. Additionally, the shell comprises the shell metal oxide can be in crystalline and/or amorphous form. The core-shelled TiO₂ nanocrystals prepared according to the method of embodiments 14-18 have a narrow particle size distribution, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

19. A method of capping core-shelled TiO₂ nanocrystals having a core comprising TiO₂ nanocrystals with a shell comprising ZrO₂, comprising reacting the nanocrystals of any one of embodiments 1-5 with a first capping agent in a first capping solvent to produce a first at least partially capped core-shelled TiO₂ nanocrystals. The capping agent is one or more of methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof. Preferably the capping agent are one or more of methyltrimethoxysilane, phenytrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, vinyltrimethoxysilane, allyltrimethoxysilane, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, 2-[2-(2-methoxyethoxy)ethoxy]acetic acid, or any combination thereof.

20. A nanocrystal dispersion comprising at least partially capped core-shelled nanocrystals comprising a core metal oxide with an outer shell comprising a shell metal oxide, at least one capping agent, and a dispersion media wherein the core metal oxide is characterized as having an average particle size greater than 3 nm but less than 50 nm as measure by TEM or DLS and the shell is characterized as having a thickness between 0.1 nm and 5 nm as measure by TEM or DLS; and wherein the at least partially capped core-shelled nanocrystals are present in an amount of greater than 10%, or greater than 20%, or greater than 30%, or greater than 40%, or greater than 50%, or greater than 60%, or greater than 70%, or greater than 80%, by weight of the dispersion. The at least partially capped core-shelled nanocrystals are capped with at least one capping agent selected from methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof. Preferably the capping agent are one or more of methyltrimethoxysilane, phenytrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, vinyltrimethoxysilane, allyltrimethoxysilane, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, 2-[2-(2-methoxyethoxy)ethoxy]acetic acid, or any combination thereof.

21. The nanocrystal dispersion of embodiment 20, wherein the core-shelled nanocrystals are treated with an inorganic passivation agent comprising sodium polyphosphate, lithium nitrate, sodium hypochlorite, sodium hypophosphite, sodium phosphite, lithium chloride, sodium nitrate, sodium chloride, sodium aluminum phosphate, sodium hexametaphosphate or any combination thereof. Preferably inorganic passivation agent comprises NaH₂PO₂.

22. The nanocrystal dispersion of any of embodiments 20-21, wherein the organic content of the at least partially capped nanocrystals is typically 0-25% such as 0-5%, or 5-10%, or 10-15%, or 15-20%, or 20-25%, or less than 5%, or less than 8% or less than 10%, less than 12%, or less than 14% or less than 16%, less than 18%, or less than 20% or less than 20%, less than 25% of the capped nanocrystals, as measured by TGA.

23. The nanocrystal dispersion of any of embodiments 20-22, wherein the core metal oxide comprises titanium dioxide, zirconium dioxide, and/or barium titanate, and the shell metal oxide comprises silicon dioxide, zirconium dioxide, hafnium dioxide, niobium oxide, aluminum oxide, tantalum oxide, barium titanium oxide, cerium oxide, or any combination thereof. Preferred core-shell nanocrystals comprise a TiO2 core and a ZrO2 shell metal oxide.

24. The nanocrystal dispersion of any of embodiments 20-23, wherein the at least partially capped core-shelled nanocrystals are present in an amount equal to or greater than 50%, by weight of the dispersion and wherein the % organics are less than 20% of the at least partially capped core-shelled nanocrystals, and the core metal oxide is titanium oxide and the shell metal oxide comprises zirconium oxide and the average particle size of the at least partially capped core-shelled nanocrystals is less than 30 nm as measured by TEM or DLS. The atomic ratio of the shell Zr to the core Ti is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX. Preferably, the atomic ratio of the shell Zr to the core Ti is less than 1.

25. The nanocrystal dispersion of any of embodiments 20-24, wherein the particle size distribution of the at least partially capped core-shelled nanocrystals is characterized by a D9999 as less than 500 nm as measured by volume of the at least partially capped core-shelled nanocrystals dispersed 5% by weight in a solvent by Dynamic Light Scattering (DLS). Preferably, D9999 is less than 300 nm.

26. The nanocrystal dispersion of any of embodiments 20-25, wherein the dispersion media comprises a solvent, monomer, oligomer of a polymer, or a combination thereof. Examples of the solvent that is used for dispersion include but are not limited to THF, acetone, heptane, benzyl alcohol, phenol, oleyl alcohol, butanol, propanol, isopropanol, ethanol, butoxy ethanol, butoxy propanol, methanol, tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, and diethylene glycol monoethyl ether, diethylene glycol, dipropylene glycol, acetone; esters, such as: propylene glycol methyl ether acetate (PGMEA), ethyl lactate (EL), methyl acetates, ethyl acetate (ETA), butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate, benzene, toluene, and water and any combination or mixture thereof. Preferred solvents include: THF, isopropanol, ethanol, dipropylene glycol methyl ether (DPGME), propylene glycol monomethyl ether (PGME), propylene glycol methyl ether acetate (PGMEA), ethyl acetate, toluene, and any combination or mixture thereof. The monomers include benzyl (meth)acrylate (BA and BMA), trimethylolpropane tri(meth)acrylate (TMPTA and TMPTMA), trimethylolpropane ethoxylate tri(meth)acrylate (EOTMPTA and EOTMPTMA), 1,6-hexanediol di(meth)acrylate (HDDA and HDDMA), di(ethyleneglycol) di(meth)acrylate (DEGDA and DEGDMA), ethylene glycol diacrylate, glycerol 1,3-diglycerolate diacrylate, tri(propylene glycol) diacrylate, 1,6-hexanediol ethoxylate diacrylate, ethylene glycol phenyl ether (meth)acrylate (PEA and PEMA), 2-hydroxy-3-phenoxypropyl acrylate (HPPA), 2-hydroxy-3-phenoxypropyl methacrylate (HPPMA), 2-phenoxy benzyl acrylate (PBA), biphenyl methacrylate (BPMA), isobornyl acrylate (IBA), 2-phenylphenol methacrylate (PPMA), isobutyl acrylate (IBA), 2-phenylethyl acrylate (2-PEA), 2-(phenylthio)ethyl acrylate (PTEA), tris(2-hydroxy Ethyl)isocyanurate triacrylate (THEICTA or M370), Bisphenol A Glycerolate Dimethacrylate, esters with acrylic acid (OPPEOA), 9,9-Bis[4-(2-acryloyloxyethyloxy)phenyl]fluorene or bisfluorene diacrylate in OPPEOA (HR6042), Bisphenol A Ethoxylate diacrylates, Bisphenol A propoxylate diacrylate, Bisphenol F ethoxylate (2 EO/phenol) diacrylate, Bisphenol A glycerolate diacrylates, bisphenol A ethoxylate dimethacrylate, Ethoxylated (4) bisphenol A diacrylate (SR-601), Biphenol A ethoxylate diacrylate(SR-349), Tris(2-acryloyloxy)ethyl} isocyanurate, tricyclodecane dimethanol diacrylate, cresol novolac epoxy acrylate (CN112C60), tri(ethyleneglycol) diacrylate, ethylene glycol diacrylate, Poly(ethylene glycol) diacrylate, Glycerol 1,3-diglycerolate diacrylate, and N-vinyl pyrrolidone (NVP), phenyl norborene, styrene (STY), 4-methylstyrene, 4-vinylanisole, divinylbenzene combinations thereof. In some preferred embodiments, the monomer, oligomer and/or polymer can be selected from, 2-phenylethyl acrylate (2-PEA), biphenyl methacrylate (BPMA), 2-phenoxy benzyl acrylate (PBA), trimethylolpropane tri(meth)acrylate (TMPTA and TMPTMA), tris(2-hydroxy ethyl)isocyanurate triacrylate (THEICTA), 9,9-Bis[4-(2-acryloyloxyethyloxy)phenyl]fluorene or bisfluorene diacrylate in OPPEOA (HR6042), and combinations thereof. The dispersion described herein can also have a tunable viscosity in the range of about 1 cp to about 1000 cp, such as about 1 cP-2 cP, about 2 cP-5 cP, about 5 cP-10 cP, about 10 cP-15 cP, about 15 cP-20 cP, about 20 cP-25 cP, about 25 cP-30 cP, about 30 cP-40 cP, about 40 c-50 cP, about 50 cP-60 cP, about 60 cP-75 cP, about 75 cP-100 cP, about 100 cP-200 cP, about 200 cP-500 cP, or about 500 cP-1,000 cP, or about 1,000 cP-2,000 cP, or about 2,000 cP-3,000 cP, or about 3,000 cP-4,000 cP, or about 4,000 cP-5,000 cP, or about 5,000 cP-6,000 cP, or about 6,000 cP-7,000 cP, or about 7,000 cP-8,000 cP, or about 8,000 cP-9,000 cP, or about 9,000 cP-10,000 cP, or >10,000 cP when measured with a Brookfield RVDV II+cone and plate viscometer.

27. A nanocomposite formulation comprising 1) at least partially capped core-shelled TiO₂ nanocrystals with an outer shell comprising a shell metal oxide; 2) a monomer, oligomer, and/or polymer; 3)optionally a solvent; and 4) a curing agent, wherein the at least partially capped core-shelled TiO₂ nanocrystals are present in an amount of greater than 20% by weight with respect to the monomer, oligomer and/or polymer, wherein the core of the at least partially capped core-shelled TiO₂ nanocrystals comprises crystalline titanium dioxide, and is treated with at least one inorganic passivation agent; and wherein the average particle size of the at least partially capped core-shelled TiO₂ nanocrystals when measured with DLS as a 5% nanocrystal dispersion in PGMEA is in the range of 3-50 nm and a shell thickness between 0.1 nm and 3 nm as measure by TEM. The at least partially capped core-shelled TiO₂ nanocrystals are capped with at least one capping agent selected from methyltrimethoxysilane, phenytrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, vinyltrimethoxysilane, allyltrimethoxysilane, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, 2-[2-(2-methoxyethoxy)ethoxy]acetic acid, or any combination thereof.

28. The nanocomposite formulation of embodiment 27, wherein the shell metal oxide comprises silicon dioxide, zirconium dioxide, hafnium dioxide, niobium oxide, aluminum oxide, tantalum oxide, barium titanium oxide, cerium oxide, or any combination thereof. Preferably the shell metal oxide comprises silicon dioxide, cerium oxide and/or zirconium oxide.

29. The nanocomposite formulation of any of embodiments 27-28, wherein the at least partially capped core-shelled nanocrystals are present in an amount equal to or greater than 35%, by weight with respect to the monomer, oligomer and/or polymer and the viscosity of the formulation is in the range of 1-10,000 cP. Preferably the viscosity of the formulation is in the range of 1-3,000 cP.

30. The nanocomposite formulation of any of embodiments 27-29 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1-10 μm thick films made from the formulation comprising core-shell nanocrystals is measured using a hazemeter before and after the UV exposure at 320 nm-390 nm for 66 h at 4 mW/cm², or at or above 450 nm for 1000 h at 16 mW/cm², or at or above 405 nm for 148 h at 25 mW/cm² intensity, or at 340 nm for 72 h at 0.89 mW/cm² intensity. The nanocomposite formulation of any of embodiments 27-29 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in E* when the E* of a 1-10 μm thick films made from the formulation comprising core-shell nanocrystals is measured using a hazemeter before and after the UV exposure at 320 nm-390 nm for 66 h at 4 mW/cm², or at or above 450 nm for 1000 h at 16 mW/cm², or at or above 405 nm for 148 h at 25 mW/cm² intensity, or at 340 nm for 72 h at 0.89 mW/cm² intensity.

31. The nanocomposite formulation of any of embodiments 27-30 wherein the at least partially capped core-shelled TiO₂ nanocrystals have low photocatalytic activity as measured by less than 0.08, such as less than 0.01, less than 0.02, less than 0.03, less than 0.04, less than 0.05, less than 0.06, less than 0.07, less than 0.08, less than 0.09, less than 0.1 change in refractive index when the refractive index of a film comprising the core-shell nanocrystals is measured using a prism coupler or an ellipsometer before and after the UV exposure before and after the UV exposure at 320 nm-390 nm for 66 h at 4 mW/cm², or at or above 450 nm for 1000 h at 16 mW/cm², or at or above 405 nm for 148 h at 25 mW/cm² intensity, or at 340 nm for 72 h at 0.89 mW/cm² intensity.

32. A nanocomposite comprising cured film comprising at least partially capped core-shelled TiO₂ nanocrystals with an outer shell comprising a shell metal oxide and at least one monomer, oligomer and/or polymer, wherein the at least partially capped core-shelled TiO₂ nanocrystals are present in an amount greater than 35%, by weight of the nanocomposite, wherein the transmittance of the film with a thickness of 1 micron is greater than 80% at wavelength of 400 nm and above, and the film has a refractive index of about 1.55 to about 2.20 as measured using a Prism Coupler or an ellipsometer.

33. The nanocomposite film of embodiment 32, wherein the at least partially capped core-shelled TiO₂ nanocrystals have an average particle size greater than 3 nm but less than 50 nm as measure by TEM and a shell thickness between 0.1 nm and 3 nm as measure by TEM. The atomic ratio of the shell metal oxide/Ti is less than 0.1, less than 0.2, less than 0.3, less than 0.4, less than 0.5, less than 0.6, less than 0.7, less than 0.8, less than 0.9, less than 1 as measured by SEM EDX. The at least partially capped core-shelled TiO₂ nanocrystals are capped with at least one capping agent selected from methyltrimethoxysilane, phenytrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, vinyltrimethoxysilane, allyltrimethoxysilane, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, 2-[2-(2-methoxyethoxy)ethoxy]acetic acid, or any combination thereof. The shell metal oxide comprises silicon dioxide, zirconium dioxide, hafnium dioxide, niobium oxide, aluminum oxide, tantalum oxide, cerium oxide, barium titanium oxide, or any combination thereof.

34. The nanocomposite of any of embodiments 32-33 comprising monomers selected from benzyl (meth)acrylate (BA and BMA), trimethylolpropane tri(meth)acrylate (TMPTA and TMPTMA), trimethylolpropane ethoxylate tri(meth)acrylate (EOTMPTA and EOTMPTMA), 1,6-hexanediol di(meth)acrylate (HDDA and HDDMA), di(ethyleneglycol) di(meth)acrylate (DEGDA and DEGDMA), ethylene glycol diacrylate, glycerol 1,3-diglycerolate diacrylate, tri(propylene glycol) diacrylate, 1,6-hexanediol ethoxylate diacrylate, ethylene glycol phenyl ether (meth)acrylate (PEA and PEMA), 2-hydroxy-3-phenoxypropyl acrylate (HPPA), 2-hydroxy-3-phenoxypropyl methacrylate (HPPMA), 2-phenoxy benzyl acrylate (PBA), biphenyl methacrylate (BPMA), isobornyl acrylate (IBA), 2-phenylphenol methacrylate (PPMA), isobutyl acrylate (IBA), 2-phenylethyl acrylate (2-PEA), 2-(phenylthio)ethyl acrylate (PTEA), tris(2-hydroxy Ethyl)isocyanurate triacrylate (THEICTA or M370), Bisphenol A Glycerolate Dimethacrylate, esters with acrylic acid (OPPEOA), 9,9-Bis[4-(2-acryloyloxyethyloxy)phenyl]fluorene or bisfluorene diacrylate in OPPEOA (HR6042), Bisphenol A Ethoxylate diacrylates, Bisphenol A propoxylate diacrylate, Bisphenol F ethoxylate (2 EO/phenol) diacrylate, Bisphenol A glycerolate diacrylates, bisphenol A ethoxylate dimethacrylate, Ethoxylated (4) bisphenol A diacrylate (SR-601), Biphenol A ethoxylate diacrylate(SR-349), Tris(2-acryloyloxy)ethyl} isocyanurate, tricyclodecane dimethanol diacrylate, cresol novolac epoxy acrylate (CN112C60), tri(ethyleneglycol) diacrylate, ethylene glycol diacrylate, Poly(ethylene glycol) diacrylate, Glycerol 1,3-diglycerolate diacrylate, and N-vinyl pyrrolidone (NVP), phenyl norborene, styrene (STY), 4-methylstyrene, 4-vinylanisole, divinylbenzene combinations thereof. In some preferred embodiments, the monomer, oligomer and/or polymer can be selected from, 2-phenylethyl acrylate (2-PEA), biphenyl methacrylate (BPMA), 2-phenoxy benzyl acrylate (PBA), trimethylolpropane tri(meth)acrylate (TMPTA and TMPTMA), tris(2-hydroxy ethyl)isocyanurate triacrylate (THEICTA), 9,9-Bis[4-(2-acryloyloxyethyloxy)phenyl]fluorene or bisfluorene diacrylate in OPPEOA (HR6042), and combinations thereof.

35. An exemplary formulation comprises at least one of acrylic monomers selected from HR6042 and BPMA, at least partially capped titanium oxide nanocrystals (e.g., any of those described herein, such as those preferred or exemplified herein), or at least partially capped core shell nanocrystals comprising TiO₂ as the core and ZrO₂ as the shell metal oxide (e.g., any of those described herein, such as those preferred or exemplified herein) wherein weight ratio of the nanocrystal to combined weight of monomers is from 0.5:1 to 3:1. The formulation can further comprise a photoinitiator, TPO, and at least one solvent (e.g., any of those described herein, such as those preferred or exemplified herein). The formulation can be applied to a surface by spin coating and is nanoimprintable. A nanocomposite film formed by applying this formulation to a surface preferably has transmittance greater than 80%, or greater than 90%, or greater than 93% at film thicknesses from 40 nm to 30 μm. The nanocomposite has RI in the range of 1.6 to 2.2, such as in the range of 1.6-1.7, or 1.7-1.8, or 1.8-1.9 or 1.9-2.0 at 520 nm. Preferably the RI is in the range of 1.8-2.0. The nanocomposite also has low haze of less than 1% and b* of less than 1.

36. Another exemplary formulation comprises an acrylic monomer comprising PBA and/or THEICTA and at least partially capped titanium oxide nanocrystals (e.g., any of those described herein, such as those preferred or exemplified herein), or at least partially capped core shell nanocrystals comprising TiO₂ as the core and ZrO₂ as the shell metal oxide (e.g., any of those described herein, such as those preferred or exemplified herein) wherein at least partially capped nanocrystals present in the range of 20-60% by weight with respect to total formulation, monomers are present in the range of 3-25 weight percent with respect to the total formulation such that nanocrystals to monomer ratio ranges from 3:7 to 8:2. The formulation can further comprise a photoinitiator (e.g., any of those described herein, such as those preferred or exemplified herein) present in the range of 0.5-2.5 weight percent with respect to the total formulation and solvent (e.g., any of those described herein, such as those preferred or exemplified herein) present in the range of 20-40 weight percent with respect to the total formulation. The formulation can be applied to a surface by spin coating and is nanoimprintable. A nanocomposite film formed by applying this formulation to a surface has transmittance greater than 80%, or greater than 90%, or greater than 93% at film thicknesses from 40 nm to 30 μm. The nanocomposite has RI in the range of 1.6 to 2.2, such as in the range of 1.6-1.7, or 1.7-1.8, or 1.8-1.9 or 1.9-2.0 at 520 nm. Preferably the RI is in the range of 1.7-1.9. The nanocomposite also has low haze of less than 1% and b* of less than 1.

37. Another exemplary formulation comprises at least partially capped nanocrystals, core shell nanocrystals or core shell nanocrystals with inorganic treatment, e.g., any of those described herein, such as those preferred or exemplified herein, and at least one monomer, wherein the core shell nanocrystals comprise TiO₂ core and ZrO₂ shell. Nanocrystals are present in the range of 35-80 by wt, preferably 65-75% by weight with respect to the total formulation. Monomers preferably include at least one of 2-PEA, PTEA, PEA, PBA, and/or IBA that are present in the range of 3-18 weight percent with respect to the total formulation, and TEICHTA present in the range of 1-10 weight percent with respect to the total formulation. Formulation optionally contains an additive such as Tinivin 405, Irganox 1010, present in the range of 0.5-2.5 weight percent with respect to the total formulation, and/or photoinitiator (e.g., any of those described herein, such as those preferred or exemplified herein) present in the range of 0.5-2.5 weight percent with respect to the total formulation. The formulation typically contains less than 6.5% solvent. Formulation with nanocrystal loading in the 65-75% show low viscosity of 500-5000 cP, preferably 1,000-3,000 cP. Nanocomposite film formed by applying this formulation to a surface has transmittance greater than 80%, or greater than 90%, or greater than 93% at film thicknesses from 40 nm to 30 μm. The nanocomposite has RI in the range of 1.6 to 2.2, such as in the range of 1.6-1.7, or 1.7-1.8, or 1.8-1.9 or 1.9-2.0 at 520 nm. Preferably the RI is in the range of 1.75-1.9. The nanocomposite also has low haze of less than 5% and b* of less than 2 at about 10 μm thickness.

38. Another exemplary formulation comprises at least partially capped nanocrystals, core shell nanocrystals or core shell nanocrystals with inorganic treatment, e.g., any of those described herein, such as those preferred or exemplified herein, and at least one monomer, wherein the core shell nanocrystals comprise TiO₂ core and ZrO₂ shell. The nanocrystals are present in the range of 20-60 weight with respect to total formulation, monomer blends comprising at least one of BA, BPMA, and/or DVE, present in the range of 40-80 weight percent with respect to the total formulation, formulation optionally contains a diluent such as STY or ethyl acetate present in the range of 0.5-5 weight percent with respect to the total formulation, at least one of photoinitiator and photosensitizer selected from Irgacure 819, ITX, and Esacure 1001M, present in the range of 0.5-2.5 weight percent with respect to the total formulation. The solvent content of the formulation is less than 6.5 weight percent with respect to the total formulation. The formulation can be prepared as described in method 2 of the present disclosure. Formulation with nanocrystal loading in the 20-50% shows low viscosity of 10-100 cP, preferably 10-40 cP. The formulation is inkjet printable. Nanocomposite film formed by applying this formulation to a surface has transmittance greater than 80%, or greater than 90%, or greater than 93% at film thicknesses from 40 nm to 30 μm. The nanocomposite has RI in the range of 1.6 to 1.9, such as in the range of 1.6-1.7, or 1.7-1.8, or 1.8-1.9 at 589 nm. Preferably the RI is in the range of 1.6-1.8. The nanocomposite also has low haze of less than 2% and b* of less than 3 at about 10 μm thickness.

39. The nanocomposite of any of embodiments 32-38, wherein the film with <5 μm thickness is thermally stable when subjected to temperatures higher than 200C for 5 minutes wherein the change in b*is less than 1%, or less than 5%, or less than 10%, or less than 15%, or less than 20%, or less than 25% and the change in % haze is less than 1%, or less than 5%, or less than 10%, or less than 15%, or less than 20%, or less than 25% of the initial b* as measured by hazemeter. 40. The nanocomposite film of any of embodiments 32-39 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at 320 nm-390 nm for 66 h at 4 mW/cm², or at or above 450 nm for 1000 h at 16 mW/cm², or at or above 405 nm for 148 h at 25 mW/cm² intensity, or at 340 nm for 72 h at 0.89 mW/cm² intensity. The nanocomposite film of any of embodiments 32-39 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in E* when the E* of a 1-10 μm thick films made from the formulation comprising core-shell nanocrystals is measured using a hazemeter before and after the UV exposure before and after the UV exposure at 320 nm-390 nm for 66 h at 4 mW/cm², or at or above 450 nm for 1000 h at 16 mW/cm², or at or above 405 nm for 148 h at 25 mW/cm² intensity, or at 340 nm for 72 h at 0.89 mW/cm² intensity. In addition the change in % haze is less than 1%, or less than 5%, or less than 10%, or less than 15%, or less than 20%, or less than 25%, less than 30%, less than 40%, less than 50% of the initial haze.

41. The nanocomposite film of any of embodiments 32-40 wherein the at least partially capped core-shelled TiO₂ nanocrystals have low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure before and after the UV exposure at 320 nm-390 nm for 66 h at 4 mW/cm², or at or above 450 nm for 1000 h at 16 mW/cm², or at or above 405 nm for 148 h at 25 mW/cm² intensity, or at 340 nm for 72 h at 0.89 mW/cm² intensity. In addition, films show a percent change in film thickness less than 0.1, or less than 0.2, or less than 0.3, or less than 0.4, or less than 0.5, or less than 0.6, or less than 0.7, or less than 0.8, or less than 0.9, or less than 1.0, or less than 1.5, or less than 2.0, or less than 2.5, or less than 3.0 or less than 3.5 or less than 4.0 or less than 4.5, or less than 5, or less than 10, or less than 15, or less than 20, or less than 25, or less than 50 percent.

42. A device comprising any of the nanocomposite films of any of embodiments 32-41.

### EXAMPLES

### Example 1: Synthesis of Titanium Oxide (TiO₂) Nanocrystals

Titanium oxide nanocrystals having a size in the range of 1-30 nm are prepared from precursors such as Titanium (IV) methoxide, Titanium (IV) ethoxide, Titanium (IV) propoxide, Titanium (IV) isopropoxide, Titanium (IV) butoxide, or Titanium (IV) oxyacetylacetonate. Titanium n-butoxide, Chlorotriisopropoxytitanium (IV), titanium n-propoxide, titanium (IV) chloride, titanium chloride tri-n-butoxide, or titanium dichloride diethoxide would be advantageously used as precursors depending on final product desired.

In an exemplary method, a titanium alkoxide precursor, such as, but not limited to, titanium n-butoxide, titanium n-propoxide, titanium isopropoxide isopropanol or titanium ethoxide, is mixed with water acting as a reagent, and with a solvent or mixture of solvents, including benzyl alcohol, phenol, oleyl alcohol, butanol, propanol, isopropanol, tetrahydrofuran, ethanol, methanol, acetonitrile, toluene, PGMEA, Propylene glycol propylether (PGPE), PGME, 2-methyl-1-propanol, or triethylene glycol monomethyl ether and sealed within an autoclave. The reaction mixture is heated to a temperature between 140-300° C., preferably to a temperature of 180 C-250 C. Once the reaction mixture reaches the set temperature, the temperature is maintained for a length of time ranging from 20 minutes to 24 hours, preferably 30 min-2 h depending in part on the solvent or solvent mixtures and/or the temperature of the reaction. Titanium oxide nanocrystals are obtained as a white milky suspension. The TiO₂ is separated from the suspension by centrifuge. The milky suspension is transferred to centrifuge bottles and centrifuged at 4500 rpm for 10 minutes. The centrifuge step causes the TiO₂ to collect at the bottom of the bottles with clear supernatant at the top. The clear supernatant is decanted and discarded to a white solid at the bottom of the bottle. This solid is referred to as ‘wetcake’ because the solid has most of the solvent remove but is still in the wet form.

In a preferred method 879 g of 100% (w/w) Titanium (IV) n-butoxide was mixed with 3550 g of benzyl alcohol and 116.3 g of water in an inerted 2-gallon Parr reactor. The setup was sealed under an inert condition such as nitrogen atmosphere to prevent oxygen contamination. The Parr reactor was then heated up to 200° C. while stirring at 600 rpm and maintained at this temperature for one hour. After the reaction, the reactor was cooled down to room temperature and a white milky solution of as-synthesized titanium oxide nanocrystals was collected. The milky suspension is transferred to centrifuge bottles and centrifuged at 4500 rpm for 10 minutes and the wetcake was collected.

### Example 2: Synthesis of Zirconium Oxide (ZrO₂) Nanocrystals

An exemplary synthetic method using zirconium n-butoxide as the precursor is as follows: 21.58 g of 80% (w/w) Zirconium (IV) n-butoxide in 1-butanol solution (containing 17.26 g or 45 mmol Zirconium (IV) n-butoxide) was mixed with 300 ml of benzyl alcohol and then transferred into an autoclave. Optionally, water was added as a reactant in the amount of from 0.1 to 2 mole percent of the zirconium precursor. The setup was sealed under an inert atmosphere to prevent oxygen and moisture contamination. The autoclave was then heated up to 325.degree. C., kept at this temperature for one hour and then cooled down to room temperature. A white milky solution of as-synthesized zirconium oxide nanocrystals was collected.

Zirconium n-butoxide is received as a solution in 1-butanol (80% w/w). 1-butanol can be removed from the precursor before the synthesis under vacuum and/or heating (30-50.degree. C.), during the synthesis by releasing the pressure of the autoclave when the temperature reaches around 100.degree. C. or after the reaction is completed. The nanocrystals are spherical in shape and around 5 nm in diameter.

### Example 3: High Temperature ZrO₂ Shell Formation on TiO₂ and Subsequent Surface Modification

TiO₂ wetcake from example 1 (450 g) was mixed with benzyl alcohol (1240 g). The resulting milky white suspension is centrifuged at 4500 rpm for 10-min. The supernatant is decanted, and the nanocrystal settles at the bottom of the centrifuge bottle as a wetcake. The wetcake is then again re-dispersed into benzyl alcohol (3400 g) and the slurry is transferred to a 2-gallon reactor. The reactor is closed and sealed. 340 g of zirconium butoxide (80% in n-butanol) is then charged into the reactor, followed by 200 g of benzyl alcohol. The reactor is inerted with nitrogen gas and stirred for 20 minutes. The reactor is then heated to 20° C. and held at that temperature for four hours. After cooling to room temperature, the material is discharged.

The resulting treated TiO₂ is separated from the reaction mixture via centrifugation at 4500 rpm for 10-min. The solid material is then dispersed into PGMEA shaken vigorously, and then collected via centrifugation at 4500 rpm for 10-min, where the PGMEA was decanted away. The material (46 g) is then transferred to a flask and dispersed into PGMEA (85 g). Methoxy(triethyleneoxy)propyl trimethoxysilane is then added (6.9 g) and the reaction mixture was heated at 70 C for 40 minutes. 3-(methacryloyloxy)propyl trimethoxysilane was then added (13.8) and heated for an additional 70 C for 30 minutes. Water (2.3) is then added to the reaction mixture and the reaction mixture is heated at 70 C for an additional 30 minutes to form capped nanocrystals.

The capped nanocrystals are separated from the reaction mixture by precipitating the nanocrystal using heptanes (700 ml). The solid was collected by centrifugation and the liquid is decanted away. The solid material is then dispersed into 100 ml of xylene for 2 minutes followed by an additional 200 ml of THF before adding 700 ml of heptanes. The solid was collected by centrifugation and the liquid is decanted away. This solid is then dispersed into 300 ml of THF and precipitated using heptanes (700 ml). The solid is collected by centrifugation and the liquid is decanted away. The solid is then dried overnight in a vacuum oven. The dried material is then dispersed into PGMEA at 50% weight loading and then filtered.

### Example 4: Formation of ZrO₂ Shell on TiO₂ to Yield TiO₂—ZrO₂ Nanocrystal

TiO₂ from example 1 collected as wet cake is dispersed into acetone and homogenized with zirconia beads. The homogenized TiO₂ is separated from the reaction mixture through centrifugation at 4500 rpm for 10-min. The supernatant is decanted, and the nanocrystal settles at the bottom of the centrifuge bottle as a wet cake. This process is repeated. The wet cake (wet solid) obtained is then dispersed into water using zirconia beads until a homogeneous mixture was obtained. The TiO₂ is again collected through centrifugation at 4500 rpm for 10-min. The supernatant is decanted, and the nanocrystal settles at the bottom of the centrifuge bottle as a wetcake. This process is repeated again. The purified TiO₂ wet-cake is then transferred to a 3-neck flask and water is added to the wet-cake (10:1 water to the TiO₂ wet-cake weight). The mixture is stirred until the mixture became homogeneous. ZrOCl₂·8H₂O is then added to the reaction mixture (30% by weight to the TiO₂ wet cake). The reaction mixture is then heated at 90 C for 24 hours. After cooling to room temperature, the resultant reaction mixture after the ZrO₂ shell formation process is a transparent dispersion in water.

### Example 5: Capping of TiO₂—ZrO₂ Core Shell Nanocrystal

The resulting TiO₂—ZrO₂ core-shell nanocrystals from example 4 are purified by precipitating using THF in a 1:4 reaction mixture to THF by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in water in a 1:1 wetcake to water by weight-to-weight ratio and precipitated with THF in a 1:4 nanocrystal dispersion to THF by weight-to-weight ratio. The resulting milky white suspension is centrifuged at 4500 rpm for 10-min and the supernatant decanted. The wetcake collected is re-dispersed in water, re-precipitated in THF, and centrifuged to collect the purified wetcake. This wetcake is dispersed in ethanol in a 1:1 wetcake to water by weight-to-weight ratio and precipitated with acetone in a 1:4 nanocrystal dispersion to acetone by weight-to-weight ratio. The nanocrystal dispersion is centrifuged at 4500 rpm for 10-min. The supernatant is decanted and the wetcake is collected at the bottom of the bottle. This dispersion, precipitation and centrifugation process is repeated two more time.

After the final centrifuge and decant step, the resulting wetcake is transferred to a 1.0-L round bottom flask with the aid of PGMEA to make a final suspension of 25% by weight of the wetcake in PGMEA. The mixture is stirred at room temperature for 15-min to get a homogenous suspension. Methoxy(triethyleneoxy)propyltrimethoxysilane is then added to the reaction flask at 17% by weight of the silane to the wet cake. This mixture is then stirred at room temperature for 15-min. Ammonium hydroxide solution in water (28-30%) is carefully added to the reaction mixture in the flask at 15% by weight of the base to the wetcake. The mixture is heated to 120 degrees C. for 100-min. When the reaction is complete, the mixture will have a translucent appearance.

The reaction mixture is then cooled to room temperature and washed to remove excess capping agent and impurities. The reaction mixture is precipitated in an anti-solvent such as heptane in a 4:1 heptane to reaction mixture weight-to-weight ratio. The suspension is centrifuged at 4500 rpm for 10 minutes. The resulting supernatant is decanted and discarded. The solids obtained is then dispersed in THF at 2:1 THF to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained is again dispersed in THF at 2:1 THF to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter.

DLS of capped titanium oxide nanocrystals with ZrO₂ shell dispersed at 5% by weight in PGMEA demonstrates an average particle size of 34.30 nanometers by Intensity and 25.67 nanometers by volume with a narrow size distribution showing D9999 of 84.3.

### Example 6: Capping of TiO₂—ZrO₂ Core Shell Nanocrystals Followed by Treatment with an Inorganic Passivation Agent

The resulting TiO₂—ZrO₂ core shell nanocrystals from example 4 is purified by precipitating using THF in a 1:4 reaction mixture to THF by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in water in a 1:1 wetcake to water by weight-to-weight ratio and precipitated with THF in a 1:4 nanocrystal dispersion to THF by weight-to-weight ratio. The resulting milky white suspension is centrifuged at 4500 rpm for 10-min and the supernatant decanted. The wetcake collected is re-dispersed in water, re-precipitated in THF, and centrifuged to collect the purified wetcake. This wetcake is dispersed in ethanol in a 1:1 wetcake to water by weight-to-weight ratio and precipitated with acetone in a 1:4 nanocrystal dispersion to acetone by weight-to-weight ratio. The nanocrystal dispersion is centrifuged at 4500 rpm for 10-min. The supernatant is decanted and the wetcake is collected at the bottom of the bottle. This dispersion, precipitation and centrifugation process is repeated two more time.

After the final centrifuge and decant step, the resulting wetcake is transferred to a 1.0-L round bottom flask with the aid of ethanol to make a final suspension of 25% by weight of the wetcake in ethanol. The mixture is stirred at room temperature for 15-min to get a homogenous suspension. Methoxy(triethyleneoxy)propyltrimethoxysilane is then added to the reaction flask at 30% by weight of the silane to the wet cake. This mixture is then stirred at room temperature for 15-min. Ammonium hydroxide solution in water (28-30%) is carefully added to the reaction mixture in the flask at 30% by weight of the base to the wetcake. The mixture is heated to 70 degrees C. for 30-min. After the 30-min hold time, sodium hypophosphite monohydrate powder at 3% by weight to the weight of the wetcake is weighed out and added slowly to the reaction mixture. The mixture is continued to heat at 70 C for an additional 30-min. When the reaction is complete, the mixture will have a translucent appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter.

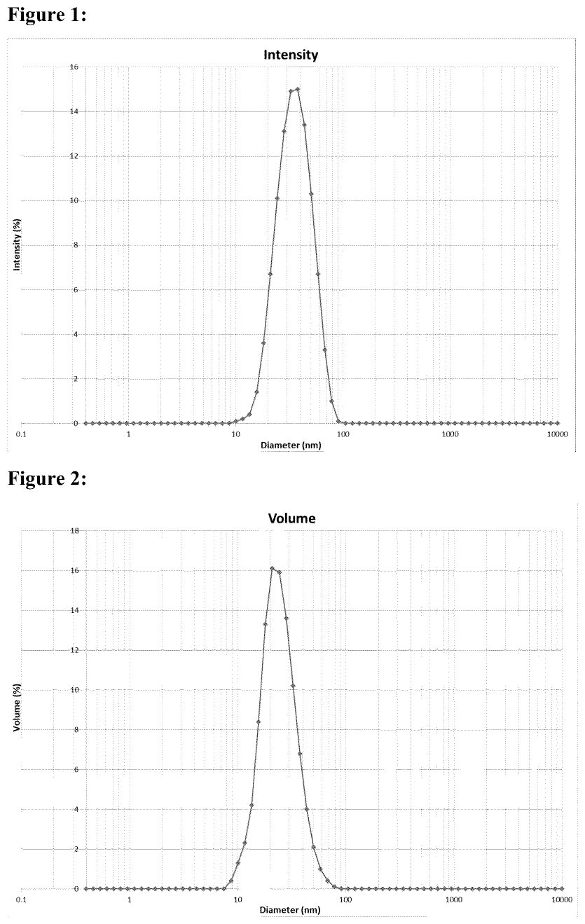

Shown in FIG. 1 is the DLS plot of the capped titanium oxide nanocrystals with ZrO₂ shell dispersed at 5% by weight in PGMEA. The figure shows the DLS plot as a measure of Intensity versus particle size showing an average particle size of 37.15 nanometers with a narrow size distribution.

Shown in FIG. 2 is the DLS plot capped titanium oxide nanocrystals with ZrO₂ shell dispersed at 5% by weight in PGMEA. The figure shows the DLS plot as a measure of volume versus particle size showing an average particle size of 25.46 nanometers with a narrow size distribution. D9999 of this dispersion is 91.1.

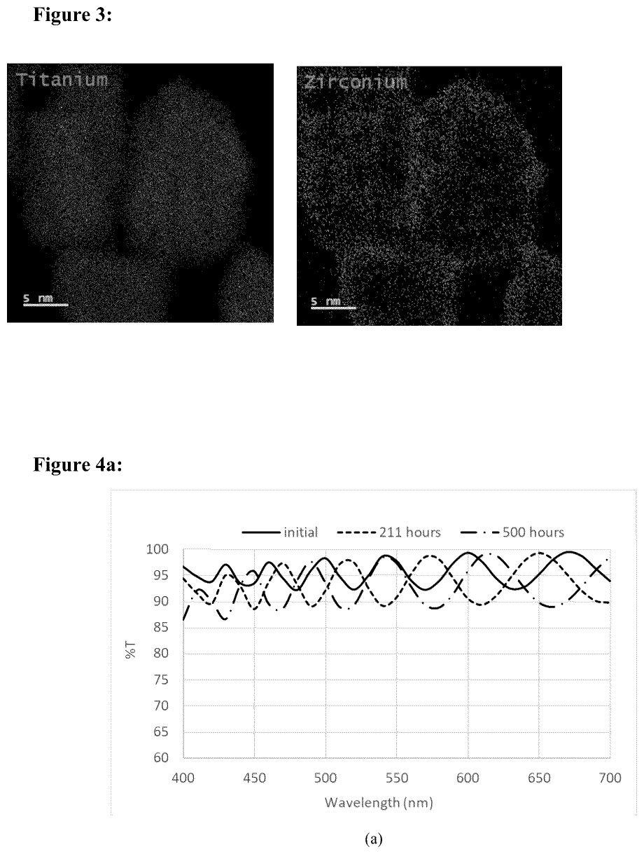

High resolution TEM images with elemental mapping of Ti and Zr are shown in FIG. 3. Figure shows two images of the same particles.

### Example 7: Inorganic Surface Passivation of the TiO₂—ZrO₂ Core-Shell Nanocrystal Before Capping

The resulting TiO₂—ZrO₂ core-shell nanocrystal from example 4 is purified by precipitating using THF in a 1:4 reaction mixture to THF by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in water in a 1:1 wetcake to water by weight-to-weight ratio and precipitated with THF in a 1:4 nanocrystal dispersion to THF by weight-to-weight ratio. The resulting milky white suspension is centrifuged at 4500 rpm for 10-min and the supernatant decanted. The wetcake collected is re-dispersed in water, re-precipitated in THF, and centrifuged to collect the purified white wetcake. This wetcake is re-dispersed in ethanol in a 1:1 wetcake to water by weight-to-weight ratio and precipitated with acetone in a 1:4 nanocrystal dispersion to acetone by weight-to-weight ratio. The nanocrystal dispersion is centrifuged at 4500 rpm for 10-min. The supernatant is decanted and the wetcake is collected at the bottom of the bottle. The process of dispersion, precipitation and centrifugation is repeated two more time.

After the final centrifuge and decant step, the resulting wetcake is re-dispersed in ethanol at 50% by weight and stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 12 hours. After the desired duration, the solid part is separated from the liquid by centrifuge at 4500 rpm for 10 min. The resultant supernatant is decanted off leaving a white wet solid cake at the bottom of the centrifuge bottle. This wet cake is then rinsed with ethanol at a 2.75 to 1 ratio solvent to wet cake weight-to-weight, followed by vigorously agitated. This suspension is then centrifuged again at 4500 rpm for 10 min, and the resulting supernatant decanted off the top. This rinse step is repeated twice. At the end of the rinse step, a white wet solid cake is obtained.

The wetcake is then transferred to a 1.0-L round bottom flask with the aid of ethanol to make a final suspension of 25% by weight of the wetcake in ethanol. The mixture is stirred at room temperature for 15-min to get a homogenous suspension. Methoxy(triethyleneoxy)propyltrimethoxysilane is then added to the reaction flask at 30% by weight of the silane to the wet cake. This mixture is then stirred at room temperature for 15-min. Ammonium hydroxide solution in water (28-30%) is carefully added to the reaction mixture in the flask at 30% by weight of the base to the wetcake. The mixture is heated to 70 degrees C. for 45-min. When the reaction is complete, the mixture will have a translucent appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter.

DLS capped titanium oxide nanocrystals with ZrO₂ shell dispersed at 5% by weight in PGMEA demonstrates an average particle size of 41.37 nanometers and 26.47 nanometers by Intensity versus particle size and volume versus particle size respectively with a narrow size distribution. D9999 of this dispersion is 102.

### Example 8: Capping of TiO₂—ZrO₂ Core Shell Nanocrystals; with Inorganic Surface Passivation Followed by Additionally Treatment with Inorganic Agent

The resulting TiO₂—ZrO₂ core-shell nanocrystal from example 4 is purified by precipitating using THF in a 1:4 reaction mixture to THF by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in water in a 1:1 wetcake to water by weight-to-weight ratio and precipitated with THF in a 1:4 nanocrystal dispersion to THF by weight-to-weight ratio. The resulting milky white suspension is centrifuged at 4500 rpm for 10-min and the supernatant decanted. The wetcake collected is re-dispersed in water, re-precipitated in THF, and centrifuged to collect the purified white wetcake. This wetcake is re-dispersed in ethanol in a 1:1 wetcake to water by weight-to-weight ratio and precipitated with acetone in a 1:4 nanocrystal dispersion to acetone by weight-to-weight ratio. The nanocrystal dispersion is centrifuged at 4500 rpm for 10-min. The supernatant is decanted and the wetcake is collected at the bottom of the bottle. The process of dispersion, precipitation and centrifugation is repeated two more time.

After the final centrifuge and decant step, the resulting wetcake is re-dispersed in ethanol at 50% by weight and stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 12 hours. After the desired duration, the solid part is separated from the liquid by centrifuge at 4500 rpm for 10 min. The resultant supernatant is decanted off leaving a white wet solid cake at the bottom of the centrifuge bottle. This wet cake is then rinsed with ethanol at a 2.75 to 1 ratio solvent to wet cake weight-to-weight, followed by vigorously agitated. This suspension is then centrifuged again at 4500 rpm for 10 min, and the resulting supernatant decanted off the top. This rinse step is repeated twice. At the end of the rinse step, a white wet solid cake is obtained.

The wetcake is then transferred to a 1.0-L round bottom flask with the aid of ethanol to make a final suspension of 25% by weight of the wetcake in ethanol. The mixture is stirred at room temperature for 15-min to get a homogenous suspension. Methoxy(triethyleneoxy)propyltrimethoxysilane is then added to the reaction flask at 30% by weight of the silane to the wet cake. This mixture is then stirred at room temperature for 15-min. Ammonium hydroxide solution in water (28-30%) is carefully added to the reaction mixture in the flask at 30% by weight of the base to the wetcake. The mixture is heated to 70 degrees C. for 45-min. At the end of the 30-min hold time, Sodium hypophosphite monohydrate powder is carefully added to the nanocrystal suspension at 3% by weight to the weight of the wetcake. The reaction mixture is held at 70 C for an additional 30-min. When the reaction is complete, the mixture will have a translucent appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter.

### Example 9: Inorganic Treatment of the TiO₂ Prior to ZrO₂ Shell Coating Followed by Capping

The TiO₂ nanocrystals from example 1 is re-dispersed in ethanol at 50% by weight and stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 12 hours. After the desired duration, the solid part is separated from the liquid by centrifuge at 4500 rpm for 10 min. The resultant supernatant is decanted off leaving a white wet solid cake at the bottom of the centrifuge bottle. This wet cake is then rinsed with ethanol at a 2.75 to 1 ratio solvent to wet cake weight-to-weight, followed by vigorously agitated. This suspension is then centrifuged again at 4500 rpm for 10 min, and the resulting supernatant decanted off the top. This rinse step is repeated twice. At the end of the rinse step, a white wet solid cake is obtained.

The wet cake is then dispersed into water at 10:1 water-to-TiO₂ wet-cake by weight. The mixture is stirred until the mixture became homogeneous. ZrOCl₂·8H₂O is added to the reaction mixture (30% by weight to the TiO₂ wet-cake). The reaction mixture was then heated at 90 C for 24 hours. After cooling to room temperature, the resultant reaction mixture after the ZrO₂ shell formation process is a transparent dispersion in water.

The resulting TiO₂—ZrO₂ nanocrystal from example is purified by precipitating using THF in a 1:4 reaction mixture to THF by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in water in a 1:1 wetcake to water by weight-to-weight ratio and precipitated with THF in a 1:4 nanocrystal dispersion to THF by weight-to-weight ratio. The resulting milky white suspension is centrifuged at 4500 rpm for 10-min and the supernatant decanted. The wetcake collected is re-dispersed in water, re-precipitated in THF, and centrifuged to collect the purified wetcake. This wetcake is dispersed in ethanol in a 1:1 wetcake to water by weight-to-weight ratio and precipitated with acetone in a 1:4 nanocrystal dispersion to acetone by weight-to-weight ratio. The nanocrystal dispersion is centrifuged at 4500 rpm for 10-min. The supernatant is decanted and the wetcake is collected at the bottom of the bottle. This dispersion, precipitation and centrifugation process is repeated two more time.

After the final centrifuge and decant step, the resulting wetcake is transferred to a 1.0-L round bottom flask with the aid of ethanol to make a final suspension of 25% by weight of the wetcake in ethanol. The mixture is stirred at room temperature for 15-min to get a homogenous suspension. Methoxy(triethyleneoxy)propyltrimethoxysilane is then added to the reaction flask at 30% by weight of the silane to the wet cake. This mixture is then stirred at room temperature for 15-min. Ammonium hydroxide solution in water (28-30%) is carefully added to the reaction mixture in the flask at 30% by weight of the base to the wetcake. The mixture is heated to 70 degrees C. for 30-min. When the reaction is complete, the mixture will have a translucent appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids are precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter.

### Example 10: Inorganic Treatment of TiO₂ Nanocrystals with No Metal Oxide Shell Followed by Capping

The synthesized TiO₂ nanocrystals from example 1 is re-dispersed in ethanol at 50% by weight and stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 12 hours. After the desired duration, the solid part is separated from the liquid by centrifuge at 4500 rpm for 10 min. The resultant supernatant is decanted off leaving a white wet solid cake at the bottom of the centrifuge bottle. This wet cake is then rinsed with ethanol at a 2.75 to 1 ratio solvent to wet cake weight-to-weight, followed by vigorously agitated. This suspension is then centrifuged again at 4500 rpm for 10 min, and the resulting supernatant decanted off the top. This rinse step is repeated twice. At the end of the rinse step, a white wet solid cake is obtained.

The wetcake is transferred to a 1.0-L round bottom flask with the aid of ethanol to make a final suspension of 30% by weight of the wetcake in ethanol. The mixture is stirred at room temperature for 15-min to get a homogenous suspension. Methoxy(triethyleneoxy) propyltrimethoxysilane is then added to the reaction flask at 30% by weight of the silane to the wet cake. This mixture is then stirred at room temperature for 15-min. Ammonium hydroxide solution in water (28-30%) is carefully added to the reaction mixture in the flask at 30% by weight of the base to the wetcake. The mixture is heated to 70 degrees C. for 45-min. When the reaction is complete, the mixture will have a translucent appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGME to create a 50% by weight loaded dispersion. The resulting dispersion was filtered through a 0.45 micron and then a 0.2-micron absolute filter.

### Example 11: Capping of TiO₂Nanocrystals with ZrO₂ Shells Along with Inorganic Surface Passivation

TiO₂ from example 1 collected as wet cake is dispersed into acetone and homogenized with zirconia beads. The homogenized TiO₂ is separated from the reaction mixture through centrifugation at 4500 rpm for 10-min. The supernatant is decanted, and the nanocrystal settles at the bottom of the centrifuge bottle as a wet cake. The purified TiO₂ wet-cake is then transferred to a 3-neck flask and water is added to the wet-cake (1:4 TiO₂ wetcake-to-water by weight). The mixture is stirred until the mixture became homogeneous. ZrOCl₂·8H₂O is then added to the reaction mixture (30% by weight to the TiO₂ wet cake). The reaction mixture is then heated at 90 C for 8 hours. After cooling to room temperature, the resultant reaction mixture after the ZrO₂ shell formation process is a transparent dispersion in water.

### Example 11A

The resulting TiO₂—ZrO₂ core-shell nanocrystal is purified by precipitating the NC from the mother liquor using acetone in a 1:4 reaction mixture to acetone by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in ethanol in a 1:1 wetcake-to-ethanol by weight-to-weight ratio and precipitated with acetone in a 1:4 nanocrystal dispersion to acetone by weight-to-weight ratio. The resulting milky white suspension is centrifuged at 4500 rpm for 10-min and the supernatant decanted and wetcake collected.

The resulting wetcake is then transferred to a 1.0-L round bottom flask with the aid of ethanol to make a final suspension of 25% by weight of the wetcake in ethanol. It is stirred at room temperature for 15-min to get a homogenous distribution of the solids in the solvent. After the desired duration, methoxy(triethyleneoxy)propyltrimethoxysilane is then added to the reaction flask at 30% by weight of the silane to the wet cake. This mixture is then stirred at room temperature for 30-min. Ammonium hydroxide solution in water (28-30%) is carefully added to the reaction mixture in the flask at 30% by weight of the base to the wetcake. The mixture is heated to 70 degrees C. for 45-min. At the end of the 45-min hold time, sodium hypophosphite monohydrate powder is carefully added to the reaction mixture at 3% by weight to the weight of the wetcake and continued to hold at 70 C for another 30 min. When the reaction is complete, the mixture will have a light milky appearance. The mixture is stirred at room temperature for 1 hours.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in ETA (ethylacetate) to create a 50% by weight loaded dispersion. The resulting dispersion was filtered through a 0.45 micron and then a 0.2-micron absolute filter.

Capped titanium oxide nanocrystals with ZrO₂ shell dispersed at 50% by weight in ETA has a % organics of 11.32.

### Example 11B

The resulting TiO₂—ZrO₂ core-shell nanocrystal is purified by precipitating the NC from the mother liquor using acetone in a 1:4 reaction mixture to acetone by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in ethanol in a 1:1 wetcake-to-ethanol by weight-to-weight ratio and precipitated with acetone in a 1:4 nanocrystal dispersion to acetone by weight-to-weight ratio. The resulting milky white suspension is centrifuged at 4500 rpm for 10-min and the supernatant decanted and wetcake collected.

After the final centrifuge and decant step, the resulting wetcake is then transferred to a 1.0-L round bottom flask with the aid of ethanol to make a final suspension of 25% by weight of the wetcake in ethanol. It is stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 1 hour. After the desired duration, methoxy(triethyleneoxy)propyltrimethoxysilane is then added to the reaction flask at 30% by weight of the silane to the wet cake. This mixture is then stirred at room temperature for 30-min. Ammonium hydroxide solution in water (28-30%) is carefully added to the reaction mixture in the flask at 15% by weight of the base to the wetcake. The mixture is heated to 70 degrees C. for 45-min. At the end of the 45-min hold time, 3-(methacryloyloxy) propyl trimethoxysilane is carefully added to the nanocrystal suspension at 10% by weight to the weight of the wetcake. The reaction mixture is continued to be held at 70 C for an additional 30-min. When the reaction is complete, the mixture will have a light milky appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA or ETA (ethylacetate) to create a 50% by weight loaded dispersion. The resulting dispersion was filtered through a 0.45 micron and then a 0.2-micron absolute filter.

Capped titanium oxide nanocrystals with ZrO₂ shell dispersed at 50% by weight in ETA has a % organics of 9.93 and 9.55 respectively.

DLS of capped titanium oxide nanocrystals with ZrO₂ shell dispersed at 5% by weight in ETA demonstrates an average particle size of 33.850 nanometers by intensity versus particle and 24.42 nanometers by volume versus particle size with a narrow size distribution. D9999 of this dispersion is 85.5.

### Example 11C

The resulting TiO₂—ZrO₂ core-shell nanocrystal is purified by precipitating the NC from the mother liquor using acetone in a 1:4 reaction mixture to acetone by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in ethanol in a 1:1 wetcake-to-ethanol by weight-to-weight ratio and precipitated with acetone in a 1:4 nanocrystal dispersion to acetone by weight-to-weight ratio. The resulting milky white suspension is centrifuged at 4500 rpm for 10-min and the supernatant decanted and wetcake collected.

The resulting wetcake is redispersed in PGMEA in a 1:4 wetcake-to-PGMEA by weight-to-weight ratio. The resulting milky white suspension is centrifuged at 4500 rpm for 10-min and the supernatant decanted. The resulting wetcake is then transferred to a 1.0-L round bottom flask with the aid of PGMEA to make a final suspension of 25% by weight of the wetcake in PGMEA. It is stirred at room temperature for 15-min to get a homogenous distribution of the solids in the solvent. After the desired duration, methoxy(triethyleneoxy)propyltrimethoxysilane is then added to the reaction flask at 17% by weight of the silane to the wet cake. This mixture is then stirred at room temperature for 30-min. Ammonium hydroxide solution in water (28-30%) is carefully added to the reaction mixture in the flask at 15% by weight of the base to the wetcake. The mixture is heated to 100 degrees C. for 45-min. At the end of the 45-min hold time, 3-(methacryloyloxy) propyl trimethoxysilane is carefully added to the nanocrystal suspension at 30% by weight to the weight of the wetcake. The reaction mixture is continued to be held at 100 C for an additional 30-min. After which, sodium hypophosphite monohydrate powder is carefully added to the reaction mixture at 1% by weight to the weight of the wetcake and continued to hold at 70 C for another 30 min. When the reaction is complete, the mixture will have a light milky appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA or ETA (ethylacetate) to create a 50% by weight loaded dispersion. The resulting dispersion was filtered through a 0.45 micron and then a 0.2-micron absolute filter.

Capped titanium oxide nanocrystals with ZrO₂ shell dispersed at 50% by weight in ETA has a % organics of 13.99.

DLS of capped titanium oxide nanocrystals with ZrO₂ shell dispersed at 5% by weight in ETA demonstrates an average particle size of 29.81 nanometers by Intensity versus particle size and 15.11 nanometers by volume versus particle size with a narrow size distribution. D9999 of this dispersion is 88.5.

### Example 11D

The resulting TiO₂—ZrO₂ core-shell nanocrystal is purified by precipitating the NC from the mother liquor using acetone in a 1:4 reaction mixture to acetone by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in water in a 1:1 wetcake-to-water by weight-to-weight ratio and precipitated with acetone in a 1:4 nanocrystal dispersion to acetone by weight-to-weight ratio. The resulting milky white suspension is centrifuged at 4500 rpm for 10-min and the supernatant decanted and wetcake collected.

After the final centrifuge and decant step, the resulting wetcake is then transferred to a 1.0-L round bottom flask with the aid of water to make a final suspension of 15% by weight of the wetcake in water. It is stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 1 hour. After the desired duration, methoxy(triethyleneoxy)propyltrimethoxysilane is then added to the reaction flask at 30% by weight of the silane to the wet cake. This mixture is then stirred at room temperature for 30-min. Ammonium hydroxide solution in water (28-30%) is carefully added to the reaction mixture in the flask at 15% by weight of the base to the wetcake. The mixture is heated to 95 degrees C. for 45-min. At the end of the 45-min hold time, 3-(methacryloyloxy) propyl trimethoxysilane is carefully added to the nanocrystal suspension at 10% by weight to the weight of the wetcake. The reaction mixture is continued to be held at 95 C for an additional 30-min. When the reaction is complete, the mixture will have a light milky appearance.

The reaction mixture is then cooled to room temperature to yield slurry of white precipitate suspended in the reaction solvent. The solid white precipitate is collected by centrifugation at 3000 rpm for 10 min. The solids obtained is then dispersed in THF at 2:1 THF to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in THF at 2:1 THF to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA or ETA (ethylacetate) to create a 50% by weight loaded dispersion. The resulting dispersion was filtered through a 0.45 micron and then a 0.2-micron absolute filter.

Capped titanium oxide nanocrystals with ZrO₂ shell dispersed at 50% by weight in ETA has a % organics of 11.42%.

DLS of capped titanium oxide nanocrystals with ZrO₂ shell dispersed at 5% by weight in ETA demonstrates an average particle size of 43.23 nanometers by intensity versus particle and 29.21 nanometers by volume versus particle size with a narrow size distribution.

### Example 12

TiO₂ from example 1 collected as wet cake is dispersed into acetone and homogenized with zirconia beads. The homogenized TiO₂ is separated from the reaction mixture through centrifugation at 4500 rpm for 10-min. The supernatant is decanted, and the nanocrystal settles at the bottom of the centrifuge bottle as a wet cake. The purified TiO₂ wet-cake is then transferred to a 3-neck flask and water is added to the wet-cake (1:4 TiO₂ wetcake-to-water by weight). The mixture is stirred until the mixture became homogeneous. ZrOCl₂·8H₂O is then added to the reaction mixture (17% by weight to the TiO₂ wet cake) followed by CeCl₃·7H₂O (Cerium (III) chloride heptahydrate) or Ce₂CO₃)₃·xH₂O (cerium (III) carbonate hydrate) at 3% by weight to the TiO₂ wetcake. The reaction mixture is then heated at 90 C for 24 hours. After cooling to room temperature, the resultant reaction mixture after the ZrO₂ shell formation process is a transparent dispersion in water.

The resulting dispersion has a pH of 1 and is neutralized using aqueous ammonium hydroxide (5N) to pH 4. Ammonium hydroxide solution is added slowly to the reaction mixture upon stirring. pH change of the mixture is monitored with a pH meter. Once the pH reaches 4, the NC is collected from the reaction mixture using centrifuge. The NC from the mother liquor using acetone in a 1:4 reaction mixture to acetone by weight-to-weight ratio. The resulting milky white suspension is centrifuged at 4500 rpm for 10-min. The supernatant is decanted, and the nanocrystal settles at the bottom of the centrifuge bottle as a wetcake. The wetcake is redispersed in ethanol in a 1:1 wetcake-to-ethanol by weight-to-weight ratio and precipitated with acetone in a 1:4 nanocrystal dispersion to acetone by weight-to-weight ratio. The resulting milky white suspension is centrifuged at 4500 rpm for 10-min and the supernatant decanted.

After the final centrifuge and decant step, the resulting wetcake is re-dispersed in ethanol at 50% by weight and stirred at room temperature for 15-min to get a homogenous distribution of the solids in the solvent. Sodium hypophosphite monohydrate powder is carefully added to the nanocrystal suspension at 3% by weight to the weight of the wetcake. The mixture is stirred at room temperature for 12 hours. After the desired duration, the solid part is separated from the liquid by centrifuge at 4500 rpm for 10 min. The resultant supernatant is decanted off leaving a white wet solid cake at the bottom of the centrifuge bottle. This wet cake is then rinsed with ethanol at a 2.75 to 1 ratio solvent to wet cake weight-to-weight, followed by vigorously agitated. This suspension is then centrifuged again at 4500 rpm for 10 min, and the resulting supernatant decanted off the top. The resulting wetcake is capping according to the procedure described in example 12A and 12B.

### Example 12A

The wetcake from example 12 is then transferred to a 1.0-L round bottom flask with the aid of ethanol to make a final suspension of 25% by weight of the wetcake in ethanol. The mixture is stirred at room temperature for 15-min to get a homogenous suspension. Methoxy(triethyleneoxy)propyltrimethoxysilane is then added to the reaction flask at 30% by weight of the silane to the wet cake. This mixture is then stirred at room temperature for 15-min. Aqueous ammonium hydroxide (28-30%) is carefully added to the reaction mixture in the flask at 30% by weight of the base to the wetcake. The mixture is heated to 70 degrees C. for 45-min. When the reaction is complete, the mixture will have a translucent appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter.

Capped titanium oxide nanocrystals with ZrO₂ shell dispersed at 50% by weight in PGMEA has a % organics of 8.97.

DLS plot of capped titanium oxide nanocrystals with ZrO₂ shell dispersed at 5% by weight in PGMEA demonstrates an average particle size of 53.85 nanometers by Intensity versus particle size and 36.15 nanometers with a narrow size distribution. D9999 of this dispersion is 141.0.

### Example 12B

The wetcake from example 12 is then transferred to a 1.0-L round bottom flask with the aid of ethanol to make a final suspension of 25% by weight of the wetcake in ethanol. The mixture is stirred at room temperature for 15-min to get a homogenous suspension. After the desired duration, methoxy(triethyleneoxy)propyltrimethoxysilane is then added to the reaction flask at 30% by weight of the silane to the wet cake. This mixture is then stirred at room temperature for 30-min. Ammonium hydroxide solution in water (28-30%) is carefully added to the reaction mixture in the flask at 15% by weight of the base to the wetcake. The mixture is heated to 70 degrees C. for 45-min. At the end of the 30-min hold time, 3-(methacryloyloxy) propyl trimethoxysilane is carefully added to the nanocrystal suspension at 5% by weight to the weight of the wetcake. The reaction mixture is continued to be held at 70 C for an additional 30-min. When the reaction is complete, the mixture will have a light milky appearance.

The reaction mixture is then cooled to room temperature and washed to remove excess capping agent and impurities. The reaction mixture is diluted in THF at a 1:2 ratio of reaction mixture to THF and precipitated in an anti-solvent such as heptane in a 4:1 heptane to reaction mixture-THF weight-to-weight ratio. The suspension is centrifuged at 4500 rpm for 10 minutes. The resulting supernatant is decanted and discarded. The solids obtained is then dispersed in ethanol at 2:1 ethanol to wetcake weight-to-weight ratio. The dispersed solids is precipitated in an anti-solvent again such as heptane in a 4:1 heptane to reaction mixture weight-to-weight ratio. This suspension is centrifuged at 4500 rpm for 10 minutes. The resulting supernatant was decanted and discarded. The solids obtained again dispersed in ethanol at 2:1 ethanol to wetcake weight-to-weight ratio. The dispersed solids are again precipitated in an anti-solvent again such as heptane in a 4:1 heptane to reaction mixture weight-to-weight ratio. This precipitate is centrifuged at 4500 rpm for 10 minutes. The resulting supernatant is decanted and discarded. The solids are then placed in a vacuum oven to dry overnight.

The dried solids are redispersed in a 1:1 ratio of solids to solvent weight ratio in PGMEA to create a 50% by weight loaded dispersion. The resulting dispersion was filtered through a 0.45 micron and then a 0.2-micron absolute filter. capped titanium oxide nanocrystals with ZrO₂ shell dispersed at 50% by weight in PGMEA has a % organics of 10.03.

### Example 13: Formation of SiO₂ Shell on Capped TiO₂

Previously capped TiO₂ powder (51 g) was dispersed into ethanol (1400 g) using an acoustic mixer. After allowing it to sit overnight, the capped TiO₂ was resuspended and transferred into a 2-gallon reactor. The reactor was then closed and sealed. Stirring in the reactor was set at 150-200 RPM. A pressure check was done on the reactor, where it is held at 10 PSIG for 10 minutes and then vented to 2 PSIG. Aqueous ammonia (224 g) was added to 1900 g of water and then transferred into the reactor. The line was then flushed 470 g of water. 69 g of tetraethylorthosilicate was added to the reactor, followed by 100 g of ethanol. The reactor was inerted by pressurizing with N₂ and then venting to 2 PSIG (this was repeated 10 times). Stir rate was then increased to 600 rpm and the temperature was increased to 200 C. After holding at 200 C for three hours, the reactor was cooled room temperature. The reactor was then vented and the material discharged into a vessel. A white slurry was obtained.

### Example 14: Formation of SiO₂ shell on TiO₂

TiO₂ wetcake from example 1 is rinsed with ethanol by mixing a 1:1 ratio of ethanol to wet cake. The resulting milky white suspension is centrifuged at 4500 rpm for 10-min. The supernatant is decanted, and the nanocrystal settles at the bottom of the centrifuge bottle as a wet-cake. This purification step is repeated. The rinsed TiO₂ wet-cake (97 g) is then dispersed into ethanol (1400 g) using an acoustic mixer. After allowing it to sit overnight, the TiO₂ is resuspended and transferred into a 2-gallon reactor. The reactor is then closed and sealed. Stirring in the reactor is set at 150-200 RPM. A pressure check is done on the reactor, where it is held at 10 PSIG for 10 minutes and then vented to 2 PSIG. Aqueous ammonia (224 g) is added to 1900 g of water and then transferred into the reactor. The line is then flushed 470 g of water. 69 g of tetraethylorthosilicate is added to the reactor, followed by 100 g of ethanol. The reactor is inerted by pressurizing with N₂ and then venting to 2 PSIG (this is repeated 10 times). Stir rate is then increased to 600 rpm and the temperature is increased to 200 C. After holding at 200 C for three hours, the reactor is cooled room temperature. The reactor is then vented and the material discharged into a vessel. A white slurry is obtained.

### Example 15: Formation of HfO₂ Shell on TiO₂

TiO₂ from example 1 collected as wet cake is dispersed into acetone and homogenized with zirconia beads. The homogenized TiO₂ is separated from the reaction mixture through centrifugation at 4500 rpm for 10-min. The supernatant is decanted, and the nanocrystal settles at the bottom of the centrifuge bottle as a wet cake. This process is repeated. The wet cake (wet solid) obtained is then dispersed into water using zirconia beads until a homogeneous mixture was obtained. The TiO₂ is again collected through centrifugation at 4500 rpm for 10-min. The supernatant is decanted, and the nanocrystal settles at the bottom of the centrifuge bottle as a wetcake. This process is repeated again. The purified TiO₂ wet-cake is then transferred to a 3-neck flask and water is added to the wet-cake (10:1 to the TiO₂ wet-cake weight). HfOCl₂·8H₂O is then added to the reaction mixture (38% by weight to the TiO₂ wet cake). The mixture is stirred until the mixture became homogeneous. The reaction mixture is then heated at 90 C for 24 hours. After cooling to room temperature, the resultant reaction mixture after the ZrO₂ shell formation process is a transparent dispersion in water.

The nanocrystals are capped as described in example 7.

### Example 16: Formation of A12O₃ Shell on TiO₂

TiO₂ from example 1 collected as wet cake is dispersed into acetone and homogenized with zirconia beads. The homogenized TiO₂ is separated from the reaction mixture through centrifugation at 4500 rpm for 10-min. The supernatant is decanted, and the nanocrystal settles at the bottom of the centrifuge bottle as a wet cake. This process is repeated. The wet cake (wet solid) obtained is then dispersed into water using zirconia beads until a homogeneous mixture was obtained. The TiO₂ is again collected through centrifugation at 4500 rpm for 10-min. The supernatant is decanted, and the nanocrystal settles at the bottom of the centrifuge bottle as a wetcake. This process is repeated. The purified TiO₂ wet-cake is then transferred to a 3-neck flask and water is added to the wet-cake (10:1 to the TiO₂ wet-cake weight). The pH of the reaction mixture was adjusted to pH 10 using 2M NaOH solution. The mixture was then heated to 60 C and a solution of 2M NaAlO₂ in water was added to the reaction mixture (the total amount of NaAlO₂ added was 35% of the weight of TiO₂ nanocrystals). The pH of the reaction mixture was then adjusted to pH 8 using 2M HCl solution. The reaction mixture temperature was raised to 90 C for 12-hrs. After cooling to room temperature, the product was centrifuged and washed twice with water and then twice with ethanol.

### Example 17: Test to Determine the UV Stability of the Uncapped Nanocrystals

The stability of the titanium oxide, and titanium oxide with a metal oxide shell of the present disclosure to various film processing conditions are tested using a home-made color test. Polystyrene-PGMEA dispersion is prepared by dissolving polystyrene in PGMEA at 50% by weight of polystyrene in PGMEA. The dried nanocrystal powder is mixed vigorously in the polystyrene-PGMEA dispersion at 1:2 nanocrystal to polystyrene/PGMEA dispersion weight-to-weight ratio for 10-min to yield a white opaque viscous paste. The viscous paste or drop-cast is dropped onto a glass surface using a pipette and processed. The drop-cast is baked at 110 C for 5-min on a hot plate under air, followed by UV exposure using a Hg boardband lamp for 120 sec (5 J/cm²) or a 365-nm UV-LED lamp for 60 sec (7.5 J/cm²). The drop-cast is then baked at 135 C for 5-min on a hot plate under air, followed by an additional bake process in an oven at 200C for 5-min. The degree of color change of the drop-cast during each processing step is recorded for any discoloration. Any type of discoloration is gauged as stability to that process. UV stability. The results of the TiO2 nanocrystals without shell and with ZrO2 shell to various film processing conditions is shown in Tables 1 and 2.

TABLE 1
The results of the drop-cast of paste comprising TiO₂ nanocrystals without any shell and
TiO2 nanocrystals with ZrO₂ shell present in this disclosure and polystyrene mixed with
polystyrene after each processing step. The TiO2 nanocrystals are not capped and do
not have any inorganic treatment The discoloration upon UV irradiation is ranked
from 0 to 6; ‘0’ signifies no change and ‘6’ signifies the most yellowing after a process.
The TiO₂ without any ZrO₂ shell shows the most yellowing especially after UV
irradiation, while the ones with ZrO₂ shell showed less discoloration during the process.

| | Samples | | | |
|---|---|---|---|---|
| | As-synthesized | TiO₂ | TiO₂ | TiO₂ |
| | TiO₂ | nanocrystals | nanocrystals | nanocrystals |
| | nanocrystals | with ZrO₂ shell | with ZrO₂ shell | with ZrO₂ shell |
| | (without any | (50% ZrO2 shell | (30% ZrO2 shell | (15% ZrO2 shell |
| | shell) | precursor) | precursor) | precursor) |
| Initial | 0 | 0 | 0 | 0 |
| After heating at | 0 | 0 | 0 | 0 |
| 110° C./5 min | | | | |
| After UV | 5 | 1 | 0 | 1 |
| exposure (Hg | | | | |
| boardband) for | | | | |
| 2 min at 5 J/cm² | | | | |
| After heating at | 6 | 4 | 2 | 2 |
| 135° C./5 min | | | | |

Table 1: The results of the drop-cast of paste comprising TiO₂ nanocrystals without any shell and TiO₂ nanocrystals with ZrO₂ shell present in this disclosure and polystyrene mixed with polystyrene after each processing step. The nanocrystals are not capped and do not have any inorganic treatment. Upon exposure to different conditions, the paste undergoes discoloration. The discoloration is ranked from 0 to 6; ‘0’ signifies no change and ‘6’ signifies the most yellowing after a process. The TiO₂ without any ZrO₂ shell shows the most yellowing especially after UV irradiation, while the ones with ZrO₂ shell showed less discoloration during the process.

Shown in table 2 are coupons of a paste prepared by mixing at least partially capped TiO₂ nanocrystals that are treated with inorganic passivation agents during capping with polystyrene on a glass substrate and at various stages of film processing conditions. The TiO₂ nanocrystals without any inorganic treatment turns yellow upon heat, meanwhile the TiO₂ nanocrystals with an inorganic treatment shows less dis-coloration. Additionally, shown in table 3 is the thermal stability of the at least partially capped titanium oxide nanocrystals with ZrO₂ shell powder subjected to higher temperatures at from 100° C. to 200 C for a period.

TABLE 2
The results of the paste comprising without any metal oxide shell and containing different
inorganic treatments when exposed to various film processing conditions. Upon exposure
to different conditions, the paste undergoes discoloration. The discoloration is ranked
from 0 to 6; ‘0’ signifies no change and ‘6’ signifies the most yellowing after a process.
The TiO₂ without any ZrO₂ shell shows the most yellowing especially after UV
irradiation, while the ones with ZrO₂ shell showed less discoloration during the process.

| | Samples | | | | | |
|---|---|---|---|---|---|---|
| | TiO₂ | TiO₂ | TiO₂ | | TiO₂ | |
| | nanocrystals- | nanocrystals | nanocrystals | TiO₂ | nanocrystals | TiO₂ |
| | no | with | with | nanocrystals | with | nanocrystals |
| | treatment | NaH₂PO₂ | NaNO₃ | with NaCl | LiNO₃ | with LiCl |
| After | 2 | 0 | 0 | 0 | 0 | 0 |
| heating at | | | | | | |
| 110° C./5 min | | | | | | |
| After UV | 4 | 0 | 1 | 0 | 1 | 0 |
| exposure | | | | | | |
| (Hg | | | | | | |
| boardband) | | | | | | |
| for 2 min | | | | | | |
| at 5 J/cm² | | | | | | |
| After | 6 | 0 | 2 | 2 | 3 | 3 |
| heating at | | | | | | |
| 135° C./5 min | | | | | | |
| After | 6 | 0 | 3 | 3 | 4 | 5 |
| heating an | | | | | | |
| additional | | | | | | |
| 5 mins at | | | | | | |
| 200° C. | | | | | | |

### Example 18: Thermal Stability of the Capped TiO₂—ZrO₂ Core Shell Nanocrystals

The thermal stability of the at least partially capped titanium oxide and core-shell nanocrystals of the present disclosure is tested by subjecting the dried powder of the capped nanocrystals, prior to dispersion in any solvent, to different temperature in air for different duration of time. Around 1 g of the dried capped nanocrystal powder is taken in an aluminum pan and is placed in an oven. The powder is baked at the desired temperature for a set duration of time. The degree of color change of the powders is recorded and gauged as thermal stability. The results from one such experiment is shown in table 3.

Compared to the TiO₂ without any oxide shell (oxide coating), TiO₂ nanocrystals without ZrO₂ shell but having only inorganic treatment (example 10) does not show any discoloration upon upto 150 C and small amount of discoloration at 200 C/10 min heating (Table 3). TiO₂ nanocrystals with the ZrO₂ shell (example 5) but no inorganic treatment shows less discoloration at lower temperature but starts to discolor at higher temperatures. However, TiO₂ nanocrystals with ZrO₂ shell and an inorganic treatment shows better thermal stability. This indicates that inorganic treatment is necessary to make the nanocrystals more thermally stable.

TABLE 3
The results of the dry powder before and after subjecting
to higher temperature. The discoloration is ranked from 0
to 6; ‘0’ signifies no change and ‘6’ signifies
the most yellowing after a process.

| | | 100° C./ | 100° C./ | |
|---|---|---|---|---|
| | | 30 min + | 30 min + | |
| | | 150° C./ | 150° C./ | 200° C./ |
| | No heat | 15 min | 30 min | 10 min |
| As-synthesized TiO₂ | 3 | 6 | 6 | 6 |
| without oxide coating or | | | | |
| inorganic treatment | | | | |
| TiO₂ with oxide coating | 0 | 3 | 4 | 6 |
| but no inorganic | | | | |
| treatment (example 5) | | | | |
| TiO₂ with oxide coating | 0 | 0 | 1 | 4 |
| and inorganic | | | | |
| treatment (example 6) | | | | |
| TiO₂ with oxide coating | 0 | 1 | 2 | 4 |
| and inorganic | | | | |
| treatment (example 7) | | | | |
| TiO₂ with oxide coating | 0 | 0 | 0 | 1 |
| and inorganic treatment | | | | |
| (example 8) | | | | |
| TiO₂ without oxide coating | 0 | 0 | 0 | 1 |
| but only inorganic | | | | |
| treatment (example 10) | | | | |

### Example 19: Formulation and Nanocomposite Process Using TiO₂ Nanocrystals Comprising a Metal Oxide Shell

An exemplary formulation comprises PGMEA as the solvent, acrylic monomer combinations of HR6042 and BPMA (1:1 by weight of HR6042-to-BPMA), at least partially capped titanium oxide nanocrystals of the present disclosure at 1.6:1 weight ratio of the nanocrystal to combined weight of monomers, and photoinitiator, TPO, 4% by weight to the combined monomer weights.

Monomers, HR6042 and BPMA, is mixed at 1:1 weight ratio. A 50% by weight of the capped titanium oxide nanocrystal with ZrO₂ shell in propylene glycol monomethyl ether acetate (PGMEA) is mixed with the monomers, at 1.6:1 ratio of nanocrystal to combined monomer weight. The mixture is blended by stirring on a stir plate using magnetic stirrer or vortexing at 25-30 C temperature for 1-2 hours to allow homogenous mixture. Photoinitiator, TPO added to the formulation at 4% by weight to the monomers and again mixed at room temperature on a stir plate using a magnetic stirrer for an additional 5-30 minutes at temperature of 20-30 C. The resulting formulation is filtered through a membrane filter to yield a clear, transparent, liquid. The viscosity of the formulation is between 5-6 cP which is measured by Brookfield RVDV-II+PCP cone and plate viscometer.

The nanocomposite coating or films with this formulation is coated on a 2.5×2.5-inch (0.7 mm thick) soda lime glass wafer. The glass wafer is cleaned according to the internal cleaning procedure before applying the film to remove contaminants and dusts. 1-2-micron thick film is either spin coated at 2000-4000 rpm for 1 minute on the glass wafer. Since this is a solvent-containing formulation, the coated film is processed by an initial bake process at 110 C for 2 minutes on a hot plate to remove some solvent prior to UV exposure. The film is then exposed to 365 nm LED for 90 seconds under nitrogen using Phoseon FireJet LED lamps (365 nm) at 125 mW/cm² (11.25 J/cm²). The film is then subjected to a 2-minute post bake on a hotplate at 135 C to remove residual solvents. The film thickness is measured using a Metricon 2010/M prism coupler.

Table 4 shows the film properties for some exemplary 1-micron thick nanocomposites comprising at least partially capped titanium oxide or core-shell nanocrystals of the present disclosure prepared following example 19. The refractive index and the film thickness is measured using Metricon's 2010/M model Prism Coupler and the b* and % haze is measured with HunterLab's Vista hazemeter. The low % haze signifies high clarity of the film.

TABLE 4
Optical properties of the nanocomposites made
using formulation described in example 19

| | RI at 520 | | |
|---|---|---|---|
| Nanocrystals | nm | b* | % haze |
| Example 5 | 1.9018 | 0.56 | 0.04 |
| Example 6 | 1.9053 | 0.52 | 0.10 |
| Example 7 | 1.9062 | 0.5 | 0.05 |
| Example 8 | 1.8984 | 0.67 | 0.08 |
| Example 10 | 1.9496 | 0.75 | 0.48 |

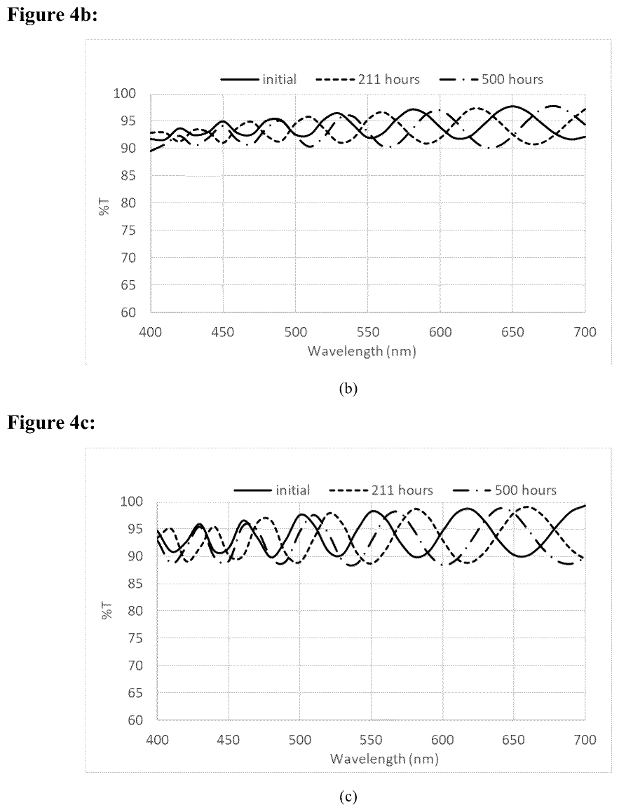

The nanocomposites produced with the formulation demonstrate high optical transmittance. FIG. 4 shows the optical transmittance of an as-made (solid line) films with (a) nanocrystals from example 5, (b) nanocrystals from example 6, and (c) nanocrystals from example 7, as measured by Perkin Elmer Lambda 850 spectrophotometer with a blank soda lime glass as the reference or background. The thickness of the film is about 1 micron. The films show an optical transmittance of >90% at wavelengths between 375-800 nm. The ripples in the spectrum are the results of interference of incoming light and reflected light, it usually is an indication of high film quality, i.e. high smoothness, high uniformity, and high transparency.

### Example 20: UV Stability Testing of Nanocomposites Prepared as Example 19

Nanocomposites made from nanocrystals presented in this disclosure prepared as described in example 19 are evaluated for photocatalytic stability by exposing the nanocomposites to various UV wavelength ranges for a set duration of time. The wavelengths of exposure used are 320-390 nm (intensity of 4 mW/cm²) for 66 hours (dosage of 950.4 J/cm²) or 72 hours (dosage 1036.8 J/cm²), 450 nm (intensity of 16 mW/cm²) for 1000 hours (dosage of 57600 J/cm²) and 405 nm (intensity of 25 mW/cm²), for 148 hours (dosage of 13600 J/cm²). The general film properties such as b*, % haze, RI and film thickness of the nanocomposites are measured at different intervals during the test. At the end of the test, change in b*, % haze, RI and film thickness of the films from start to the end of the test is evaluated to determine photostability of the nanocrystals to UV irradiations. The nanocomposite that shows the least change in film properties are considered to be the most photo-stable. The refractive index and the film thickness is measured using Metricon's 2010/M model Prism Coupler and the b* and % haze is measured with HunterLab's Vista hazemeter.

### Example 20A: Photostability Testing at 320-390 nm

Nanocomposites made from TiO₂ nanocrystals with ZrO₂ shell such as the ones described in examples 5, 6, 7, and 8 are tested for their photostability to 320-390 nm UV irradiation along with those that do not have the ZrO₂ shell (TiO₂ with no shell) and inorganic treated nanocrystals of example 10. Table 5 shows the film properties of these nanocomposites before any exposure and the change in the film properties (b*, % haze, RI and film thickness) after the exposure. Compared to TiO₂ nanocrystals with no shell and example 10, examples 5, 6, 7 and 8 show the least b* change and % haze change. The lower b* change of nanocomposites of examples 5, 6, 7 and 8 indicates that the TiO₂ with the ZrO₂ shell are not yellowing to the extent as the nanocrystals with no shell. The lower % haze change also indicates that there is less degradation of the nanocomposite upon exposure to light. A typical indication of TiO₂ photocatalytic activity is the appearance of chalkiness and increased haziness in coatings.

TABLE 5
The change in b*, % haze, RI at 520 nm and film thickness upon exposure
to 320-390 nm wavelength for 66 hours (950.4 J/cm²) continuously.

| | | | | | | | Film thickness (FT) | |
|---|---|---|---|---|---|---|---|---|
| | b* | | % haze | | RI at 520 nm | | (micron) | |
| Examples | Initial | Delta | Initial | Delta | Initial | Delta | Initial | % FT loss |
| Non-shelled | 1.44 | 5.36 | 0.48 | −0.05 | 1.9301 | −0.01 | 1.27 | 20 |
| TiO2 NC | | | | | | | | |
| Example 10 - | 0.75 | 7.62 | 0.48 | 0.03 | 1.9496 | −1.95 | 2.07 | 43 |
| no shell | | | | | | | | |
| Example 5 | 0.63 | 0.56 | 0.06 | 0.24 | 1.8354 | 0.04 | 1.57 | 27 |
| Example 6 | 0.55 | 1.55 | 0.05 | 0.04 | 1.8891 | −0.04 | 1.33 | 22 |
| Example 7 | 0.69 | 1.10 | 0.03 | 0.05 | 1.8933 | 0.02 | 1.32 | 20 |
| Example 8 | 0.67 | 1.02 | 0.08 | 0.03 | 1.8984 | −1.90 | 1.30 | 22 |

### Example 20B: Photostability Testing at 405 nm

Nanocomposites made with the nanocrystals described in examples 7, 11B, 11IC, 12A, 12B are tested for their photostability to 405 nm UV irradiation for 148 hours along with those that do not have the ZrO₂ shell (TiO2 with no shell). Table 6 shows the film properties of these nanocomposites before any exposure and the change in the film properties (b*, % haze, RI and film thickness) after the exposure. Of the samples in the list, TiO₂ nanocrystal without the ZrO₂ shell shows the highest initial b* and the highest b* change.

TABLE 6
The change in b*, % haze, RI at 520 nm and film thickness upon exposure
to 405 nm wavelength for 148 hours (13600 J/cm²)continuously.

| | | | | | | | Film thickness | |
|---|---|---|---|---|---|---|---|---|
| | b* | | Haze | | RI at 520 nm | | (FT) (nm) | |
| Examples | Initial | Delta | Initial | Delta | Initial | Delta | Initial | % FT loss |
| Non-shelled TiO2 | 1.49 | 1.28 | 0.22 | 0.22 | 1.9088 | 0.06 | 927.3 | 28 |
| NC | | | | | | | | |
| Example 7 | 0.55 | 0.29 | 0.06 | 0.20 | 1.8779 | 0.04 | 957.5 | 16 |
| Example 11B | 0.59 | 0.52 | 0.08 | −0.01 | 1.8770 | 0.03 | 1067.5 | 10 |
| Example 11C | 0.59 | 0.28 | 0.11 | 0.01 | 1.8582 | 0.05 | 1093.9 | 17 |
| Example 12A | 0.61 | 0.42 | 0.02 | 0.16 | 1.8958 | 0.04 | 903.8 | 7 |
| Example 12B | 0.52 | 0.21 | 0.05 | 0.23 | 1.8775 | 0.03 | 1075.9 | 10 |

### Example 20C: Photostability Testing at 450 nm

Nanocomposites made with the nanocrystals described in examples 5, 6 and 7 are tested for their photostability to 450 nm UV irradiation for 1000 hours along with those that do not have the ZrO₂ shell (TiO₂ with no shell). Table 7 shows the film properties of these nanocomposites before any exposure and the change in the film properties (b*, % haze, RI and film thickness) after the exposure. Of the samples in the list, TiO₂ nanocrystal without the ZrO₂ shell shows the highest initial b* and the highest b* change.

TABLE 7
The change in b*, % haze, RI at 520 nm (measured using
Prism Coupler) and film thickness upon exposure to 450 nm wavelength
for 1000 hours (57600 J/cm²) continuously.

| | | | % | | | | | |
|---|---|---|---|---|---|---|---|---|
| | | | haze | | | | Film thickness | |
| | b* | | | Delta | RI at 520 nm | | (microns) | |
| | | Delta | | % | | Delta | | % FT |
| Examples | Initial | b* | Initial | haze | Initial | RI | Initial | loss |
| Non- | 1.42 | 0.60 | 0.67 | 0.10 | 1.9316 | −0.08 | 1.33 | 17 |
| shelled | | | | | | | | |
| TiO2 NC | | | | | | | | |
| Example 5 | 0.43 | 0.32 | 0.55 | 0.04 | 1.8385 | 0.09 | 1.47 | 26 |
| Example 6 | 0.60 | 0.32 | 0.20 | 0.20 | 1.8963 | 0.07 | 1.33 | 17 |
| Example 7 | 0.65 | 0.37 | 0.18 | 0.14 | 1.8918 | 0.07 | 1.31 | 14 |

### Example 21: Solvent-Free Formulation (Solvent-Free)

Another exemplary formulation comprises at least partially capped nanocrystals presented in this disclosure and at least one monomer. Nanocrystals are present in the range of 65-75% by weight with respect to the total formulation. Monomers include at least one of 2-PEA, PTEA, PEA, PBA, and/or IBA present in the range of 3-18 weight percent with respect to the total formulation, and THEICTA (M370) present in the range of 1-10 weight percent with respect to the total formulation. Formulation optionally contains an additive such as T405 (Tinivin 405), 11010 (Irganox 1010), present in the range of 0.5-2.5 weight percent with respect to the total formulation, photoinitiator TPO, present in the range of 0.5-2.5 weight percent with respect to the total formulation and residual solvent, present in the range of 4.0-6.5 weight percent with respect to the total formulation. The formulation is prepared as described in method 2 of the present disclosure. At least partially capped nanocrystals dispersed in a low boiling solvent, ETA, is mixed with monomers, additives, and photoinitiator. After mixing, the formulation is rotoevaporated to remove the solvent and create a homogenous solvent free mixture. Several variations of the formulation are prepared with different nanocrystals present in the disclosure. Table 8a includes compositions, and viscosities for such formulations.

The formulation is spin coated on glass substrates and cured under N₂ with 365 nm UV lamp with 3 J/cm² dose. Films are also coated on PET substrate that have a glass backing and use a PET as a stamp covering. These films are then cured in air with a broadband UV lamp with 1 J/cm² dose. Initial optical properties of the cured films and change in properties after exposure to different wavelengths of light, and condensation conditions are shown in Tables 8b, 8c, and 8d.

### Example 21A

An exemplary formulation comprises 73.0 wt % of at least partially capped TiO₂ nanocrystals with no ZrO₂ shell, 14.6 wt % 2-PEA and 7.5 wt % THEICTA, 1.0% TPO, and 4.5% residual solvent after rotoevaporation. The viscosity of the formulation is 1030 cP at 25 C as measured by Brookfield RVDV-II+PCP cone and plate viscometer. A film of 10-micron thickness produced with the formulation demonstrates a RI of 1.86 at 589 nm on a glass or PET substrates. Films on glass substrates are made by spin coating the formulation, then UV cure under N2 with 365 nm UV lamp with 3 J/cm² dose. Films on PET have a glass backing and use a PET as a stamp covering then cured in air with a broadband UV lamp with 1 J/cm² dose.

### Example 21B

An exemplary formulation comprises 70.0 wt % of at least partially capped TiO2 nanocrystals with no ZrO₂ shell, 15.9 wt % 2-PEA and 8.6 wt % THEICTA, 1.0% TPO, and 4.5% residual solvent after rotoevaporation. The viscosity of the formulation is 660 cP at 25 C as measured by Brookfield RVDV-II+PCP cone and plate viscometer. A film of 10-micron thickness produced with the formulation demonstrates a RI of 1.85 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21C

An exemplary formulation comprises 71.0 wt % of at least partially capped TiO₂ nanocrystals with ZrO₂ shell of example 11A, 14.6 wt % 2-PEA and 7.9 wt % THEICTA, 2.0% TPO, and 4.5% residual solvent after rotoevaporation. The viscosity of the formulation is 700 cP at 25 C as measured by Brookfield RVDV-II+PCP cone and plate viscometer. A film of 10-micron thickness produced with the formulation demonstrates a RI of 1.84 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21D

An exemplary formulation comprises 71.0 wt % of at least partially capped TiO₂ nanocrystals with ZrO₂ shell of example 11A, 17.2 wt % PEA and 5.3 wt % THEICTA, 2.0% TPO, and 4.5% residual solvent after rotoevaporation. The viscosity of the formulation is 950 cP at 25 C as measured by Brookfield RVDV-II+PCP cone and plate viscometer. A film of 10-micron thickness produced with the formulation demonstrates a RI of 1.81 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21E

An exemplary formulation comprises 71.6 wt % of at least partially capped TiO₂ nanocrystals with ZrO₂ shell of example 11B, 13.7 wt % 2-PEA and 7.4 wt % THEICTA, 1.0% TPO, and 6.4% residual solvent after rotoevaporation. The viscosity of the formulation is 1700 cP at 25 C as measured by Brookfield RVDV-II+PCP cone and plate viscometer. A film of 10-micron thickness produced with the formulation demonstrates a RI of 1.82 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21F

An exemplary formulation comprises 72.8 wt % of at least partially capped TiO₂ nanocrystals with ZrO₂ shell of example 11B, 10.2 wt % 2-PEA, 5.1% PBA, and 3.7 wt % THEICTA, 1.9% TPO, and 6.3% residual solvent after rotoevaporation. The viscosity of the formulation is 2200 cP at 25 C as measured by Brookfield RVDV-II+PCP cone and plate viscometer. A film of 10-micron thickness produced with the formulation demonstrates a RI of 1.8 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21G

An exemplary formulation comprises 71.6 wt % of at least partially capped TiO₂ nanocrystals with ZrO₂ shell of example 11B, 13.7 wt % 2-PEA and 4.4 wt % THEICTA, additives 1.0% T405, 2.0% 11010, 1.0% TPO, and 6.4% residual solvent after rotoevaporation. The viscosity of the formulation is 2700 cP at 25 C as measured by Brookfield RVDV-II+PCP cone and plate viscometer. A film of 10-micron thickness produced with the formulation demonstrates a RI of 1.81 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21H

An exemplary formulation comprises 73.0 wt % of at least partially capped TiO₂ nanocrystals with ZrO₂ shell of example 6, 14.0 wt % 2-PEA and 7.5 wt % THEICTA, 1.0% TPO, and 4.5% residual solvent after rotoevaporation. The viscosity of the formulation is 4180 cP at 25 C as measured by Brookfield RVDV-II+PCP cone and plate viscometer. A film of 10-micron thickness produced with the formulation demonstrates a RI of 1.83 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 211

An exemplary formulation comprises 71.0 wt % of at least partially capped TiO₂ nanocrystals with ZrO₂ shell of example 11A, 14.6 wt % IBA and 7.9 wt % THEICTA, 2.0% TPO, and 4.5% residual solvent after rotoevaporation. The viscosity of the formulation is 1510 cP at 25 C as measured by Brookfield RVDV-II+PCP cone and plate viscometer. A film of 10-micron thickness produced with the formulation demonstrates a RI of 1.78 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

### Example 21J

An exemplary formulation comprises 71.6 wt % of at least partially capped TiO₂ nanocrystals with ZrO₂ shell of example 1 ID, 13.7 wt % 2-PEA and 4.4 wt % THEICTA, additives 1.0% T405, 2.0% 11010, 1.0% TPO, and 6.4% residual solvent after rotoevaporation. The viscosity of the formulation is 2700 cP at 25 C as measured by Brookfield RVDV-II+PCP cone and plate viscometer. A film of 10-micron thickness produced with the formulation demonstrates a RI of 1.81 at 589 nm on a glass or PET substrates. Films on glass substrates are made by spin coating the formulation, then UV cure under N₂ with 365 nm UV lamp with 3 J/cm² dose. Films on PET have a glass backing and use a PET as a stamp covering then cured in air with a broadband UV lamp with 1 J/cm² dose.

TABLE 8a
Summary of formulation composition and properties of the formulations described in example 21.
Included samples with titania nanocrystals and titania-zirconia core shell nanocrystals.

| Formulation | Viscosity | | | | | | | | | | | Residual |
|---|---|---|---|---|---|---|---|---|---|---|---|---|
| ID | (cP) | NC | 2PEA | PTEA | PEA | PBA | IBA | M370 | T405 | I1010 | TPO | Solvent |
| 21A | 1030 | 73.0 | 14.0 | — | — | — | — | 7.5 | — | — | 1.0 | 4.5 |
| 21B | 660 | 70.0 | — | 15.9 | — | — | — | 8.6 | — | — | 1.0 | 4.5 |
| 21C | 700 | 71.0 | 14.6 | — | — | — | — | 7.9 | — | — | 2.0 | 4.5 |
| 21D | 950 | 71.0 | — | — | 17.2 | — | — | 5.3 | — | — | 2.0 | 4.5 |
| 21E | 1700 | 71.6 | 13.7 | — | — | — | — | 7.4 | — | — | 1.0 | 6.4 |
| 21F | 2200 | 72.8 | 10.2 | — | — | 5.1 | — | 3.7 | — | — | 1.9 | 6.3 |
| 21G | 2700 | 71.6 | 13.7 | — | — | — | — | 4.4 | 1.0 | 2.0 | 1.0 | 6.4 |
| 21H | 4180 | 73.0 | 14.0 | — | — | — | — | 7.5 | — | — | 1.0 | 4.5 |
| 21I | 1510 | 71.0 | — | — | — | — | 14.6 | 7.9 | — | — | 2.0 | 4.5 |
| 21J | 2000 | 71.6 | 13.7 | — | — | — | — | 4.4 | 1.0 | 2.0 | 1.0 | 6.4 |

TABLE 8b
Shown are the optical properties of the nanocomposites described in example
21 when exposed to 405 UV light exposure for 148 hours (25 mW/cm²). The Initial
and change in optical properties for films on PET substrate are measured.
The change in b* is significantly higher for the 21A nanocomposite compared
to the b* for nanocomposites 21E, 21F, and 21I where films were made with similar
thicknesses on the same substrates. The film thickness and RI change were comparable
for all nanocomposites; however, starting RI values are lower for the nanocomposites
made with nanocrystals with ZrO₂ shell.

| | | | | | | | Film | ΔFilm |
|---|---|---|---|---|---|---|---|---|
| | Film | Δ | | | Film RI | ΔFilm RI | Thickness | Thickness |
| Film ID | % Haze | % Haze | Film b* | Δb* | (520 nm) | (520 nm) | (um) | (um) |
| 21A | 1.92 | 2.43 | 1.53 | 11.01 | 1.89 | 0.04 | 9.6 | 2.1 |
| 21E | 2.22 | 1.08 | 0.98 | 0.56 | 1.85 | 0.04 | 11.1 | 2.7 |
| 21F | 1.52 | 1.06 | 0.86 | 0.62 | 1.87 | 0.04 | 9.6 | 2.2 |
| 21I | 1.18 | 4.33 | 1.07 | 0.22 | 1.80 | 0.06 | 9.3 | 2.1 |

TABLE 8c
Shown are the optical properties of the nanocomposites
described in example 21 when exposed to UVA
light at 320-390 nm for 72 hours (dosage 1036.8 J/cm²;
average intensity of 4 mW/cm²).
The Initial and change in optical properties for films on glass
substrate are measured. Nanocomposites 21A and 21B are
made with the same titania nanocrystal with different monomer mixes.

| | | | | | | Film |
|---|---|---|---|---|---|---|
| Film | Film | Delta | | | Film RI | Thickness |
| ID | % Haze | % Haze | Film b* | Delta b* | (589 nm) | (um) |
| 21A | 0.99 | 0.19 | 1.14 | 14.13 | 1.86 | 7.3 |
| 21B | 0.37 | −0.05 | 1.91 | 7.77 | 1.85 | 10.6 |
| 21C | 1.46 | 3.22 | 0.93 | 3.22 | 1.84 | 8.6 |
| 21D | 0.91 | 0.31 | 0.76 | 0.31 | 1.81 | 10.0 |
| 21E | 0.64 | 0.02 | 1.48 | 1.79 | 1.82 | 13.0 |
| 21H | 0.93 | 0.47 | 1.22 | 1.73 | 1.83 | 10.3 |

TABLE 8d
Shown are the optical properties of the nanocomposites described in example 21
when exposed to QUV accelerated weathering test at 340 nm for 72 hours (0.89
mW/cm²). The initial and change in optical measurements are performed on PET
samples. Δ E* is a calculated value that incorporates the Δ L*, Δ a*, and Δ b*

| | | | | | | | | | | | Film |
|---|---|---|---|---|---|---|---|---|---|---|---|
| Film | | Δ | | | | | | | | RI (589 | Thickness |
| ID | % Haze | % Haze | L* | Δ L* | a* | Δ a* | b* | Δ b* | Δ E* | nm) | (um) |
| 21A | 1.19 | 5.08 | 97.49 | −4.39 | −0.01 | −1.53 | 1.93 | 21.3 | 21.9 | 1.86 | 10.1 |
| 21E | 3.40 | 9.68 | 98.01 | −3.23 | 0.12 | −0.57 | 0.81 | 4.9 | 5.9 | 1.81 | 7.9 |
| 21G | 1.52 | 7.83 | 98.27 | −1.81 | 0.14 | −0.79 | 0.84 | 3.9 | 4.4 | 1.81 | 6.6 |
| 21J | 1.3 | | 88.58 | −0.43 | −3.01 | −0.68 | 5.24 | 3.69 | 3.86 | 1.79 | 13 |

### Example 22: Nanocomposite Formulation (Solvent-Containing)

An exemplary formulation comprises at least partially capped nanocrystals present in this disclosure, present in the range of 20-60 weight with respect to total formulation, monomer blends comprising PBA and/or THEICTA, present in the range of 3-25 weight percent with respect to the total formulation such that nanocrystals to monomer ratio ranges from 3:7 to 8:2, photoinitiator, TPO, present in the range of 0.5-2.5 weight percent with respect to the total formulation and solvent such as PGMEA (PGA), present in the range of 20-40 weight percent with respect to the total formulation. The formulation is prepared as described in method 2 of the present disclosure. Preferred PBA to THEICTA (or M370) ratio is in that range of 1:1 to 4:1. Table 9a shows compositions and viscosities of exemplary formulations.

2-3 micron thick nanocomposite films of the formulations are prepared on glass substrates by spin coating the formulation, prebaking on a hot plate at 50 C for 5 min, then UV cure under N₂ with 365 nm UV lamp with 3 J/cm² dose, and post baked in the oven at 100 C for 5 min. Table 9b includes optical properties of the nanocomposites or films before and after UV aging under 405 nm for 148 hours (dosage 13600 J/cm²).

### Example 22A

An exemplary formulation comprises 45.3 wt % at least partially capped TiO₂ nanocrystals with no shell in a blend of acrylates consisting of 18.3 wt % PBA, 5.6 wt % THEICTA, 0.8 wt % TPO, and 30.0 wt % PGMEA. The viscosity of the formulation is 18 cP at 25 C as measured by Brookfield RVDV-II+PCP cone and plate viscometer. The nanocomposite is deposited as a 2-3 micron film and has 1.82 cured film RI at 589 nm on a glass substrate.

### Example 22B

An exemplary formulation comprises 45.3 wt % at least partially capped core shell nanocrystals of example 11B in a blend of acrylates consisting of 13.1 wt % PBA, 4.0 wt % THEICTA, 0.7 wt % TPO, and 30.5 wt % PGMEA. The viscosity of the formulation is 18.4 cP at 25 C as measured by Brookfield RVDV-II+PCP cone and plate viscometer. The nanocomposite is deposited as a 2-3-micron film and has 1.84 cured film RI at 589 nm on a glass substrate. Nanocomposite 22B significantly less yellowing than 22A as shown by about 10× reduction in delta b*.

TABLE 9a
Summary of formulation composition and
viscosities described in example 22

| Formulation | Viscosity @ | | | | | |
|---|---|---|---|---|---|---|
| ID | 25° C. (cP) | NC | PBA | M370 | TPO | PGA |
| 22A | 18 | 45.3 | 18.3 | 5.6 | 0.8 | 30.0 |
| 22B | 18.4 | 51.7 | 13.1 | 4.0 | 0.7 | 30.5 |

TABLE 9b
Optical properties of the nanocomposites on glass substrates described
in example 22 when exposed to 405 nm light for 148 hrs (13600 J/cm²).

| | | | | | | | | | Delta |
|---|---|---|---|---|---|---|---|---|---|
| | | | | | | | Delta | Film | Film |
| Film | Film | Delta | Film | | Film RI | Film RI | Film RI | Thickness | Thickness |
| ID | % Haze | % Haze | b* | Delta b* | (589 nm) | (520 nm) | (520 nm) | (um) | (um) |
| 22A | 0.22 | 0.18 | 0.99 | 3.99 | 1.815 | 1.835 | 0.04 | 2.58 | 0.34 |
| 22B | 0.29 | 0.11 | 0.70 | 0.38 | 1.840 | 1.861 | 0.03 | 3.25 | 0.25 |

### Example 23: Nanocomposite Formulation (Solvent-Free IJ)

An exemplary formulation comprises at least partially capped nanocrystals present in this disclosure, present in the range of 20-60 weight with respect to total formulation, monomer blends comprising at least one of BA, BPMA, and/or DVE, present in the range of −40-80 weight percent with respect to the total formulation, optionally contains diluent such as STY and ethyl acetate, present in the range of 0.5-5 weight percent with respect to the total formulation, at least one of photoinitiator and photosensitizer selected from Irgacure 819, ITX, and Esacure 1001M, present in the range of 0.5-2.5 weight percent with respect to the total formulation and residual solvent, present in the range of 1.0-6.5 weight percent with respect to the total formulation. The formulation is prepared as described in method 2 of the present disclosure. The at least partially capped nanocrystals dispersed in a low boiling solvent, ETA, is mixed with monomers, additives, and photoinitiator. After mixing, the formulation is rotoevaporated to remove the solvent and create a homogenous solvent free mixture. Several variations of the formulation are prepared with different nanocrystals present in the disclosure. Table 10a includes compositions, viscosities, and optical properties of the cured films.

The formulations are spin coated on glass substrates and cured in air with 385 nm UV lamp at 1 J/cm² dose. Tables 10b, and 10c includes the change in properties after exposure to 340 nm QUV exposure and condensation.

### Example 23A

An exemplary formulation comprises 40.0 wt % at least partially capped nanocrystals of TiO₂ nanocrystals with no shell in a blend of acrylates consisting of 17.0 wt % BA, 33.0 wt % BPMA, 5.0% DVE, 2.0% Irgacure 819, 1.0% ITX, 1.0% Esacure 1001M, 2.0% STY, and 0.1% BYK 333. The viscosity of the formulation is 25 cP at 25 C as measured by Brookfield RVDV-II+PCP cone and plate viscometer The nanocomposite is deposited as a 11.0-micron film on a glass substrate, and the film is cured under 385 nm UV at 1 J/cm2 in air and has a refractive index of 1.717 at 589 nm.

### Example 23B

An exemplary formulation comprises 45.0 wt % at least partially capped core shell nanocrystals of example 11B in a blend of acrylates consisting of 33.0 wt % BA, 17.0 wt % BPMA, 2.0% Irgacure 819, 2.0% ITX, and 1.0% BYK 333. The viscosity of the formulation is 19 cP at 25 C as measured by Brookfield RVDV-II+PCP cone and plate viscometer. The nanocomposite is deposited as a 11.7-micron film on a glass substrate, and the film is cured under 385 nm UV at 1 J/cm2 in air and has a refractive index of 1.701 at 589 nm.

### Example 23C

An exemplary formulation comprises 40.0 wt % at least partially capped core shell nanocrystals of example 11B in a blend of acrylates consisting of 17.0 wt % BA, 33.0 wt % BPMA, 5.0% DVE, 2.0% Irgacure 819, 1.0% ITX, 1.0% Esacure 1001M, 2.0% STY and 0.1% BYK 333. The viscosity of the formulation is 25 cP at 25 C as measured by Brookfield RVDV-II+PCP cone and plate viscometer. The nanocomposite is deposited as a 12.9-micron film on a glass substrate, and the film is cured under 385 nm UV at 1 J/cm2 in air and has a refractive index of 1.697 at 589 nm.

### Example 23D

An exemplary formulation comprises of 30.0 wt % at least partially capped core shell nanocrystals of example 11B in a blend of acrylates consisting of 20.0 wt % BA, 40.0 wt % BPMA, 5.0% DVE, 2.0% Irgacure 819, 1.0% ITX, 1.0% Esacure 1001M, 2.0% STY and 0.1% BYK 333. The viscosity of the formulation is 21 cP at 25 C as measured by Brookfield RVDV-II+PCP cone and plate viscometer. The nanocomposite is deposited as a 10.8-micron film on a glass substrate, and the film is cured under 385 nm UV at 1 J/cm2 in air and has a refractive index of 1.669 at 589 nm.

Nanocomposites comprising core shell nanocrystals show 3× improvement in delta b* and greater than 4× improvement in change in yellowness index (YI).

TABLE 10a
Viscosities and optical properties of the nanocomposites
made using formulation described in example 23

| | Viscosity @ | | | Film % T | | Film |
|---|---|---|---|---|---|---|
| | 25° C. | Film | Film | (380-780 | Film RI | Thickness |
| ID | (cP) | % Haze | b* | nm) | (589 nm) | (microns) |
| 23A | 25 | 0.5 | 2.6 | 95.5 | 1.717 | 10.2 |
| 23B | 19 | 0.4 | 2.4 | 95.8 | 1.701 | 11.7 |
| 23C | 25 | 0.5 | 2.0 | 96.3 | 1.697 | 12.9 |
| 23D | 21 | 0.6 | 1.5 | 96.6 | 1.669 | 10.8 |

TABLE 10b
Optical properties of the nanocomposites described in example 23 when exposed
to QUV accelerated weathering test at 340 nm for 72 hours (0.89 mW/cm²)

| Film | | Delta | | Delta | | Delta | | Delta | | Delta | | Delta |
|---|---|---|---|---|---|---|---|---|---|---|---|---|
| ID | L* | L* | a* | a* | b* | b* | % Haze | % Haze | Ytrans | Ytrans | YI | YI |
| 23A | 97.32 | −2.96 | −0.27 | −2.45 | 2.36 | 15.71 | 0.88 | 0.57 | 93.22 | −7.10 | 4.22 | 25.57 |
| 23C | 97.65 | −1.21 | −0.53 | −2.01 | 2.19 | 7.24 | 0.55 | 0.04 | 94.05 | −2.97 | 3.69 | 11.52 |

TABLE 10c
Optical properties of the nanocomposites described in example 23 when exposed
to 405 nm light wavelength for 148 hours (13600 J/cm²) continuously

| Film | | Delta | | Delta | | Delta | | Delta | | Delta | | Delta |
|---|---|---|---|---|---|---|---|---|---|---|---|---|
| ID | L* | L* | a* | a* | b* | b* | % Haze | % Haze | Ytrans | Ytrans | YI | YI |
| 23A | 97.40 | −1.68 | −0.48 | −0.52 | 2.20 | 6.29 | 0.47 | 2.15 | 93.42 | −4.09 | 3.75 | 11.09 |
| 23C | 97.54 | −0.63 | −0.23 | −1.75 | 1.92 | 2.21 | 0.50 | 0.12 | 93.76 | −1.55 | 3.43 | 2.75 |

The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

With respect to aspects of the invention described as a genus, all individual species are individually considered separate aspects of the invention. If aspects of the invention are described as “comprising” a feature, embodiments also are contemplated “consisting of” or “consisting essentially of” the feature.

As used herein, the term “about” modifying an amount related to the invention refers to variation in the numerical quantity that can occur, for example, through routine testing and handling; through inadvertent error in such testing and handling; through differences in the manufacture, source, or purity of ingredients employed in the invention; and the like. As used herein, “about” a specific value also includes the specific value, for example, about 10% includes 10%. Whether or not modified by the term “about”, the claims include equivalents of the recited quantities. In one embodiment, the term “about” means within 20% of the reported numerical value.

As used herein, the singular form “a”, “an”, and “the”, includes plural references unless it is expressly stated or is unambiguously clear from the context that such is not intended.

The term “and/or” as used in a phrase such as “A and/or B” herein is intended to include both A and B; A or B; A (alone); and B (alone). Likewise, the term “and/or” as used in a phrase such as “A, B, and/or C” is intended to encompass each of the following embodiments: A, B, and C; A, B, or C; A or C; A or B; B or C; A and C; A and B; B and C; A (alone); B (alone); and C (alone). Similarly, the term “and/or” as used in a phrase such as “at least one of A, B, and/or C” is intended to encompass each of the following embodiments: at least one of A, at least one of B, and at least one of C; at least one of A, at least one of B, or at least one of C; at least one of A or at least one of C; at least one of A or at least one of B; at least one of B or at least one of C; at least one of A and at least one of C; at least one of A and at least one of B; at least one of B and at least one of C; at least one of A (alone); at least one of B (alone); and at least one of C (alone).

Headings and subheadings are used for convenience and/or formal compliance only, do not limit the subject technology, and are not referred to in connection with the interpretation of the description of the subject technology. Features described under one heading or one subheading of the subject disclosure may be combined, in various embodiments, with features described under other headings or subheadings. Further it is not necessarily the case that all features under a single heading or a single subheading are used together in embodiments.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments.

All of the various aspects, embodiments, and options described herein can be combined in any and all variations.

All publications, patents, and patent applications mentioned in this specification are herein incorporated by reference to the same extent as if each individual publication, patent, or patent application was specifically and individually indicated to be incorporated by reference. To the extent that any meaning or definition of a term in this document conflicts with any meaning or definition of the same term in a document incorporated by reference, the meaning or definition assigned to that term in this document shall govern.

1. Nanocrystals having a core-shell structure, comprising a core and an outer shell, wherein the core is at least partially encapsulated by the outer shell, wherein the core comprises a core metal oxide, and the outer shell comprises a shell metal oxide, wherein:
the core metal oxide is characterized as having an average particle size greater than 3 nm but less than 50 nm as measure by TEM; and
the outer shell is characterized as having a thickness between 0.1 nm and 5 nm as measure by TEM, wherein the core metal oxide and the shell metal oxide are the same or different.

2. The nanocrystals of claim 1, wherein the atomic ratio of the shell metal oxide to the core metal oxide is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX.

3. The nanocrystals of any of claims 1 and 2, wherein the core metal oxide has a narrow particle size distribution, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

4. The nanocrystals of any of claims 1 and 2, characterized as having a narrow particle size distribution, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

5. The nanocrystals of any of claims 1-4, comprising an inorganic passivation agent treated core and/or core-shell, wherein the inorganic passivation agent comprises NaH₂PO₂, Na₂HPO₃, NaCl, NaNO₃, and/or LiNO₃.

6. The nanocrystals of any of claims 1-5, comprising an at least partially capped nanocrystal, which is capped with at least one capping agent selected from methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

7. The nanocrystals of claim 6, wherein the organic content of the at least partially capped nanocrystals is less than 25%, such as less than 5%, or 5% to 8% or 8% to 10%, or 10% to 12%, or 12% to 14% or 14% to 16%, or 16% to 18%, or 18% to 20%.

8. The nanocrystals of any of claims 1-7, wherein the core metal oxide comprises titanium dioxide, zirconium dioxide, and/or barium titanate.

9. The nanocrystals of any of claims 1-7, wherein the shell metal oxide comprises silicon dioxide, zirconium dioxide, hafnium dioxide, niobium oxide, aluminum oxide, tantalum oxide, barium titanium oxide, or any combination thereof.

10. The nanocrystals of any of claims 1-7, wherein the core metal oxide comprises TiO₂, and the shell metal oxide comprises silicon dioxide, zirconium dioxide, hafnium dioxide, niobium oxide, aluminum oxide, tantalum oxide, barium titanium oxide, or any combination thereof.

11. The nanocrystals of any of claims 1-10 exhibit low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at 320 nm-390 nm for 66 h at light intensity of 4 mW/cm2.

12. The nanocrystals of any of claims 1-10 exhibit low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at or above 450 nm for 1000 h at light intensity of 16 mW/cm2 or at or above 405 nm for 148 h at light intensity of 25 mW/cm2.

13. The nanocrystals of any of claims 1-10 exhibit low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 405 nm for 148 h at light intensity of 25 mW/cm2.

14. The nanocrystals of any of claims 1-10 exhibit low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 450 nm for 1000 h at 16 mW/cm2.

15. The nanocrystals of any of claim 11-14, wherein the core metal oxide is titanium oxide and the shell metal oxide comprises zirconium oxide, and the average particle size of the nanocrystals is less than 30 nm as measured by TEM.

16. The nanocrystals of claim 15, wherein the atomic ratio of the shell Zr to the core Ti is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX.

17. The nanocrystals of any of claims 1-16, wherein the particle size distribution of the nanocrystals is characterized by a D9999 as less than 500 nm as measured by volume of the nanocrystals dispersed 5% by weight in a solvent, by Dynamic Light Scattering (DLS).

18. A method of preparing core-shelled TiO₂ nanocrystals comprising a core comprising TiO₂ nanocrystals and a shell comprising a shell metal oxide, the method comprising converting a precursor of the shell metal oxide into the shell metal oxide at least partially encapsulating the core comprising TiO₂ nanocrystals in a solvent, wherein the converting comprises 1) mixing the precursor of the shell metal oxide in a reaction mixture of the solvent and the core comprising TiO2 nanocrystals, and 2) heating the reaction mixture at a reaction temperature, e.g., about 90° C., for a period of time to provide the shell metal oxide at least partially encapsulating the core comprising the TiO₂ nanocrystals.

19. The method of claim 18, wherein converting comprises 1) mixing the precursor of the shell metal oxide either directly, or in water, into the reaction mixture of the solvent and the core comprising TiO₂ nanocrystals, and 2) heating the reaction mixture at a reaction temperature of about 50° C. to about 90° C., for about 10 min to about 7 days to form the shell metal oxide at least partially encapsulating the core comprising the TiO₂ nanocrystals.

20. The method of any one of claims 18-19, wherein the shell metal oxide comprising zirconium oxide.

21. The method of claim 20, wherein the precursor of zirconium dioxide is a zirconium alkoxide, such as a zirconium alkoxide having a formula of Zr(OR)₄, a compound having a formula of Zr(OR)ₓG_{y}, or a combination thereof, wherein each R group can be independently an alkyl group (e.g., a C1-C6 alkyl group) or a substituted alkyl group, G group at each occurrence is independently a halogen (e.g., Cl), wherein x is an integer of 0-4, y is an integer of 0-4, provided that x+y is 4, or a zirconium oxyhalide or a zirconium halide.

22. The method of any one of claims 18-21, wherein the solvent comprises one or more solvents selected from benzyl alcohol, phenol, oleyl alcohol, butanol, propanol, isopropanol, ethanol, butoxy ethanol, butoxy propanol, methanol, 2-(isopentyloxy)ethanol, 2-propoxy-propanol (PnP), 2-(hexyloxy)ethanol, tetrahydrofuran, dimethyl ether, diethyl ether, dibutyl ether, propylene glycol monomethyl ether (PGME), diethylene glycol butyl ether, dipropylene glycol methyl ether (DPGME), diethylene glycol monomethyl ether, diethylene glycol monoethyl ether, diethylene glycol, dipropylene glycol, acetone, propylene glycol methyl ether acetate (PGMEA), ethyl lactate (EL), methyl acetates, ethyl acetates, butyl acetate, ethylene glycol monobutyl ether acetate, diethylene glycol monobutyl ether acetate, diethylene glycol monoethyl ether acetate, butoxy ethyl acetate, ethyl acetate, 2-(2-butoxyethoxy)ethyl acetate, benzene, toluene, and water.

23. The method of any one of claims 18-22, wherein the core-shelled TiO₂ nanocrystals have an average particle size of about 3 nm to about 50 nm as measured by TEM.

24. The method of any one of claims 18-23, wherein the core comprising TiO₂ nanocrystals have an average particle size of 3 nm-50 nm and the shell comprising the shell metal oxide have a shell thickness of 0.1 nm to 5 nm, as measured by TEM.

25. The method of any one of claims 20-24, wherein the shell metal oxide comprises ZrO₂, and the atomic ratio of Zr/Ti of the core TiO₂ nanocrystals and the shell ZrO₂ is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX.

26. The method of any one of claims 18-25, wherein the shell of at least one metal oxide material on the TiO₂ nanocrystals encapsulates the TiO₂ nanocrystals completely or partially.

27. The method of any one of claims 18-26, wherein the shell comprises the shell metal oxide in crystalline and/or amorphous form.

28. The method of any one of claims 18-27, wherein the core-shelled TiO₂ nanocrystals prepared according to the method have a narrow particle size distribution, which is characterized by 1) a ratio of D90:D10 of less than 5, preferably, less than 3, or less than 2, such as about 1.1 to about 2, about 1.5 to about 2, about 1.2 to about 1.8, about 1.2 to about 3, or about 1.5 to about 3; 2) a ratio of D90:D50 of less than 3, preferably, less than 2, or less than 1.5, such as about 1.1 to about 2, about 1.5 to about 2, about 1.2 to about 1.5; and/or 3) a ratio of D50:D10 of less than 3, preferably, less than 2, or less than 1.5, such as about 1.1 to about 2, about 1.5 to about 2, about 1.2 to about 1.5.

29. A method of capping core-shelled TiO₂ nanocrystals having a core comprising TiO₂ nanocrystals with a shell comprising ZrO₂, comprising reacting the nanocrystals of any one of claims 1-5 with a first capping agent in a first capping solvent to produce a first at least partially capped core-shelled TiO₂ nanocrystals.

30. The method of claim 29 wherein the capping agent is one or more of methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

31. A nanocrystal dispersion comprising at least partially capped core-shelled nanocrystals comprising a core metal oxide with an outer shell comprising a shell metal oxide, at least one capping agent, and a dispersion media wherein:
the core metal oxide is characterized as having an average particle size greater than 3 nm but less than 50 nm as measure by TEM or DLS and the shell is characterized as having a thickness between 0.2 nm and 5 nm as measure by TEM or DLS; and
wherein the at least partially capped core-shelled nanocrystals are present in an amount of greater than 10%, by weight of the dispersion.

32. The nanocrystal dispersion of claim 31, wherein at least partially capped core-shelled nanocrystals are capped with at least one capping agent selected from methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

33. The nanocrystal dispersion of any of claims 31-32, wherein the core-shelled nanocrystals are treated with an inorganic passivation agent comprising NaH₂PO₂, Na₂HPO₃, NaCl, NaNO₃, and/or LiNO₃.

34. The nanocrystal dispersion of any of claims 31-33, wherein the organic content of the at least partially capped nanocrystals is less than 25%, such as less than 5%, or less than 8% or less than 10%, less than 12%, or less than 14% or less than 16%, less than 18%, or less than 20%.

35. The nanocrystal dispersion of any of claims 31-34, wherein the core metal oxide comprises titanium dioxide, zirconium dioxide, and/or barium titanate.

36. The nanocrystal dispersion of any of claims 31-35, wherein the shell metal oxide comprises silicon dioxide, zirconium dioxide, hafnium dioxide, niobium oxide, aluminum oxide, tantalum oxide, barium titanium oxide, or any combination thereof.

37. The nanocrystal dispersion of any of claims 31-36, wherein the at least partially capped core-shelled nanocrystals are present in an amount equal to or greater than 50%, by weight of the dispersion and wherein the % organics are less than 20% of the at least partially capped core-shelled nanocrystals.

38. The nanocrystal dispersion any of claims 31-37, wherein the core metal oxide is titanium oxide and the shell metal oxide comprises zirconium oxide and the average particle size of the at least partially capped core-shelled nanocrystals is less than 30 nm as measured by TEM or DLS

39. The nanocrystal dispersion of any of claims 31-38 wherein the atomic ratio of the shell ZrO₂ to the core TiO₂ is less than 3, such as less than 0.1, less than 0.2, less than 0.3, less than 0.4, less than 0.5, less than 0.6, less than 0.7, less than 0.8 nm, less than 0.9, less than 1, less than 2, less than 3, as measured by SEM EDX.

40. The nanocrystal dispersion of any of claims 31-39, wherein the particle size distribution of the at least partially capped core-shelled nanocrystals is characterized by a D9999 as less than 500 nm as measured by volume of the at least partially capped core-shelled nanocrystals dispersed 5% by weight in a solvent by Dynamic Light Scattering (DLS).

41. The nanocrystal dispersion of any of claims 31-39, wherein the particle size distribution of the at least partially capped core-shelled nanocrystals is characterized by a D9999 as less than 300 nm as measured by volume of the at least partially capped core-shelled nanocrystals dispersed 5% by weight in a solvent by Dynamic Light Scattering (DLS).

42. The nanocrystal dispersion of any of claims 31-41, wherein the dispersion media comprises a solvent, monomer, oligomer of a polymer, or a combination thereof.

43. A nanocomposite formulation comprising 1) at least partially capped core-shelled TiO₂ nanocrystals with an outer shell comprising a shell metal oxide; 2) a monomer, oligomer, and/or polymer; 3)optionally a solvent; and 4) a curing agent, wherein the at least partially capped core-shelled TiO₂ nanocrystals are present in an amount of greater than 20% by weight with respect to the monomer, oligomer and/or polymer, wherein the core of the at least partially capped core-shelled TiO₂ nanocrystals comprises crystalline titanium dioxide, and is treated with at least one inorganic passivation agent; and wherein the average particle size of the at least partially capped core-shelled TiO₂ nanocrystals when measured with DLS as a 5% nanocrystal dispersion in PGMEA is in the range of 3-50 nm.

44. The nanocomposite formulation of claim 43, wherein the at least partially capped core-shelled TiO₂ nanocrystals have an average particle size greater than 3 nm but less than 50 nm and a shell thickness between 0.1 nm and 3 nm as measure by TEM.

45. The nanocomposite formulation of any of claims 43-44, wherein the at least partially capped core-shelled TiO₂ nanocrystals are capped with at least one capping agent selected from methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

46. The nanocomposite formulation of any of claims 43-45, wherein the shell metal oxide comprises silicon dioxide, zirconium dioxide, hafnium dioxide, niobium oxide, aluminum oxide, tantalum oxide, barium titanium oxide, or any combination thereof.

47. The nanocomposite formulation of any of claims 43-46, wherein the at least partially capped core-shelled nanocrystals are present in an amount equal to or greater than 50%, by with respect to the monomer, oligomer and/or polymer.

48. The nanocomposite formulation of any of claims 43-47 wherein the viscosity of the formulation is in the range of 1-1000 cP.

49. The nanocomposite formulation of any of claims 43-48 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at 320 nm-390 nm for 100 h.

50. The nanocomposite formulation of any of claims 43-48 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at or above 450 nm for 1000 h.

51. The nanocomposite formulation of any of claims 43-48 wherein the at least partially capped core-shelled TiO₂ nanocrystals have low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 320-390 nm for 100 h.

52. The nanocomposite formulation of any of claims 43-48 wherein the at least partially capped core-shelled TiO₂ nanocrystals have low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 450 nm for 1000 h.

53. A nanocomposite comprising cured film comprising at least partially capped core-shelled TiO₂ nanocrystals with an outer shell comprising a shell metal oxide and at least one monomer, oligomer and/or polymer, wherein the at least partially capped core-shelled TiO₂ nanocrystals are present in an amount greater than 50%, by weight of the nanocomposite, wherein the transmittance of the film with a thickness of 1 micron is greater than 80% at wavelength of 400 nm and above, and the film has a refractive index of about 1.60 to about 2.20 as measured using a Prism Coupler or an ellipsometer.

54. The nanocomposite of claim 53, wherein the film with <5 μm thickness is thermally stable when subjected to temperatures higher than 200C for 5 minutes wherein the change in b*is less than 1%, or less than 5%, or less than 10%, or less than 15%, or less than 20%, or less than 25% and the change in % haze is less than 1%, or less than 5%, or less than 10%, or less than 15%, or less than 20%, or less than 25% as measured by hazemeter.

55. The nanocomposite film of any of claims 53 and 54, wherein the at least partially capped core-shelled TiO₂ nanocrystals have an average particle size greater than 3 nm but less than 50 nm as measure by TEM and a shell thickness between 0.2 nm and 3 nm as measure by TEM.

56. The nanocomposite film of any of claims 53-55, wherein the at least partially capped core-shelled TiO₂ nanocrystals are capped with at least one capping agent selected from methyltrimethoxysilane, ethyltrimethoxysilane, n-propyltrimethoxysilane, n-propyltriethoxysilane, n-octyltrimethoxysilane, n-octyltriethoxysilane, phenytrimethoxysilane, dodecyltrimethoxysilane, m,p-ethylphenethyl trimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-(acryloyloxy)propyl trimethoxysilane, 3-isocyanatopropyltriethoxysilane, 3-isocyanatopropyltrimethoxysilane, and 3-glycidoxypropyltrimethoxysilane, vinyltrimethoxysilane, allyltrimethoxysilane, 1-hexenyltrimethoxysilane, 1-octenyltrimethoxysilane, N-phenylaminopropyltrimethoxysilane, 3-(4-pyridylethyl)thiopropyltrimethoxysilane, N-(3-Trimethoxysilylpropyl)pyrrole, 2-(3-trimethoxysilylpropylthio)thiophene, (3-trimethoxysilylpropyl)diethylenetriamine, phenyltrimethoxysilane, ((chloromethyl)phenylethyl) trimethoxysilane, 2-(Diphenylphosphino) ethyltriethoxysilane, 4-phenylbutyltrimethoxysilane, 2-phenylethyltrimethoxysilane, 4-Biphenylyltriethoxysilane, N-[3-(trimethoxysilyl) propyl] allylamine, 3-mercaptopropyltrimethoxysilane, 8-glycidoxyoctyltrimethoxysilane, (3-glycidoxypropyl) trimethoxysilane, tetraethyl orthosilicate, heptanol, hexanol, octanol, benzyl alcohol, phenol, ethanol, propanol, butanol, oleylalcohol, dodecylalcohol, octadecanol and triethylene glycol monomethyl ether, (2-{2-[2-Methoxy-ethoxy]-ethoxy}-ethyl)phosphonic acid, (6-{2-[2-(2-Methoxy-ethoxy)-ethoxy]-ethoxy}-hexyl)phosphonic acid, 11-Acryloyloxyundecylphosphonic acid, octanoic acid, acetic acid, propionic acid, 2-[2-(2-methoxyethoxy)ethoxy] acetic acid, oleic acid, benzoic acid, stearic acid, trifluoroacetic acid, biphenyl-4-carboxylic acid, 2-(2-methoxyethoxy) acetic acid, methacrylic acid, mono-2-(Methacryloyloxy)ethyl succinate, or any combination thereof.

57. The nanocomposite film of any of claims 53-56, wherein the shell metal oxide comprises silicon dioxide, zirconium dioxide, hafnium dioxide, niobium oxide, aluminum oxide, tantalum oxide, barium titanium oxide, or any combination thereof.

58. The nanocomposite film of any of claims 53-57 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at 320 nm-390 nm for 100 h.

59. The nanocomposite film of any of claims 53-57 wherein the at least partially capped core-shelled TiO₂ nanocrystals have low photocatalytic activity as measured by less than 50%, such as less than 1%, or less than 5%, or less than 10%, or less than 15%, or less than 20%, or less than 25%, less than 30%, less than 40%, less than 50% change in b* when the b* of a 1 μm thick film comprising the core-shell structure is measured using a hazemeter before and after the UV exposure at or above 450 nm for 1000 h.

60. The nanocomposite film of any of claims 53-57 wherein the at least partially capped core-shelled TiO₂ nanocrystals have low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 320-390 nm for 100 h.

61. The nanocomposite film of any of claims 53-57 wherein the at least partially capped core-shelled TiO₂ nanocrystals have low photocatalytic activity as measured by less than 0.08, such as less than 0.01, less than 0.02, less than 0.03, less than 0.04, less than 0.05, less than 0.06, less than 0.07, change in refractive index when the refractive index of a film comprising the core-shell nanocrystals is measured using a prism coupler or an ellipsometer before and after the UV exposure at or above 450 nm for 1000 h.

62. A device comprising any of the nanocomposite film of any of claims 53-61.
